(19) United States
(12) Patent Application Publication
(10) Pub. No.: US 2026/0344250 A1
(43) Pub. Date: Oct. 29, 2026

(54) Element, display device, electronic component, semiconductor device, and photosensitive composition

(71) Applicant: Toray Industries, Inc., Tokyo (JP)

(72) Inventors: Yugo TANIGAKI, Otsu-shi, Shiga (JP); Osamu BABA, Otsu-shi, Shiga (JP); Satoshi KAMEMOTO, Otsu-shi, Shiga (JP)

(73) Assignee: Toray Industries, Inc., Tokyo (JP)

(21) Appl. No.: 19/491,169

(22) PCT Filed: Jun. 21, 2024
(86) PCT No.: PCT/JP2024/022585

§ 371 Date: Dec. 8, 2025

(30) Foreign Application Priority Data
Jun. 27, 2023 (JP) 2023-104745

(51) Int. Cl. H10K 59/80; G03F 7/004; G03F 7/038; G03F 7/039; H10K 59/122

(52) U.S. Cl. CPC H10K 59/80524; G03F 7/0045; G03F 7/0387; G03F 7/0392; H10K 59/122; H10K 59/80523; H10K 59/873; H10K 59/8792

(57) ABSTRACT

The present disclosure provides an element comprising a substrate, a conductive inorganic layer, and an insulating resin layer in this order.

### TECHNICAL FIELD

The present invention relates to an element, a display device, an electronic component, a semiconductor device, and a photosensitive composition.

### BACKGROUND ART

In recent years, efforts have been made to reduce cost and increase integration by improving efficiency of a semiconductor manufacturing process, and a semiconductor device that forms a multilayer metal redistribution wiring has attracted attention. The interlayer insulating layer in such multilayer metal redistribution wiring is required to have increased migration resistance because reliability regarding electrical insulation is required due to wiring miniaturization associated with high integration of the semiconductor device.

Furthermore, in an organic electroluminescence (hereinafter, “organic EL”) display as a display device, a pixel division layer or a thin film transistor (hereinafter, “TFT”) planarization layer is formed at a position adjacent to or close to a light-emitting element. Therefore, in order to improve reliability of the organic EL display, it is necessary to examine a configuration of a pixel division layer and the like and physical properties (for example, heat resistance) of the pixel division layer and the like. In addition, in order to achieve high luminance and power saving of the organic EL display, excellent light emission characteristics capable of low voltage drive in obtaining a desired current density are required.

Material used for the interlayer insulating layer, the pixel division layer, and the like is also required to suppress development residues at the time of forming a positive type or negative type pattern by a photolithography method.

As the display device, for example, a display device including a pixel division layer containing polyimide (see, for example, Patent Document 1) and an organic EL display (see, for example, Patent Document 2) in which a sum of contents of a metal element and/or a halogen element in a cured film falls within a specific range are known.

### PRIOR ART DOCUMENT

### Patent Documents

Patent Document 1: Japanese Patent Laid-open Publication No. 2002-091343
Patent Document 2: International Publication No. 2018/123853

### SUMMARY OF THE INVENTION

### Problems to be Solved by the Invention

However, the display device described in Patent Document 1 or Patent Document 2 still has a problem with light emission characteristics related to low voltage drive, reliability of a light-emitting element, or migration resistance.

An object of the present invention is to provide a display device having excellent light emission characteristics capable of low voltage drive in obtaining a desired current density, and excellent reliability of a light-emitting element. Another object of the present invention is to provide an electronic component or a semiconductor device excellent in migration resistance.

### Solutions to the Problems

As a result of intensive studies to solve the above-described problems, it has been found that a remarkable effect can be obtained by focusing on the content of the halogen element on the electrode surface serving as the opening. In particular, the present inventors have found that the above-described problems can be solved by a specific configuration related to a fluorine element among halogen elements, and have completed the present invention. The element of the present invention of the photosensitive composition of the present invention has the following configurations [1] to [22].
[1] An element including a substrate, a conductive inorganic layer, and an insulating resin layer in this order, in which
the insulating resin layer has a plurality of openings, and
when a detection intensity of fluorine ions (F⁻) measured by time-of-flight secondary ion mass spectrometry at a position of 5 nm in depth from a surface of the conductive inorganic layer on the insulating resin layer side in the opening is denoted by (F_{ML}) counts, Formula (FA-1) is satisfied:

(F_{ML})≤500 (FA-1).
[2] A display device including the element according to [1],
further including a second electrode and a light-emitting layer, in which the conductive inorganic layer is a first electrode, and the insulating resin layer is a pixel division layer, or
the display device further including a first electrode, a second electrode, a pixel division layer, and a light-emitting layer, in which the insulating resin layer is a TFT planarization layer, and the conductive inorganic layer is a metal wiring layer.
[3] The display device according to [2], in which
the first electrode is a multi-layered non-transparent electrode, and
at least one of the layers of the first electrode other than an outermost layer on a light-emitting layer side has a non-transparent conductive metal layer containing silver or copper as a main component element.
[4] The display device according to [2] or [3], in which
the first electrode has a transparent conductive oxide layer and a non-transparent conductive metal layer, and
the outermost layer of the first electrode on the light-emitting layer side has a transparent conductive oxide layer containing indium as a main element.
[5] The display device according to [4] including a second electrode and a light-emitting layer, in which
the conductive inorganic layer is a first electrode, and the insulating resin layer is a pixel division layer, and
when the detection intensity of indium oxide ions (InO₂⁻) measured by time-of-flight secondary ion mass spectrometry at a position 5 nm deep from a surface of the transparent conductive oxide layer on a side in contact with the light-emitting layer in the opening is (InO_{ML}) counts,

Formula (FA-2) and Formula (InA-1) are satisfied:

(F_{ML})/(InO_{ML})≤0.5000 (FA-2)

1,000≤(InO_{ML})≤40,000 (InA-1).

[6] The display device according to any one of [2] to [5], in which
the pixel division layer has a step shape with a thick film portion and a thin film portion, and
the thick film portion and the thin film portion include a same (XA) resin, or
the thick film portion and the thin film portion include a same (XD) colorant, and an optical density at a visible light wavelength per 1 μm of film thickness of both the thick film portion and the thin film portion is 0.5 or more and 3.0 or less.
[7] The display device according to any one of [2] to [5], in which
the pixel division layer has a step shape having a thick film portion and a thin film portion,
the thin film portion includes an (XD) colorant, and an optical density of the thin film portion per 1 μm of film thickness at a visible light wavelength is 0.5 or more and 3.0 or less, and
the thick film portion satisfies at least one of conditions (SP1) to (SP3):
(SP1) the thick film portion does not include an (XD) colorant;
(SP2) the thick film portion includes an (XD) colorant, and the thick film portion has an optical density of 0.0 or more and 0.3 or less at a wavelength of visible light per 1 μm of a film thickness;
(SP3) the thick film portion includes compound (XC1x): one or more compounds selected from a group consisting of carboxylic acid having an indene structure, carboxylic acid ester having an indene structure, sulfonic acid having an indene structure, and sulfonic acid aryl ester having an indene structure.
[8] The element according to [1] or the display device according to any one of [2] to [7], in which when a detection intensity of chloride ions (Cl⁻) measured by time-of-flight secondary ion mass spectrometry at a position of 5 nm in depth from a surface of the conductive inorganic layer on the insulating resin layer side in the opening is (Cl_{ML}) counts, a detection intensity of bromide ions (Br⁻) is (Br_{ML}) counts, and a detection intensity of sulfur ions (S⁻) is (S_{ML}) counts,
at least one of Formula (ClA-1), Formula (BrA-1), and Formula (SA-1) is satisfied:

(Cl_{ML})≤200 (ClA-1)

(Br_{ML})≤200 (BrA-1)

(S_{ML})≤200 (SA-1).
[9] The element according to [8], or the display device according to [8], in which at least one of Formula (ClA-1a), Formula (BrA-1a), and Formula (SA-1a) is satisfied:

2≤(Cl_{ML})≤200 (ClA-1a)

2≤(Br_{ML})≤200 (BrA-1a)

2≤(S_{ML})≤200 (SA-1a).
[10] The element according to any one of [1], [8], and [9], or the display device according to any one of [2] to [7], [8], and [9], in which the insulating resin layer includes (XA1x) resin: resin having one or more structures selected from a group consisting of an imide structure, an amide structure, an oxazole structure, and a siloxane structure in a structural unit of resin, and/or (XA1y) resin: resin having a phenolic hydroxyl group in a structural unit of resin.
[11] The element according to or the display device according to [10], in which the insulating resin layer includes the (XA1x) resin, and the (XA1x) resin includes one or more resins selected from a group consisting of a polyimide, a polyimide precursor, a polybenzoxazole, a polybenzoxazole precursor, a polyamideimide, a polyamideimide precursor, and a copolymer thereof.
[12] The element according to or the display device according to [11], in which the (XA1x) resin has an amine residue having a phenolic hydroxyl group, and the amine residue having a phenolic hydroxyl group has an amine residue satisfying the following condition (XS1x):
(XS1x) an amine residue has a C₁ symmetry axis as a molecular symmetry and does not have a C₂ symmetry axis.
[13] The element according to [11] or [12] or the display device according to [11] or [12], in which
the (XA1x) resin has an amine residue having a phenolic hydroxyl group and an amine residue having no phenolic hydroxyl group, and
the amine residue having a phenolic hydroxyl group has an amine residue that satisfies the following condition (XS1x), and/or the amine residue having no phenolic hydroxyl group has an amine residue that satisfies at least one of the following conditions (XS1x) and (XS2x):
(XS1x) the amine residue has a C₁ symmetry axis as a molecular symmetry and does not have a C₂ symmetry axis;
(XS2x) the amine residue has at least one of an asymmetric center, an asymmetric axis, an asymmetric plane, and a helical axis.
[14] The element according to any one of [1] and [8] to [13], or the display device according to any one of [2] to [13] in which the insulating resin layer includes a (XH) nitrogen-containing compound, the (XH) nitrogen-containing compound includes one or more compounds selected from a group consisting of a cyclic amide compound, an amide compound, a cyclic urea compound, a urea compound, an oxazolidone compound, and an isoxazolidone compound, and a following condition (X4) is satisfied:
(X4) the total content of the cyclic amide compound, the amide compound, the cyclic urea compound, the urea compound, the oxazolidone compound, and the isoxazolidone compound in the insulating resin layer is 0.010 mass % or more and 5.0 mass % or less.
[15] The element according to any one of [1] and [8] to [14] or the display device according to any one of [2] to [14], in which
the insulating resin layer includes (XC1x) compounds: one or more compounds selected from a group consisting of carboxylic acids having an indene structure, carboxylic acid esters having an indene structure, sulfonic acids having an indene structure, and sulfonic acid aryl esters having an indene structure, and/or
(XC2x) compounds: compounds having a fluorene structure, a carbazole structure, an indole structure, or a diphenyl sulfide structure, and having an imino group bonded to any of these structures and/or having a carbonyl group bonded to any of these structures.
[16] The element according to any one of [1] and [8] to [15] or the display device according to any one of [2] to [15], in which
the insulating resin layer includes an organic black pigment and/or an inorganic black pigment, and the organic black pigment includes one or more pigment selected from a group consisting of benzofuranone-based black pigments, perylene-based black pigments, and azo-based black pigments, and
the inorganic black pigment includes one or more elements selected from a group consisting of nitrides including metal elements, carbides including metal elements, and oxynitrides including metal elements, and the metal elements being one or more elements selected from a group consisting of zirconium, vanadium, niobium, hafnium, and tantalum.
[17] The element according to any one of [1] and [8] to [16] or the display device according to any one of [2] to [16], in which
the insulating resin layer includes
a compound having a quinone structure and/or a quinoid structure of a compound having an aromatic structure to which at least three phenolic hydroxyl groups are bonded, or
a compound having a crosslinked structure between a compound having an aromatic structure to which at least three phenolic hydroxyl groups are bonded and a compound having a structure represented by Formula (11):

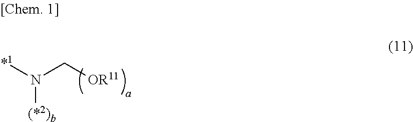

In Formula (11), R¹¹ represents a hydrogen atom or an alkyl group having 1 to 10 carbon atoms; *¹ and *² each independently represent a bonding point; however, a carbonyl group is not adjacent to a nitrogen atom; a represents 1 or 2; b represents 0 or 1; note that a+b=2.
[18] An electronic component including the element according to any one of [1] and [8] to [17], or an electronic component including the display device according to any one of [2] to [17].
[19] A semiconductor device including the element according to any one of [1] and [8] to [17],
the semiconductor device further including a semiconductor chip and a sealing material covering the semiconductor chip, in which
the conductive inorganic layer is a redistribution layer, and the insulating resin layer is an interlayer insulating layer of the redistribution layer, and
in plan view, an area of the redistribution layer is larger than an area of the semiconductor chip.
[20] A display device including the element according to any one of [1] and [8] to [17],
the display device further including a light-emitting element, in which
the conductive inorganic layer is a metal wiring layer, and the insulating resin layer is a barrier layer and/or a planarization layer,
the light-emitting element and the metal wiring are electrically connected, the light-emitting element is a semiconductor chip, the barrier layer is formed between adjacent light-emitting elements, and the planarization layer is formed so as to cover at least a part of the light-emitting element, or
the display device further including a light-emitting element and a metal wiring layer, in which
the conductive inorganic layer is a redistribution layer, and the insulating resin layer is an interlayer insulating layer of the redistribution layer,
the light-emitting element and the metal wiring are electrically connected, the light-emitting element is a semiconductor chip, and
in plan view, an area of the redistribution layer is larger than an area of the light-emitting element.
[21] An element including a substrate, a conductive inorganic layer, and an insulating resin layer in this order, in which
the insulating resin layer has a plurality of openings, and
when a detection intensity of a fluorine ion (F⁻), a detection intensity of a chlorine ion (Cl⁻), and a detection intensity of a bromine ion (Br⁻) measured by time-of-flight secondary ion mass spectrometry at a position of 5 nm in depth from a surface of the conductive inorganic layer on the insulating resin layer side in the opening are defined as (F_{ML}) counts, (Cl_{ML}) counts, and (Br_{ML}) counts, respectively, and
when a sum of (F_{ML}), (Cl_{ML}), and (Br_{ML}) is set as (XML) counts, Formula (XA-1) is satisfied, and
further, when a detection intensity of a fluorine ion (F⁻), a detection intensity of a chlorine ion (Cl⁻), and a detection intensity of a bromine ion (Br⁻) measured by time-of-flight secondary ion mass spectrometry at a position of 5 nm in depth from a surface of the insulating resin layer in the insulating resin layer portion are defined as (F_{RN}) counts, (Cl_{RN}) counts, and (Br_{RN}) counts, respectively, and
when a sum total of (F_{RN}), (Cl_{RN}), and (Br_{RN}) is set as (X_{RN}) counts, Formula (XB-1) is satisfied:

(X_{ML})≤500 (XA-1)

(X_{RN})≤500 (XB-1).

A photosensitive composition including an (A) binder resin, and a (C) photosensitive agent, the photosensitive composition further including a (B) radical polymerizable compound and/or an (F) crosslinking agent, in which
the (A) binder resin includes an (A1) weakly acidic group-containing resin, and the (A1) weakly acidic group-containing resin has one or more groups selected from a group consisting of a (WA) weakly acidic group: a phenolic hydroxyl group, a hydroxyimide group, a hydroxyamide group, a silanol group, and a mercapto group, and
the photosensitive composition satisfies a following condition (1a),
the photosensitive composition further comprises water, and satisfies a following condition (3):
(1a) a content of a fluorine element in a total solid content of the photosensitive composition is 1, 000 ppm by mass or less;
(3) a content of water in the photosensitive composition is 0.010 mass % or more and 3.0 mass % or less.

### Effects of the Invention

According to the element of the present invention, it is possible to provide a display device having excellent light emission characteristics capable of low voltage drive in obtaining a desired current density and excellent reliability of the light-emitting element. In addition, it is possible to provide an electronic component or a semiconductor device having excellent migration resistance. In addition, according to the photosensitive composition of the present invention, it is possible to obtain a cured product included in a display device that can suppress residues after development, has the same excellent light emission characteristics, and has excellent reliability of a light-emitting element. In addition, a cured product included in an electronic component or a semiconductor device having excellent migration resistance can be obtained.

### BRIEF DESCRIPTION OF THE DRAWINGS

FIG. 1 is a schematic cross-sectional view and a plan view illustrating an example of a display device 100A having a step shape in which a pixel division layer has a thick film portion and a thin film portion.

FIG. 2 is a schematic cross-sectional view illustrating an example of a display device 30A including an interlayer insulating layer, a barrier layer, and a planarization layer.

FIG. 3 is a schematic cross-sectional view illustrating an example of a pad portion of the semiconductor device 10A having bumps.

FIG. 4 is a plan view illustrating a manufacturing process of steps 1 to 4 on a substrate of an organic EL display used for light emission characteristics evaluation.

### EMBODIMENTS OF THE INVENTION

Hereinafter, an element, a display device, an electronic component, and a semiconductor device of the present invention will be described. Note that the description of the element of the present invention is common to the elements according to the first and second aspects of the present invention. On the other hand, when an element according to a specific aspect is described, the element is described as an element according to the first aspect of the present invention. The same applies to the description regarding the display device according to the first aspect, the second aspect, and the third aspect. It is noted that the present invention is not limited to the following embodiments, and various modifications can naturally be made as long as the modifications can achieve the object of the invention and do not depart from the gist of the invention.

The plane of the element of the present invention in plan view refers to a plane horizontal to a substrate described later. In addition, in a case of a display device, and in a case where a plane horizontal to a substrate is an xy-axis plane, and a direction orthogonal to the xy-axis plane is a z-axis direction, the plan view refers to a plan view on a light extraction side in the xy-axis plane viewed from the z-axis direction. In a case of the semiconductor device, the plan view refers to a plan view of the xy-axis plane viewed from any of the z-axis directions in a case where a plane horizontal to the substrate is the xy-axis plane, and a direction orthogonal to the xy-axis plane is the z-axis direction. When focusing on a specific member in a plan view of the element of the present invention, it is assumed that another member overlapping the specific member is seen through the element. In a case where the substrate is not a plane, a plane horizontal to an arbitrary pixel area to be described later, a plane horizontal to an arbitrary semiconductor chip to be described later, or a plane horizontal to an arbitrary light-emitting element to be described later is defined as an xy plane. Overlapping means overlapping directly or indirectly with respect to the z-axis direction.

Detection intensities of a fluorine ion, a chlorine ion, a bromine ion, a sulfur ion, an indium oxide ion, a carbon ion, and a cyanide ion can be calculated as an average value obtained by measuring time-of-flight secondary ion mass spectrometry three times. It is also preferable that the average value of the detection intensities of the respective ions (the average value of the detection intensities at a depth of 5 nm and a depth of 6 nm) measured at positions of a depth of 5 nm and a depth of 6 nm from the surface of the conductive inorganic layer or the surface of the insulating resin layer satisfies the above relationship. In addition, it is more preferable that the average value of the detection intensities of the respective ions (average value of detection intensities at depth of 4 nm, depth of 5 nm, and depth of 6 nm) measured at positions of a depth of 4 nm, a depth of 5 nm, and a depth of 6 nm from the surface of the conductive inorganic layer or the surface of the insulating resin layer satisfies the above relationship,

In an (XA) resin in the element of the present invention and an (A) binder resin in the photosensitive composition of the present invention, an amine residue refers to a structure obtained by removing a nitrogen atom and a substituent on the nitrogen atom from a structure derived from an amine or a structure derived from an amine derivative in the resin. That is, the amine residue corresponds to a structure obtained by removing a nitrogen atom and a substituent on the nitrogen atom from an amine molecule or an amine derivative molecule as a raw material of the resin. The amine residue preferably has a divalent or higher valent structure, that is, a structure obtained by removing at least two nitrogen atoms and substituents on the nitrogen atoms from a structure derived from an amine or a structure derived from an amine derivative in a structural unit of the resin. It is also preferable that the amine residue has a trivalent or higher structure. Examples of such an amine residue include a structure obtained by removing a nitrogen atom and a substituent on the nitrogen atom from a diamine molecule, a triamine molecule, a diamine derivative molecule, or a triamine derivative molecule as a raw material of the resin.

In the (XA) resin in the element of the present invention and the (A) binder resin in the photosensitive composition of the present invention, a carboxylic acid residue refers to a structure obtained by removing a carbonyl group and a substituent on a carbonyl carbon atom from a structure derived from a carboxylic acid or a structure derived from a carboxylic acid derivative in the resin. That is, the carboxylic acid residue corresponds to a structure obtained by removing a carbonyl group and a substituent on a carbonyl carbon atom from a carboxylic acid molecule or a carboxylic acid derivative molecule as a raw material of a resin. The carboxylic acid residue preferably has a divalent or higher structure, that is, a structure obtained by removing at least two carbonyl groups and a substituent on a carbonyl carbon atom from a structure derived from a carboxylic acid or a structure derived from a carboxylic acid derivative in the structural unit of the resin. The carboxylic acid residue preferably has a trivalent or higher structure, and also preferably has a tetravalent or higher structure. Examples of such a carboxylic acid residue include a structure obtained by removing a carbonyl group and a substituent on a carbonyl carbon atom from a dicarboxylic acid molecule, a tricarboxylic acid molecule, a tetracarboxylic acid molecule, a dicarboxylic acid derivative molecule, a tricarboxylic acid derivative molecule, or a tetracarboxylic acid derivative molecule, which are raw materials of a resin.

### <Configuration of Element>

The element of the present invention includes a substrate, a conductive inorganic layer, and an insulating resin layer in this order. The insulating resin layer has a plurality of openings. A surface of the conductive inorganic layer is preferably exposed at the plurality of openings of the insulating resin layer. In plan view, the insulating resin layer portion preferably has a plurality of openings, and the conductive inorganic layer portion is preferably exposed at the plurality of openings.

### <Substrate>

The element of the present invention has a substrate.

From the viewpoint of improving impact resistance, the substrate preferably has silicon dioxide or aluminum trioxide, and more preferably has a glass substrate, a quartz substrate, a crystal substrate, or a sapphire substrate.

The substrate, from the viewpoint of conductivity control and insulation property control, preferably has silicon, silicon dioxide, trisilicon tetranitride, silicon carbide, gallium nitride, gallium arsenide, indium phosphide, indium tin oxide, indium zinc oxide, indium gallium zinc oxide, diamond, aluminum trioxide, aluminum zinc oxide, or zinc oxide, and more preferably has a silicon substrate, a silicon carbide substrate, a gallium nitride substrate, an indium phosphide substrate, an indium tin oxide substrate, an indium gallium zinc oxide substrate, or a diamond substrate. The substrate is preferably a semiconductive substrate, and more preferably a semiconductor substrate. The semiconductivity means that a volume resistivity is 1.0×10⁻⁴ to 1.0×10⁸ Ω·cm.

The substrate is preferably a flexible substrate from the viewpoint of improving flexibility, improving bendability, and improving a degree of freedom in shape of the display device (curved surface shape, bent shape, or the like). The flexible substrate is preferably a polyimide substrate, a polyethylene terephthalate substrate, a cycloolefin polymer substrate, a polycarbonate substrate, or a cellulose triacetate substrate, and more preferably a polyimide substrate from the viewpoint of improving bendability.

### <Conductive Inorganic Layer>

The element of the present invention has a conductive inorganic layer. The conductivity means that the volume resistivity is 1.0×10⁻⁸ to 1.0×10⁻⁴ Ω·cm. From the viewpoint of improving conductivity, the conductive inorganic layer preferably includes a metal element as a main component element, and more preferably includes Ag, Cu, Au, Ti, Al, Ni, Mo, or Cr as a main component element. The element as a main component in the conductive inorganic layer refers to an element included in the largest amount on a mass basis in the constituent elements of the conductive inorganic layer. The conductive inorganic layer preferably further includes an element selected from In, Sn, Zn, Al, Ga, Pd, Cu, Bi, Nd, Ni, Mn, Na, K, Mg, Ca, C, and Si as an element different from the element of the main component. The conductive inorganic layer is preferably an electrode or a wiring. The electrode is preferably an anode, a cathode, or an electrode that exhibits conductivity by an external stimulus. Here, examples of the external stimulus include capacitance, light, heat, and pressure. As the wiring, wiring for electrically connecting members or members and an external circuit is preferable.

### <Insulating Resin Layer>

The element of the present invention has an insulating resin layer. The insulation property means that the volume resistivity is 1.0×10⁸ to 1.0×10¹⁸ Ω·cm. The insulating resin layer preferably includes carbon as a main component element from the viewpoint of improving insulating properties. The element as the main component in the insulating resin layer refers to an element included in the largest amount on a mass basis in the constituent elements of the insulating resin layer. The insulating resin layer preferably further includes an element selected from hydrogen, oxygen, nitrogen, phosphorus, sulfur, fluorine, chlorine, and bromine as an element different from the element of the main component. The insulating resin layer is preferably an insulating layer, a planarization layer, an interlayer insulating layer, a barrier layer, a protective layer, or an overcoat layer. The insulating resin layer is preferably a layer for insulating the members or the members from an external circuit.

### <Detection Intensity of Each Ion on Surface of Conductive Inorganic Layer and Surface of Insulating Resin Layer>

In the element according to the first aspect of the present invention, Formula (FA-1) is satisfied when the detection intensity of fluorine ions (F⁻) measured by time-of-flight secondary ion mass spectrometry at a position of 5 nm in depth from the surface of the conductive inorganic layer on the insulating resin layer side in the opening of the insulating resin layer is denoted by (F_{ML}) counts. The element according to the first aspect of the present invention preferably further satisfies Formula (FA-1a).

(F_{ML})≤500 (FA-1)

2≤(F_{ML})≤500 (FA-1a).

Formulas (FA-1) and (FA-1a) are each a formula indicating that the detection intensity of fluorine ions on the surface of the conductive inorganic layer falls within a specific range,

In an element according to the first aspect of the present invention, preferably at least one of Formulas (ClA-1), (BrA-1), and (SA-1) is satisfied and more preferably at least one of Formulas (ClA-1a), (BrA-1a), and (SA-1a) is satisfied when the detection intensity of chlorine ions (Cl⁻) is represented by (Cl_{ML}) counts, the detection intensity of bromine ions (Br⁻) is represented by (Br_{ML}) counts, and the detection intensity of sulfur ions (S⁻) is represented by (S_{ML}) counts, which are measured by time-of-flight secondary ion mass spectrometry at a position of 5 nm in depth from the surface of the conductive inorganic layer on the insulating resin layer side in the opening of the insulating resin layer, from the viewpoints of achieving low voltage drive of light emission characteristics, improving the reliability of the light-emitting element, and improving the migration resistance.

The element according to the first aspect of the present invention more preferably satisfies Formula (SA-1), still more preferably satisfies Formula (SA-1) and (ClA-1) and/or (BrA-1), and particularly preferably satisfies Formula (SA-1), (ClA-1), and (BrA-1) from the viewpoint of the effects of the invention described above.

(Cl_{ML})≤200 (ClA-1)

(Br_{ML})≤200 (BrA-1)

(S_{ML})≤200 (SA-1)

2≤(Cl_{ML})≤200 (ClA-1a)

2≤(Br_{ML})≤200 (BrA-1a)

2≤(S_{ML})≤200 (SA-1a).

Formulas (ClA-1), (ClA-1a), (BrA-1), (BrA-1a), (SA-1), and (SA-1a) are each a formula indicating that the detection intensity of chlorine ions, bromine ions, or sulfur ions on the surface of the conductive inorganic layer falls within a specific range.

(F_{ML}) is preferably 0 or more, more preferably 2 or more, still more preferably 4 or more, still more preferably 6 or more, particularly preferably 8 or more, and most preferably 10 or more from the viewpoint of the effects of the invention described above. On the other hand, (FM) is preferably 500 or less, more preferably 300 or less, still more preferably 200 or less, still more preferably 150 or less, and particularly preferably 120 or less from the viewpoint of the effects of the invention described above. Furthermore, (FM) is preferably 100 or less, more preferably 80 or less, still more preferably 60 or less, still more preferably 40 or less, particularly preferably 30 or less, and most preferably 25 or less.

(Cl_{ML}) is preferably 0 or more, more preferably 2 or more, still more preferably 4 or more, still more preferably 6 or more, particularly preferably 8 or more, and most preferably 10 or more from the viewpoint of the effects of the invention described above. On the other hand, (Cl_{ML}) is preferably 200 or less, more preferably 170 or less, still more preferably 150 or less, still more preferably 120 or less, particularly preferably 100 or less from the viewpoint of the effects of the invention described above. Furthermore, (Cl_{ML}) is preferably 80 or less, more preferably 60 or less, still more preferably 40 or less, still more preferably 30 or less, and particularly preferably 25 or less.

The preferred ranges of (Br_{ML}) and (S_{ML}) are also the same as the preferred ranges of (Cl_{ML}) described above, respectively.

With the above configuration, the element according to the first aspect of the present invention can provide a display device having excellent light emission characteristics capable of low voltage drive in obtaining a desired current density and excellent reliability of the light-emitting element. In addition, it is possible to provide an electronic component or a semiconductor device having excellent migration resistance. In the opening of the insulating resin layer, the detection intensity of fluorine ions on the surface of the conductive inorganic layer on the insulating resin layer side is a specific value or less, which indicates that the ratio surface-modified by the fluorine element on the surface of the conductive inorganic layer falls within the specific range. For example, when the conductive inorganic layer is an electrode in a display device, it is considered that excellent light emission characteristics enabling low voltage drive by adjusting a work function difference are achieved, and in addition, an effect of high luminance at the time of driving at the same voltage is achieved. In addition, for example, in a case where the conductive inorganic layer is a metal wiring in a display device, it is considered that the conductivity of the surface-modified metal wiring is controlled to enable low voltage drive, thereby achieving the effect of high luminance.

In addition, by intentionally adjusting the detection intensity of fluorine ions on the conductive inorganic layer, for example, in a case where the conductive inorganic layer is an electrode of a display device, it is considered that the polarization structure and the charge balance on the electrode are controlled. As a result, ion migration and electromigration caused by metal impurities and ion impurities that adversely affect the light emission characteristics are suppressed, so that it is presumed that the effect of high reliability of the light-emitting element is achieved. Similarly, for example, by controlling a polarization structure and a charge balance on a metal wiring line or a rewiring line of a display device, an electronic component, or a semiconductor device, it is presumed that ion migration and electromigration caused by metal impurities and ion impurities that adversely affect electrical characteristics are suppressed, so that an excellent migration resistance effect is achieved. In addition, it is presumed that a highly reliable effect in a display device, an electronic component, or a semiconductor device is achieved by suppressing migration or aggregation of a metal in an electrode or a metal in a metal wiring.

An element according to the second aspect of the present invention satisfies Formula (XA-1), where (F_{ML}) counts is the detection intensity of fluorine ions (F), (Cl_{ML}) counts is the detection intensity of chlorine ions (Cl⁻), (Br_{ML}) counts is the detection intensity of bromine ions (Br⁻), and (X_{ML}) counts is the sum of (F_{ML}), (Cl_{ML}), and (Br_{ML}), measured by time-of-flight secondary ion mass spectrometry at a position of 5 nm in depth from the surface of the conductive inorganic layer on the insulating resin layer side in the opening of the insulating resin layer, and
further, in the insulating resin layer portion, when the detection intensity of fluorine ions (F⁻) measured at a position of 5 nm in depth from the surface of the insulating resin layer by time-of-flight secondary ion mass spectrometry is denoted by (F_{RN}) counts, the detection intensity of chlorine ions (Cl⁻) is denoted by (Cl_{RN}) counts, the detection intensity of bromine ions (Br⁻) is denoted by (Br_{RN}) counts, and the sum of (F_{RN}), (Cl_{RN}), and (Br_{RN}) is denoted by (X_{RN}) counts, Formula (XB-1) is satisfied.

The element according to the second aspect of the present invention preferably further satisfies Formulas (XA-1a) and (XB-1a).

(X_{ML})≤500 (XA-1)

(X_{RN})≤500 (XB-1)

2≤(X_{ML})≤500 (XA-1a)

2≤(X_{RN})≤500 (XB-1a).

Formulas (XA-1) and (XA-1a) are each a formula indicating that the sum of the detection intensities of a fluorine ion, a chlorine ion, and a bromine ion on the surface of the conductive inorganic layer falls within a specific range. Formulas (XB-1) and (XB-1a) are each a formula indicating that the sum of the detection intensities of fluorine ions, chlorine ions, and bromine ions on the surface of the insulating resin layer falls within a specific range.

In the element according to the second aspect of the present invention, from the viewpoints of achieving low voltage drive of light emission characteristics, improving the reliability of the light-emitting element, and improving the migration resistance, when the detection intensity of sulfur ions (S⁻) measured by time-of-flight secondary ion mass spectrometry at a position of 5 nm in depth from the surface of the conductive inorganic layer on the insulating resin layer side in the opening of the insulating resin layer is denoted by (S_{ML}) counts, Formula (SA-1) is satisfied, and
further, when the detection intensity of sulfur ions (S⁻) measured by time-of-flight secondary ion mass spectrometry at a position of 5 nm in depth from the surface of the insulating resin layer in the insulating resin layer part is denoted by (S_{RN}) counts, it is preferable that Formula (SB-1) is satisfied.

The element according to the second aspect of the present invention more preferably further satisfies Formulas (SA-1a) and (SB-1a) from the viewpoint of the effects of the invention described above.

(S_{ML})≤200 (SA-1)

(S_{RN})≤200 (SB-1)

2≤(S_{ML})≤200 (SA-1a)

2≤(S_{RN})≤200 (SB-1a).

Formulas (SB-1) and (SB-1a) are each a formula indicating that the detection intensity of sulfur ions on the surface of the insulating resin layer falls within a specific range.

(X_{ML}) is preferably 0 or more, more preferably 2 or more, still more preferably 4 or more, still more preferably 6 or more, particularly preferably 8 or more, and most preferably 10 or more from the viewpoint of the effects of the invention described above. On the other hand, (X_{ML}) is preferably 500 or less, more preferably 300 or less, still more preferably 200 or less, still more preferably 150 or less, and particularly preferably 120 or less from the viewpoint of the effects of the invention described above. Furthermore, (X_{ML}) is preferably 100 or less, more preferably 80 or less, still more preferably 60 or less, still more preferably 40 or less, particularly preferably 30 or less, and most preferably 25 or less.

Preferred ranges of (F_{ML}), (Cl_{ML}), (Br_{ML}) and (S_{ML}) in the element according to the second aspect of the present invention are also the same as the above preferred ranges in the element according to the first aspect of the present invention.

(X_{RN}) is preferably 0 or more, more preferably 2 or more, still more preferably 4 or more, still more preferably 6 or more, particularly preferably 8 or more, and most preferably 10 or more from the viewpoint of the effects of the invention described above. On the other hand, (X_{RN}) is preferably 500 or less, more preferably 300 or less, still more preferably 200 or less, still more preferably 150 or less, and particularly preferably 120 or less from the viewpoint of the effects of the invention described above. Furthermore, (X_{RN}) is preferably 100 or less, more preferably 80 or less, still more preferably 60 or less, still more preferably 40 or less, particularly preferably 30 or less, and most preferably 25 or less.

(F_{RN}) is preferably 0 or more, more preferably 2 or more, still more preferably 4 or more, still more preferably 6 or more, particularly preferably 8 or more, and most preferably 10 or more from the viewpoint of the effects of the invention described above. On the other hand, (F_{RN}) is preferably 500 or less, more preferably 300 or less, still more preferably 200 or less, still more preferably 150 or less, and particularly preferably 120 or less from the viewpoint of the effects of the invention described above. Furthermore, (F_{RN}) is preferably 100 or less, more preferably 80 or less, still more preferably 60 or less, still more preferably 40 or less, particularly preferably 30 or less, and most preferably 25 or less.

(Cl_{RN}) is preferably 0 or more, more preferably 2 or more, still more preferably 4 or more, still more preferably 6 or more, particularly preferably 8 or more, and most preferably 10 or more from the viewpoint of the effects of the invention described above. On the other hand, (Cl_{RN}) is preferably 200 or less, more preferably 170 or less, still more preferably 150 or less, still more preferably 120 or less, and particularly preferably 100 or less from the viewpoint of the effects of the invention described above. Furthermore, (Cl_{RN}) is preferably 80 or less, more preferably 60 or less, still more preferably 40 or less, still more preferably 30 or less, and particularly preferably 25 or less.

The preferred ranges of (Br_{RN}) and (S_{RN}) are also the same as the preferred ranges of (Cl_{RN}) described above, respectively.

With the above configuration, the element according to the second aspect of the present invention can provide a display device having excellent light emission characteristics capable of low voltage drive in obtaining a desired current density and excellent reliability of the light-emitting element. In addition, it is possible to provide an electronic component or a semiconductor device having excellent migration resistance. In the opening of the insulating resin layer, the sum of the detection intensities of fluorine ions, chlorine ions, and bromine ions on the surface of the conductive inorganic layer on the insulating resin layer side is a specific value or less, which means that the ratio surface-modified with these elements on the surface of the conductive inorganic layer falls within the specific range. That is, even when fluorine ions are not detected on the surface of the conductive inorganic layer, the effect of the present invention is achieved by the configuration of the detection intensity of chlorine ions and bromine ions. In addition, by intentionally adjusting the detection intensity of these ions on the conductive inorganic layer, for example, when the conductive inorganic layer is an electrode of a display device, it is considered that the polarization structure and the charge balance on the electrode are controlled. Therefore, similarly to the element according to the first aspect above, for example, it is considered that the polarization structure and the charge balance on the metal wiring or the rewiring of the display device, the electronic component, or the semiconductor device are controlled. As a result, it is considered that the effects of the invention described above are achieved.

Further, in the insulating resin layer, the sum of the detection intensities of fluorine ions, chlorine ions, and bromine ions on the surface of the insulating resin layer is a specific value or less, which indicates that the abundance ratio of these elements on the surface of the insulating resin layer falls within a specific range or less. That is, even when fluorine ions are not detected on the surface of the insulating resin layer, the effect of the present invention is achieved by the configuration of the detection intensity of chlorine ions and bromine ions. It is also conceivable that these elements on the surface of the insulating resin layer transition to the surface of the conductive inorganic layer on the insulating resin layer side at the opening of the insulating resin layer, whereby the surface of the conductive inorganic layer is surface-modified by these elements. As a result, for example, when the conductive inorganic layer is an electrode or metal wiring in a display device, it is considered that the conductivity in the surface-modified electrode or metal wiring is controlled, and the effect of excellent light emission characteristics and high luminance capable of low voltage drive is achieved. In addition, it is considered that, for example, the polarization structure and the charge balance in the insulating resin layer of the display device, the electronic component, or the semiconductor device are controlled by intentionally adjusting the detection intensity of these ions on the insulating resin layer. As a result, it is presumed that the effect of high reliability or excellent migration resistance of the light-emitting element is achieved by suppressing ion migration and electromigration caused by metal impurities and ion impurities that adversely affect light emission characteristics or electrical insulation properties. In addition, it is presumed that a highly reliable effect in a display device, an electronic component, or a semiconductor device is achieved by suppressing migration or aggregation of a metal in an electrode or a metal in a metal wiring.

The surface of the conductive inorganic layer on the insulating resin layer side in the element of the present invention can be determined by depth measurement in time-of-flight secondary ion mass spectrometry. First, etching ion species accelerated by applying a bias are caused to collide with the opening of the insulating resin layer from the insulating resin layer side, and primary ion species accelerated by applying a bias are caused to collide with the opening of the insulating resin layer from the insulating resin layer side while etching is performed in the depth direction from the conductive inorganic layer side toward the substrate side. The secondary ions released at that time are measured, and a depth profile in the depth direction from the conductive inorganic layer side toward the substrate side is measured. In the depth profile, a point at which the detection intensity of at least one ion among elements contained in the outermost layer on the insulating resin layer side of the conductive inorganic layer is 100 or more is defined as a surface of the conductive inorganic layer. In addition, the depth profile in the depth direction from the conductive inorganic layer side toward the substrate side is measured from the surface of the conductive inorganic layer to the surface opposite to the substrate side, the thickness of the conductive inorganic layer is measured, and a sputter rate of the conductive inorganic layer is calculated from these values, whereby the position of the depth of 5 nm from the surface of the conductive inorganic layer in the depth profile can be obtained.

By the same method, the surface of the insulating resin layer can also be determined by depth measurement in time-of-flight secondary ion mass spectrometry. In the depth profile, a point at which the detection intensity of at least one ion among elements contained in the outermost layer of the insulating resin layer is 100 or more is defined as a surface of the insulating resin layer. In addition, the depth profile in the depth direction from the insulating resin layer side toward the substrate side is measured from the surface of the insulating resin layer to the surface opposite to the substrate side, the thickness of the insulating resin layer is measured, and the sputter rate of the insulating resin layer is calculated from these values, whereby the position at a depth of 5 nm from the surface of the insulating resin layer in the depth profile can be obtained,

By the same method, the surface of the transparent conductive oxide layer containing indium as a main component element on the side in contact with the light-emitting layer in the display device of the present invention described later can also be determined by depth measurement in time-of-flight secondary ion mass spectrometry. In the depth profile, a point at which the detection intensity of indium oxide ions is 100 or more is defined as a surface of the transparent conductive oxide layer including indium as a main component element. In addition, the depth profile in the depth direction from the light-emitting layer side toward the substrate side is measured from the surface of the transparent conductive oxide layer to the surface opposite to the substrate side, the thickness of the transparent conductive oxide layer is measured, and the sputter rate of the transparent conductive oxide layer is calculated from these values, whereby the position at a depth of 5 nm from the surface of the transparent conductive oxide layer containing indium as a main component element in the depth profile can be obtained.

In the depth profile, a point at which the detection intensity of at least one ion among elements contained in the layer located immediately below the first electrode or the layer located immediately below the transparent conductive oxide layer is 100 or more is defined as a surface opposite to the substrate side of the first electrode or a surface opposite to the substrate side of the transparent conductive oxide layer.

The thickness of the first electrode and the thickness of the transparent conductive oxide layer can be measured using TEM or SEM. The thickness of the first electrode and the thickness of the transparent conductive oxide layer can also be determined by the following method. The first electrode or the transparent conductive oxide layer is subjected to elemental composition analysis, and a metal film or an oxide film having the same composition as the elemental composition is formed at a desired thickness. Next, the obtained metal film or oxide film is subjected to depth measurement in time-of-flight secondary ion mass spectrometry to measure the depth profile in the depth direction from the surface of the metal film or oxide film to the surface opposite to the substrate side, and the sputter rate of the metal film or oxide film is calculated from the thickness of the metal film or oxide film. Examples of the method of elemental composition analysis include Rutherford backscattering analysis and other analysis methods.

### <Display Device>

A display device of the present invention includes the element of the present invention. A display device according to a first aspect of the present invention is a display device including the element according to the first aspect of the present invention, further including a second electrode and a light-emitting layer, in which the conductive inorganic layer is a first electrode and the insulating resin layer is a pixel division layer, or further including a first electrode, a second electrode, a pixel division layer, and a light-emitting layer, the insulating resin layer is a TFT planarization layer, and the conductive inorganic layer is a metal wiring layer. A display device according to a second aspect of the present invention is a display device including the element according to the second aspect of the present invention, further including a second electrode and a light-emitting layer, in which the conductive inorganic layer is a first electrode, and the insulating resin layer is a pixel division layer, or further including a first electrode, a second electrode, a pixel division layer, and a light-emitting layer, the insulating resin layer is a TFT planarization layer, and the conductive inorganic layer is a metal wiring layer.

The display device is preferably a flexible display device, and more preferably includes a curved display unit, a display unit including an outward bent surface, or a display unit including an inward bent surface. The display device is preferably an organic EL display, a quantum dot display, a micro light emitting diode (hereinafter, “LED”) display, a mini LED display, or a liquid crystal display.

### <Configuration of Display Device>

The display device of the present invention preferably includes a first electrode, a second electrode, a pixel division layer, and a light-emitting layer on the same substrate. In addition, from the viewpoint of suppressing external light reflection and improving luminance, it is preferable to further include at least one of a linear polarizing plate, a ¼ wavelength plate, and a circularly polarizing plate, or a color filter layer and a black matrix layer. The display device of the present invention preferably has a first electrode, a second electrode, a pixel division layer, a light-emitting layer, a sealing layer, a color filter layer, and a black matrix layer on the same substrate, and more preferably has a first electrode, a second electrode, a pixel division layer, a light-emitting layer, a TFT planarization layer, a metal wiring layer, a sealing layer, a color filter layer, and a black matrix layer on the same substrate. In the display device of the present invention, the first electrode, the light-emitting layer, the second electrode, the sealing layer, and the color filter layer are preferably formed so as to overlap in this order, and the metal wiring layer, the TFT planarization layer, the first electrode, the light-emitting layer, the second electrode, the sealing layer, and the color filter layer are preferably formed so as to overlap in this order. In the display device of the present invention, in a case where these layers are formed on the same substrate, for example, it is possible to suppress light emission defect and the like due to deterioration in positional accuracy between the pixel area and the color filter layer portion, an exposure alignment error, and the like, so that the effects of suppressing a decrease in yield of the panel and improving the reliability of the light-emitting element become remarkable.

In the display device of the present invention, the pixel division layer preferably has a plurality of openings. The display device of the present invention preferably has a plurality of pixel areas in plan view. In a plan view, the pixel area is preferably a portion where the light-emitting layer is formed on the first electrode portion in the opening of the pixel division layer portion. The TFT planarization layer also preferably has a plurality of openings. The surface of the metal wiring layer is preferably exposed at a plurality of openings of the TFT planarization layer.

The display device of the present invention includes the element of the present invention, and preferably further includes a second electrode and a light-emitting layer. The conductive inorganic layer in the element is a first electrode, and the insulating resin layer in the element is a pixel division layer. In addition, it is also preferable that the display device of the present invention includes the element of the present invention, further includes a first electrode, a second electrode, a pixel division layer, and a light-emitting layer. The insulating resin layer in the element is a TFT planarization layer, and the conductive inorganic layer in the element is a metal wiring layer.

### <First Electrode and Second Electrode>

The display device of the present invention preferably has a first electrode and a second electrode. The electrode is required to have excellent electrical characteristics. Composite characteristics are required; for example, in a case where the electrode is used as an anode, holes can be efficiently injected, and on the other hand, in a case where the electrode is used as a cathode, electrons can be efficiently injected. In the display device of the present invention, the first electrode is preferably an anode, and the second electrode is preferably a cathode.

By using a transparent electrode and a non-transparent electrode in combination as the first electrode and the second electrode, light emission in a light-emitting layer described later can be extracted to one side.

A display device having a bottom emission type configuration includes a transparent electrode as a first electrode and a non-transparent electrode as a second electrode. On the other hand, a display device having a top emission type configuration includes a non-transparent electrode as a first electrode and a transparent electrode as a second electrode. The transparent electrode refers to an electrode having a light transmittance of 30% or more at a wavelength of 550 nm, and the non-transparent electrode refers to an electrode having a light transmittance of less than 30% at a wavelength of 550 nm. It is preferable to adjust the transmittance at a wavelength of 550 nm by adjusting the film thickness of the electrode. In order to achieve both composite characteristics, the first electrode is preferably a non-transparent electrode having a multilayer structure. For example, the first electrode may be a non-transparent electrode having a multilayer structure, and a base layer for improving adhesion and corrosion resistance and a reflection adjusting layer for adjusting reflectance may be provided on the substrate side of the first electrode. When the electrode has a single-layer structure, the term “transparent or non-transparent” in the transparent conductive oxide layer, the non-transparent conductive layer, the non-transparent conductive metal layer, the transparent conductive layer, and the transparent conductive metal layer described later means that the transmittance at a wavelength of 550 nm is 30% or more or less than 30% as described above. On the other hand, in a case where the electrode has a multilayer structure, a case where the transmittance at a wavelength of 550 nm is 30% or more as a whole is referred to as transparent, and a case where even one layer among the layers constituting the multilayer structure is less than 30% is referred to as non-transparent. That is, when the multilayer structure has at least one non-transparent conductive layer or non-transparent conductive metal layer, the electrode including the multilayer structure is a non-transparent electrode.

The transmittances of the first electrode and the second electrode can be determined by separating the first electrode or the second electrode from the display device and measuring the first electrode or the second electrode with a single beam using an ultraviolet-visible spectrophotometer. When it is difficult to separate the first electrode or the second electrode from the display device, the transmittances of the first electrode and the second electrode can be obtained by the following method. First, a measurement sample A is obtained by separating the first electrode or the second electrode and at least one layer including a layer in contact with the first electrode or the second electrode from the display device. The measurement sample A is measured with a single beam using an ultraviolet-visible spectrophotometer to obtain an ultraviolet-visible absorption spectrum A. Next, the first electrode or the second electrode is separated or dissolved from the measurement sample A to obtain a measurement sample B. The measurement sample B is measured with a single beam using an ultraviolet-visible spectrophotometer to obtain an ultraviolet-visible absorption spectrum B. The transmittance of the first electrode or the second electrode is calculated from the difference between the obtained ultraviolet-visible absorption spectrum A and the obtained ultraviolet-visible absorption spectrum B. As a method of separating or dissolving the first electrode, the second electrode, or the like, a physical method, an optical method, or a chemical method can be used, and examples thereof include a method of separating by applying an external force, a method of separating by irradiating a laser or an ion beam, and a method of dissolving by using a chemical solution.

The display device of the present invention preferably includes a plurality of first electrode portions in plan view. The above-described first electrode in plan view corresponds to a first electrode portion. The display device of the present invention preferably includes a second electrode portion in plan view. The above-described second electrode in plan view corresponds to the second electrode portion. The display device of the present invention more preferably includes a plurality of second electrode portions.

### <Transparent Conductive Oxide Layer, Non-Transparent Conductive Metal Layer, and Transparent Conductive Metal Layer>

The first electrode has a single-layer structure or a multilayer structure. When the first electrode has a multilayer structure, the first electrode is a transparent electrode or a non-transparent electrode.

When the first electrode has a single-layer structure, the first electrode is preferably a transparent electrode. When the first electrode has a multilayer structure, the first electrode preferably has a transparent conductive oxide layer on the outermost layer on the light-emitting layer side, more preferably has a transparent conductive oxide layer containing In, Sn, Zn, Al, or Ga as a main component element, and still more preferably has a transparent conductive oxide layer containing indium as a main component element. The element as a main component in the transparent conductive oxide layer refers to an element other than oxygen included most on a mass basis in the constituent elements of the transparent conductive oxide layer. The transparent conductive oxide layer is preferably indium tin oxide (hereinafter, ITO) or indium zinc oxide (IZO), more preferably ITO, from the viewpoint of achieving low voltage drive of light emission characteristics and improving the luminance. The transparent conductive oxide layer is preferably an amorphous transparent conductive oxide layer from the viewpoint of achieving low voltage drive of light emission characteristics, improving luminance, and improving the reliability of the light-emitting element. On the other hand, the transparent conductive oxide layer is preferably a polycrystalline transparent conductive oxide layer from the viewpoint of improving the reliability of the light-emitting element.

When the first electrode is used as an anode, the first electrode is preferably ITO or IZO, more preferably ITO, from the viewpoint of achieving low voltage drive of light emission characteristics and improving luminance. When the first electrode is a transparent electrode, it is preferable to adjust the transmittance at a wavelength of 550 nm by adjusting the film thickness of the first electrode.

When the first electrode is a non-transparent electrode having a multilayer structure, the first electrode has a non-transparent conductive layer. The non-transparent conductive layer is preferably a non-transparent conductive metal layer including a metal element. When the first electrode is used as an anode, the non-transparent conductive metal layer preferably includes Ag, Cu, Au, Ti, Al, Ni, Mo, or Cr as a main component element, more preferably includes Ag, Cu, Au, Ti, or Al as a main component element, and still more preferably includes silver or copper as a main component element, from the viewpoint of achieving low voltage drive of light emission characteristics, improvement in luminance, improvement in reliability of the light-emitting element, and improvement in corrosion resistance. The element as the main component in the non-transparent conductive metal layer refers to an element contained in the largest amount on a mass basis in the constituent elements of the non-transparent conductive metal layer. The non-transparent conductive metal layer is preferably provided on at least one of the layers other than the outermost layer on the light-emitting layer side of the first electrode.

When the second electrode has a single-layer structure, the second electrode is preferably a transparent electrode. When the second electrode has a multilayer structure, the second electrode preferably has a transparent conductive metal layer on the outermost layer on the light-emitting layer side, more preferably has a transparent conductive metal layer including Li, Mg, Ag, Cu, Au, Ti, or Al as a main component element, and still more preferably has a transparent conductive metal layer including magnesium or silver as a main component element. The element as a main component in the transparent conductive metal layer refers to an element included most on a mass basis in the constituent elements of the transparent conductive metal layer. The transparent conductive metal layer is preferably LiAg or MgAg, more preferably MgAg, from the viewpoint of improving the luminance.

In the display device of the present invention, it is preferable that the first electrode is a non-transparent electrode having a multilayer structure, and at least one of the layers other than the outermost layer on the light-emitting layer side of the first electrode has a non-transparent conductive metal layer containing silver or copper as a main component element, from the viewpoints of achieving low voltage drive of light emission characteristics, improvement in luminance, improvement in reliability of the light-emitting element, and improvement in corrosion resistance.

In the case of the above configuration, in the display device of the present invention, it is preferable that the first electrode has a transparent conductive oxide layer and a non-transparent conductive metal layer, and the first electrode has a transparent conductive oxide layer containing indium as a main component element on the outermost layer on the light-emitting layer side from the viewpoints of achieving low voltage drive of light emission characteristics, improving the luminance, and improving the reliability of the light-emitting element.

In the case of the above configuration, the transparent conductive oxide layer containing indium as a main component element is preferably amorphous or polycrystalline, and preferably amorphous. It is presumed that the presence of the amorphous transparent conductive oxide layer suppresses the occurrence of defects and protrusions on the surface of the first electrode, so that the effect of improving the reliability of the light-emitting element becomes remarkable. In addition, since the surface modification in the amorphous transparent conductive oxide layer is likely to proceed, it is presumed that the effects of achieving low voltage drive of light emission characteristics and improving the luminance become remarkable by adjusting the work function difference. By having the non-transparent conductive metal layer including silver or copper as a main component element, the light extraction efficiency is improved due to the high reflectance characteristics of these metals, and thus it is presumed that the effect of improving the luminance is remarkable. In addition, since the conductivity is improved by the low resistivity characteristics of these metals, it is presumed that the effects of achieving low voltage drive of light emission characteristics and improving the luminance become remarkable. Due to these effects, the above configuration is particularly suitable in the display device having a top emission type configuration.

### <Detection Intensity of Each Ion on Surface of First Electrode, Surface of Pixel Division Layer, Surface of Metal Wiring Layer, and Surface of TFT Planarization Layer>

In the display device according to the first aspect of the present invention, the following (I-D1) or (II-D1) preferably satisfies the above Formula (FA-1), and more preferably satisfies the above Formula (FA-1a).

In addition, it is preferable that the following (I-D1) or (II-D1) satisfies at least one of the above Formulas (ClA-1), (BrA-1), and (SA-1), and it is more preferable that (I-D1) or (II-D1) satisfies at least one of the above Formulas (ClA-1a), (BrA-1a), and (SA-1a).

In addition, the following (I-D1) or (II-D1) more preferably satisfies above Formula (SA-1), still more preferably satisfies above Formulas (SA-1) and (ClA-1) and/or (BrA-1), and particularly preferably satisfies above Formulas (SA-1), (ClA-1), and (BrA-1).
(I-D1) Detection intensity of fluorine ions, detection intensity of chlorine ions, detection intensity of bromine ions, and detection intensity of sulfur ions measured by time-of-flight secondary ion mass spectrometry at a position of 5 nm in depth from the surface of the first electrode on the side in contact with the light-emitting layer in the opening of the pixel division layer.
(II-D1) Detection intensity of fluorine ions, detection intensity of chlorine ions, detection intensity of bromine ions, and detection intensity of sulfur ions measured by time-of-flight secondary ion mass spectrometry at a position of 5 nm in depth from the surface of the metal wiring layer on the TFT planarization layer side in the opening of the TFT planarization layer.

In the display device according to the second aspect of the present invention, when the above (I-D1) satisfies each of the above formulas in the display device according to the first aspect, the following (I-D2) preferably satisfies the above Formulas (XA-1) and (XB-1), and more preferably satisfies the above Formulas (XA-1a) and (XB-1a).

In the display device according to the second aspect of the present invention, when the above (II-D1) satisfies each of the above formulas in the display device according to the first aspect, the following (II-D2) preferably satisfies the above Formulas (XA-1) and (XB-1), and more preferably satisfies the above Formulas (XA-1a) and (XB-1a).
(I-D2) The sum of the detection intensity of fluorine ions, the detection intensity of chlorine ions, and the detection intensity of bromine ions, and the detection intensity of sulfur ions measured by time-of-flight secondary ion mass spectrometry at a position of 5 nm in depth from the surface of the pixel division layer in the pixel division layer portion.
(II-D2) The sum of the detection intensity of fluorine ions, the detection intensity of chlorine ions, and the detection intensity of bromine ions, and the detection intensity of sulfur ions measured by time-of-flight secondary ion mass spectrometry at a position of 5 nm in depth from the surface of the TFT planarization layer in the TFT planarization layer portion.

### <Detection Intensity of Indium Oxide Ions on Surface of First Electrode>

In a case where the display device according to a first aspect of the present invention includes a second electrode and a light-emitting layer, the conductive inorganic layer is a first electrode, the insulating resin layer is a pixel division layer, and a transparent conductive oxide layer including indium as a main component element is provided on an outermost layer on a light-emitting layer side of the first electrode, from the viewpoints of achieving low voltage drive of light emission characteristics, improving reliability of the light-emitting element, and improving migration resistance,
when the detection intensity of indium oxide ions (InO₂⁻) measured by time-of-flight secondary ion mass spectrometry at a position of 5 nm in depth from the surface of the transparent conductive oxide layer on the side in contact with the light-emitting layer in the opening of the pixel division layer is denoted by (InO_{ML}) counts, it is preferable to satisfy Formulas (FA-2) and (InA-1), and it is more preferable to satisfy Formulas (FA-2a) and (InA-1).

(F_{ML})/(InO_{ML})≤0.5000 (FA-2)

1,000≤(InO_{ML})≤40,000 (InA-1)

0.0001≤(F_{ML})/(InO_{ML})≤0.5000 (FA-2a).

In a case of the above configuration, the display device according to the first aspect of the present invention includes a transparent conductive oxide layer containing indium as a main component element and having a thickness of 5 nm or more on the outermost layer on the light-emitting layer side of the first electrode in the pixel area. Formula (InA-1) is a formula indicating that the detection intensity of indium oxide ions on the surface of the transparent conductive oxide layer falls within a specific range. In the pixel area, the higher the detection intensity of indium oxide ions on the surface of the transparent conductive oxide film on the side in contact with the light-emitting layer, the higher the ratio at which the surface of the transparent conductive oxide layer containing indium as a main component element is exposed.

The display device according to the first aspect of the present invention satisfies the above Formulas (FA-2) and (InA-1), preferably satisfies at least one of Formulas (ClA-2), (BrA-2), and (SA-2), and more preferably satisfies at least one of Formulas (ClA-2a), (BrA-2a), and (SA-2a), from the viewpoint of achieving low voltage drive of light emission characteristics, improving the reliability of the light-emitting element, and improving the migration resistance.

The display device according to the first aspect of the present invention more preferably satisfies Formula (SA-2), still more preferably satisfies Formulas (SA-2) and (ClA-2) and/or (BrA-2), and particularly preferably satisfies Formulas (SA-2), (ClA-2), and (BrA-2) from the viewpoint of the effects of the invention described above.

(Cl_{ML})/(InO_{ML})≤0.2000 (ClA-2)

(Br_{ML})/(InO_{ML})≤0.2000 (BrA-2)

(SMI)/(InO_{ML})≤0.2000 (SA-2)

0.0001≤(Cl_{ML})/(InO_{ML})≤0.2000 (ClA-2a)

0.0001≤(Br_{ML})/(InO_{ML})≤0.2000 (BrA-2a)

0.0001≤(SMI)/(InO_{ML})≤0.2000 (SA-2a).

(InO_{ML}) is more preferably 1,500 or more, and still more preferably 2, 000 or more from the viewpoint of the effects of the invention described above. On the other hand, (InO_{ML}) is preferably 30, 000 or less, more preferably 20,000 or less, still more preferably 15, 000 or less, and particularly preferably 10,000 or less from the viewpoint of the effects of the invention described above. Furthermore, (InO_{ML}) is preferably 7, 500 or less, more preferably 6,000 or less, still more preferably 5, 000 or less, still more preferably 4,000 or less, and particularly preferably 3,500 or less.
(F_{ML})/(InO_{ML}) is preferably 0 or more, more preferably 0.0001 or more, still more preferably 0.0003 or more, still more preferably 0.0005 or more, and particularly preferably 0.0010 or more from the viewpoint of the effects of the invention described above. Furthermore, (F_{ML})/(InO_{ML}) is preferably 0.0020 or more, more preferably 0.0040 or more, still more preferably 0.0060 or more, still more preferably 0.0080 or more, and particularly preferably 0.0100 or more. On the other hand, (F_{ML})/(InO_{ML}) is preferably 0.5000 or less, more preferably 0.3000 or less, still more preferably 0.2000 or less, still more preferably 0.1500 or less, and particularly preferably 0.1200 or less from the viewpoint of the effects of the invention described above. Furthermore, (F_{ML})/(InO_{ML}) is preferably 0.1000 or less, more preferably 0.0800 or less, still more preferably 0.0600 or less, still more preferably 0.0400 or less, particularly preferably 0.0300 or less, and most preferably 0.0250 or less.
(Cl_{ML})/(InO_{ML}) is preferably 0 or more, more preferably 0.0001 or more, still more preferably 0.0003 or more, still more preferably 0.0005 or more, and particularly preferably 0.0010 or more from the viewpoint of the effects of the invention described above. Furthermore, (Cl_{ML})/(InO_{ML}) is preferably 0.0020 or more, more preferably 0.0040 or more, still more preferably 0.0060 or more, still more preferably 0.0080 or more, and particularly preferably 0.0100 or more. On the other hand, (Cl_{ML})/(InO_{ML}) is preferably 0.2000 or less, more preferably 0.1700 or less, still more preferably 0.1500 or less, and particularly preferably 0.1200 or less from the viewpoint of the effects of the invention described above. Furthermore, (Cl_{ML})/(InO_{ML}) is preferably 0.1000 or less, more preferably 0.0800 or less, still more preferably 0.0600 or less, still more preferably 0.0400 or less, particularly preferably 0.0300 or less, and most preferably 0.0250 or less.

The preferred ranges of (Br_{ML})/(InO_{ML}) and (S_{ML})/(InO_{ML}) are also the same as the preferred ranges of (Cl_{ML})/(InO_{ML}) described above, respectively.

The display device according to a second aspect of the present invention includes a second electrode and a light-emitting layer from viewpoints of achieving low voltage drive of light emission characteristics, improving reliability of a light-emitting element, and improving migration resistance, in which the conductive inorganic layer is a first electrode, and the insulating resin layer is a pixel division layer, and
when the detection intensity of indium oxide ions (InO₂⁻) measured by time-of-flight secondary ion mass spectrometry at a position of 5 nm in depth from the surface of the transparent conductive oxide layer on the side in contact with the light-emitting layer in the opening of the pixel division layer is denoted by (InO_{ML}) counts,
it is preferable to satisfy Formulas (XA-2) and (InA-1), and it is more preferable to satisfy Formulas (XA-2a) and (InA-1).

(X_{ML})/(InO_{ML})≤0.5000 (XA-2)

1,000≤(InO_{ML})≤40,000 (InA-1)

0.0001≤(X_{ML})/(InO_{ML})≤0.5000 (XA-2a).

In the case of the above configuration, the display device according to the second aspect of the present invention includes a transparent conductive oxide layer containing indium as a main component element and having a thickness of 5 nm or more on the outermost layer on the light-emitting layer side of the first electrode in the pixel area. Formula (InA-1) is a formula indicating that the detection intensity of indium oxide ions on the surface of the transparent conductive oxide layer falls within a specific range. In the pixel area, the higher the detection intensity of indium oxide ions on the surface of the transparent conductive oxide film on the side in contact with the light-emitting layer, the higher the ratio at which the surface of the transparent conductive oxide layer containing indium as a main component element is exposed.

The display device according to the second aspect of the present invention satisfies the above Formula (XA-2) and (InA-1), preferably satisfies Formula (SA-2), and more preferably satisfies Formula (SA-2a) from the viewpoint of achieving low voltage drive of light emission characteristics, improving reliability of a light-emitting element, and improving migration resistance.

(S_{ML})/(InO_{ML})≤0.2000 (SA-2)

0.0001≤(S_{ML})/(InO_{ML})≤0.2000 (SA-2a).
(X_{ML})/(InO_{ML}) is preferably 0 or more, more preferably 0.0001 or more, still more preferably 0.0003 or more, still more preferably 0.0005 or more, and particularly preferably 0.0010 or more. Furthermore, (X_{ML})/(InO_{ML}) is preferably 0.0020 or more, more preferably 0.0040 or more, still more preferably 0.0060 or more, still more preferably 0.0080 or more, and particularly preferably 0.0100 or more. On the other hand, (X_{ML})/(InO_{ML}) is preferably 0.5000 or less, more preferably 0,3000 or less, still more preferably 0.2000 or less, still more preferably 0.1500 or less, and particularly preferably 0.1200 or less. Furthermore, (X_{ML})/(InO_{ML}) is preferably 0.1000 or less, more preferably 0.0800 or less, still more preferably 0.0600 or less, still more preferably 0.0400 or less, and particularly preferably 0.0300 or less, and most preferably 0.0250 or less.

Preferred ranges of (InO_{ML}), (F_{ML})/(InO_{ML}), (Cl_{ML})/(InO_{ML}), (Br_{ML})/(InO_{ML}), and (SMI)/(InO_{ML}) in the display device according to the second aspect of the present invention are also the same as the above preferred ranges in the display device according to the first aspect of the present invention.

### <Detection Intensity of Carbon Ion and Cyanide Ion on Surface of Conductive Inorganic Layer>

The element of the present invention preferably satisfies Formulas (CA-1) and/or (CNA-1) when the detection intensity of carbon ions (C⁻) measured by time-of-flight secondary ion mass spectrometry at a position of 5 nm in depth from the surface of the conductive inorganic layer on the insulating resin layer side in the opening of the insulating resin layer is denoted by (C_{ML}) counts and the detection intensity of cyanide ions (CN⁻) is denoted by (CN_{ML}) counts, from the viewpoint of achieving low voltage drive of light emission characteristics, improving the reliability of the light-emitting element, and improving the migration resistance.

20≤(CML)≤4,000 (CA-1)

20≤(CN_{ML})≤4,000 (CNA-1).

(C_{ML}) is preferably 50 or more, more preferably 75 or more, still more preferably 100 or more. On the other hand, (C_{ML}) is preferably 3,000 or less, more preferably 2,000 or less, still more preferably 1, 000 or less. The preferred range of (CN_{ML}) is also the same as the preferred range of (C_{ML}) described above.

Formulas (CA-1) and (CNA-1) are each a formula indicating that the detection intensity of carbon ions or cyanide ions on the surface of the conductive inorganic layer falls within a specific range. In the opening of the insulating resin layer, the higher the detection intensity of carbon ions on the surface of the conductive inorganic layer on the insulating resin layer side, the higher the abundance ratio of carbon atoms on the surface of the conductive inorganic layer. The higher the detection intensity of cyanide ions, the higher the abundance ratio of carbon atoms bonded to nitrogen atoms on the surface of the conductive inorganic layer.

In a case where the display device of the present invention includes a second electrode and a light-emitting layer, the conductive inorganic layer is a first electrode, the insulating resin layer is a pixel division layer, and a transparent conductive oxide layer including indium as a main component element is provided on the outermost layer on the light-emitting layer side of the first electrode, from the viewpoints of achieving low voltage drive of light emission characteristics, improving reliability of the light-emitting element, and improving migration resistance,
when the detection intensity of carbon ions measured by time-of-flight secondary ion mass spectrometry at a position of 5 nm in depth from the surface of the transparent conductive oxide layer on the side in contact with the light-emitting layer in the opening of the pixel division layer is denoted by (C_{ML}) counts and the detection intensity of cyanide ions is denoted by (C_{ML}) counts, it is preferable that Formulas (CA-2) and/or (CNA-2) be further satisfied, and Formula (InA-1) be satisfied.

0.001≤(C_{ML})/(InO_{ML})≤4.0 (CA-2)

0.001≤(CN_{ML})/(InO_{ML})≤4.0 (CNA-2)

1,000≤(InO_{ML})≤40, 000 (InA-1).

(C_{ML})/(InO_{ML}) is preferably 0.003 or more, more preferably 0.005 or more, still more preferably 0.010 or more, and particularly preferably 0.020 or more. Furthermore, (C_{ML})/(InO_{ML}) is preferably 0.050 or more, more preferably 0.075 or more, still more preferably 0.100 or more. On the other hand, (C_{ML})/(InO_{ML}) is preferably 3.0 or less, more preferably 2.0 or less, still more preferably 1.0 or less.

The preferable range of (CN_{ML})/(InO_{ML}) is also the same as the preferable range of (C_{ML})/(InO_{ML}) described above. The preferred range of (InO_{ML}) is as described above.

### <Pixel Division Layer>

The display device of the present invention preferably includes a pixel division layer. The pixel division layer is a layer that divides adjacent pixel areas and defines a region of each pixel area. The pixel division layer is preferably a layer that divides a region on the first electrode. The pixel division layer is preferably formed so as to overlap a part of the first electrode. With such a configuration, the first electrode and the second electrode in an arbitrary pixel can be insulated from each other, and the first electrodes between a plurality of adjacent pixels can be insulated from each other. The pixel division layer is preferably formed of a cured product obtained by curing the photosensitive composition. The pixel division layer is preferably black. The pixel division layer can be made black by coloring components such as a resin in the photosensitive composition.

The display device of the present invention preferably includes a pixel division layer portion having a plurality of openings in plan view. The above-described pixel division layer in plan view corresponds to a pixel division layer portion. The shape of the pixel area to be described later is preferably a shape resembling or similar to the shape of the opening of the pixel division layer portion, and is more preferably the same as the shape of the opening of the pixel division layer portion. The shape of the pixel area in a plan view is preferably a closed polygon, a shape in which at least some sides and/or vertices are replaced with an arc from the closed polygon, or a closed shape formed by an arc, Examples of the closed polygon include a triangle, an equilateral triangle, a quadrangle, a square, a rhombus, a rectangle, a pentagon, a regular pentagon, a right pentagon, a hexagon, a regular hexagon, a right hexagon, a heptagon, or an octagon. Examples of the closed shape formed by an arc include a circular shape, a perfect circular shape, and an elliptical shape.

### <Step Shape Having Thick Film Portion and Thin Film Portion>

In the display device of the present invention, from the viewpoint of improving the reliability of the light-emitting element, the pixel division layer preferably has a step shape having a thick film portion and a thin film portion. Since the pixel division layer has the thick film portion and the thin film portion, only the thick film portion of the pixel division layer is in contact with a deposition mask when the light-emitting layer is formed, and the contact area between the pixel division layer and the deposition mask can be reduced. Therefore, the damage of the pixel division layer can be suppressed, and the effects of suppressing the decrease in the yield of the panel and improving the reliability of the light-emitting element become remarkable. In addition, since the thin film portion has a light-shielding property, outgassing from the pixel division layer and the film below the pixel division layer is suppressed, so that the effect of improving the reliability of the light-emitting element becomes remarkable. In addition, in the display device of the present invention, from the viewpoint of suppressing external light reflection and improving the reliability of the light-emitting element, it is preferable that the thin film portion includes the (XD) colorant, and the optical density at the wavelength of visible light per film thickness of 1 μm of the thin film portion is 0.5 or more and 3.0 or less.

In the display device of the present invention, it is preferable that the pixel division layer has a step shape having a thick film portion and a thin film portion, and the thick film portion and the thin film portion include the same (XA) resin, from the viewpoints of achieving low voltage drive of light emission characteristics, improving reliability of a light-emitting element, and improving migration resistance. In addition, in the display device of the present invention, it is also preferable that the pixel division layer has a step shape having a thick film portion and a thin film portion, the thick film portion and the thin film portion include the same (XD) colorant, and the optical density of each of the thick film portion and the thin film portion at the wavelength of visible light per film thickness of 1 μm is 0.5 or more and 3.0 or less from the similar viewpoint of the effect of the present invention. The same (XA) resin refers to a resin in which structural units constituting the resin have the same structure. That is, resins in which amine residues, carboxylic acid residues, and the like in the structural unit of the resin have the same structure are defined as the same (XA) resin.

In a case of the above configuration, it is preferable that the pixel division layer is a cured product obtained by curing a single photosensitive composition, and the thick film portion and the thin film portion of the pixel division layer are formed by a method of collectively processing a step shape using a halftone photomask. In this case, the thick film portion and the thin film portion have the same degree of crosslinking, and the gradient of the degree of crosslinking in the film is uniform. Therefore, it is considered that the occurrence of fine cracks and the occurrence of fine coarse and dense structures in the film due to the difference in thermal expansion coefficient between the thick film portion and the thin film portion are suppressed, and the polarization structure and the charge balance in the film are controlled. As a result, it is presumed that the effect of improving the reliability or migration resistance of the light-emitting element becomes remarkable by suppressing ion migration and electromigration caused by metal impurities and ion impurities that adversely affect the light emission characteristics or electrical insulation properties. In addition, it is considered that residue generation after thermal curing due to outgas or the like from the pixel division layer is suppressed by suppressing generation of fine cracks and suppressing generation of fine coarse and dense structures in the film. Therefore, it is presumed that the surface modification action on the surface of the first electrode is promoted by suppressing the residue on the surface of the first electrode in the opening of the pixel division layer, and the effects of achieving low voltage drive of light emission characteristics and improving the luminance become remarkable.

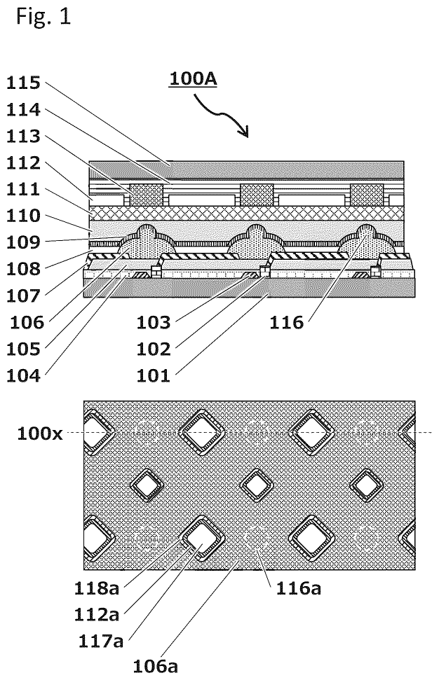

FIG. 1 illustrates a schematic cross-sectional view and a plan view illustrating an example of a display device 100A in which a pixel division layer has a thick film portion and a thin film portion and has a step shape. The cross-sectional view in FIG. 1 is a cross-sectional view taken along a cross-sectional axis 100x in the plan view. Metal wiring 102 and a TFT element layer 103 are formed on a substrate 101, and an interlayer insulating layer 104 and a TFT planarization layer/TFT protective layer 105 are formed thereon in this order. On the TFT planarization layer/TFT protective layer 105, a pixel division layer 106 having a step shape and a first electrode 107 are formed such that the pixel division layer 106 divides the first electrode 107, and such that the pixel division layer 106 overlaps a part of the first electrode 107. The pixel division layer 106 includes a thick film portion 116. A light-emitting layer 108, the second electrode 109, the sealing layer 110, the touch panel wiring/touch panel electrode 111, the color filter layer 112, the black matrix layer 113, an overcoat layer 114, and a substrate 115 are further formed in this order thereon. In addition, a color filter layer portion 112a, an opening 117a of a pixel division layer portion, and an opening 118a of a black matrix layer portion are formed in a portion corresponding to the pixel area in plan view.

The thick film portion and/or the thin film portion of the pixel division layer is preferably black. The optical density of the thick film portion and the thin film portion at a wavelength of visible light per film thickness of 1 μm is preferably 0.5 or more, more preferably 0.7 or more, still more preferably 1.0 or more, still more preferably 1.2 or more, and particularly preferably 1, 5 or more from the viewpoint of suppressing external light reflection and improving the reliability of the light-emitting element. On the other hand, the optical density is preferably 3.0 or less, more preferably 2.5 or less, and still more preferably 2.0 or less from the viewpoint of achieving low voltage drive of light emission characteristics. The optical density is preferably an optical density in a cured product obtained by heating and curing the composition.

In the display device of the present invention, the pixel division layer has a step shape having a thick film portion and a thin film portion from the viewpoints of achieving low voltage drive of light emission characteristics, improving reliability of a light-emitting element, and improving migration resistance, and
it is preferable that the thin film portion includes the (XD) colorant, the optical density of the thin film portion at a wavelength of visible light per 1 μm of film thickness is 0.5 or more and 3.0 or less, and the thick film portion satisfies at least one of the following conditions (SP1) to (SP3).
(SP1) Thick film portion does not include (XD) colorant.
(SP2) The thick film portion includes an (XD) colorant, and the thick film portion has an optical density of 0.0 or more and 0.3 or less at a wavelength of visible light per 1 μm of film thickness.
(SP3) The thick film portion includes (XC1x) compound: one or more compounds selected from the group consisting of carboxylic acid having an indene structure, carboxylic acid ester having an indene structure, sulfonic acid having an indene structure, and sulfonic acid aryl ester having an indene structure.

In this case, the pixel division layer is preferably a cured product obtained by curing at least two photosensitive compositions in which the thick film portion and the thin film portion of the pixel division layer have different compositions. In addition, it is preferable that the thick film portion and the thin film portion of the pixel division layer are formed by a method of forming two layers. When the above condition (SP1) or (SP2) is satisfied, it is preferable that the content of the (XD) colorant is smaller in the thick film portion than in the thin film portion, and/or the content of the (XA) resin is larger in the thick film portion than in the thin film portion. When the above condition (SP3) is satisfied, the thick film portion is preferably a cured product obtained by curing the positive type photosensitive composition. When the pixel division layer is formed by a two-layer film forming method, the opening of the pixel division layer comes into contact with the alkaline developer twice, so that it is presumed that the surface modification action on the surface of the first electrode is promoted by suppressing the residue on the surface of the first electrode, and the effects of achieving low voltage drive of light emission characteristics and improving the luminance become remarkable. In particular, when the thick film portion is formed of a positive type photosensitive composition, the opening of the pixel division layer is accelerated by alkali dissolution by exposure, so that the effects of the invention described above become remarkable. In addition, since the thin film portion is formed not by halftone exposure but by full-tone exposure, the degree of crosslinking in the film can be maintained high even when either a negative type or a positive type is used. In addition, when the above condition (SP1) or (SP2) is satisfied, the gradient of the degree of crosslinking in the film can be minimized. Therefore, it is considered that the polarization structure and the charge balance in the film are controlled in the same manner as described above, and as a result, it is presumed that the effect of improving the reliability or migration resistance of the light-emitting element becomes remarkable. When the thick film portion is formed of the positive type photosensitive composition, the effects of the invention described above become remarkable by forming a crosslink with the thin film portion by the positive type photosensitive composition.

### <(XA) Resin in Insulating Resin Layer>

In the element of the present invention, the insulating resin layer preferably includes (XA) resin. The (XA) resin in the insulating resin layer is preferably the (A) binder resin described later, and a resin having a structure derived from the (A) binder resin is also preferable. The (XA) resin preferably has one or more groups selected from the group consisting of (WA) weakly acidic groups: a phenolic hydroxyl group, a hydroxyimide group, a hydroxyamide group, a silanol group, and a mercapto group, and more preferably has (WA) weakly acidic groups in the structural unit of the resin, from the viewpoint of achieving low voltage drive of light emission characteristics. As the (WA) weakly acidic group, a phenolic hydroxyl group or a silanol group is preferable, and a phenolic hydroxyl group is more preferable from the viewpoint of achieving low voltage drive of light emission characteristics. The (XA) resin having a (WA) weakly acidic group may be referred to as a (XA1) weakly acidic group-containing resin.

From the viewpoint of achieving low voltage drive of light emission characteristics, improving the reliability of light-emitting elements, and improving migration resistance, the insulating resin layer of the element of the present invention preferably includes an (XA1x) resin: a resin having one or more structures selected from the group consisting of an imide structure, an amide structure, an oxazole structure, and a siloxane structure (hereinafter, “imide structure and the like”) in the structural unit of the resin, and/or an (XA1y) resin; a resin having a phenolic hydroxyl group in the structural unit of the resin. In the element of the present invention, the (XA1x) resin preferably has the (WA) weakly acidic group from the viewpoint of the effects of the invention described above. In the element of the present invention, it is also preferable that the (XA1) weakly acidic group-containing resin includes the (XA1x) resin and/or the (XA1y) resin from the viewpoint of the effects of the invention described above.

Both the structural unit having an imide structure and the like and the structural unit having a phenolic hydroxyl group are structural units constituting a resin, and are repeating units having two or more repeating units. The number of repetitions of these units is preferably 2 or more, more preferably 5 or more, and still more preferably 10 or more. On the other hand, the number of repetitions is preferably 1,000 or less. The number of repetitions of these units is preferably 2 or more, more preferably 5 or more, and still more preferably 10 or more. On the other hand, the number of repetitions is preferably 1, 000 or less.

In the element of the present invention, the insulating resin layer more preferably includes a (XA1x) resin from the viewpoint of the effects of the invention described above. The (XA1x) resin preferably includes one or more resins selected from the group consisting of a polyimide, a polyimide precursor, a polybenzoxazole, a polybenzoxazole precursor, a polyamideimide, a polyamideimide precursor, a polyamide, a polysiloxane, a maleimide resin, a maleimide-styrene resin, a maleimide-triazine resin, a maleimide-oxazine resin, and copolymers thereof, and more preferably includes one or more resins selected from the group consisting of a polyimide, a polyimide precursor, a polybenzoxazole, a polybenzoxazole precursor, a polyamideimide, a polyamideimide precursor, and copolymers thereof (hereinafter, “polyimide-based resin”). The (XA1x) resin further preferably includes two or more resins selected from the group consisting of polyimide-based resins, and particularly preferably contains a polyimide precursor and a polybenzoxazole precursor. In the element of the present invention, the (XA1) weakly acidic group-containing resin more preferably includes the (XA1x) resin from the viewpoint of the effects of the invention described above. When the polyimide-based resin has the (WA) weakly acidic group, it may be referred to as a polyimide-based resin having a weakly acidic group.

Examples of the polyimide precursor include a polyamic acid, a polyamic acid ester, a polyamic acid amide, and a polyisoimide. Examples of the polyimide include a resin obtained by dehydrating and cyclizing a polyimide precursor. Examples of the polybenzoxazole precursor include polyhydroxyamides. Examples of the polybenzoxazole include a resin obtained by dehydrating and cyclizing a polybenzoxazole precursor. Examples of the polyamideimide precursor include a resin obtained by reacting a tricarboxylic anhydride or the like with a diamine or the like. Examples of the polyamideimide include a resin obtained by dehydrating and cyclizing a polyamideimide precursor. Examples of the polyamide include a resin obtained by reacting a dicarboxylic acid chloride or the like with a diamine or the like. The polyimide-based resin and the polyimide-based resin having a weakly acidic group may be further copolymers with polyamides. The (XA1x) resin may be either a single resin or a copolymer thereof.

With the above configuration, it is considered that these resins promote the surface modification action on the surface of the conductive inorganic layer in the opening of the insulating resin layer. Therefore, it is presumed that the effects of achieving low voltage drive of light emission characteristics and improving the luminance become remarkable. In addition, since these resins are excellent in heat resistance and low outgassing properties as compared with general resins, the effects of improving the reliability and migration resistance of the light-emitting element become remarkable.

The polyimide-based resin having a weakly acidic group preferably has an amine residue having a phenolic hydroxyl group. The amine residue having a phenolic hydroxyl group more preferably has at least two cyclic structures having a phenolic hydroxyl group. The polyimide-based resin having a weakly acidic group also preferably has an amine residue having two or more phenolic hydroxyl groups. The cyclic structure is preferably an aromatic structure or a condensed polycyclic structure, and more preferably an aromatic structure having 6 to 15 carbon atoms or a condensed polycyclic structure having 6 to 20 carbon atoms, from the viewpoint of improving the reliability and migration resistance of the light-emitting element. The aromatic structure is preferably a biphenyl structure or a benzene structure. The condensed polycyclic structure is preferably a fluorene structure, an anthracene structure, or a naphthalene structure. The phenolic hydroxyl group in the amine residue having a phenolic hydroxyl group may react with a structure and/or a group in the resin to form a benzoxazole ring. That is, in the resin having a benzoxazole ring in the structural unit of the resin, the benzoxazole ring may have an amine residue having a phenolic hydroxyl group,

### <Amine Residue Having Phenolic Hydroxyl Group>

The (XA1x) resin preferably has an amine residue having a phenolic hydroxyl group. When the insulating resin layer includes the (XA1x) resin and the (XA1x) resin includes one or more resins selected from the group consisting of polyimide-based resins, the (XA1x) resin preferably has an amine residue having a phenolic hydroxyl group. The (XA1x) resin also preferably has an amine residue having two or more phenolic hydroxyl groups,

The amine residue having a phenolic hydroxyl group preferably has an amine residue (hereinafter, “a specific amine residue having a phenolic hydroxyl group”) satisfying the following conditions (XS1x) from the viewpoint of achieving low voltage drive of light emission characteristics, improving reliability of a light-emitting element, and improving migration resistance. The specific amine residue having a phenolic hydroxyl group is more preferably an amine residue that further satisfies the following condition (XS1y), and still more preferably an amine residue that further satisfies the following condition (XS1z).
(XS1x) The amine residue has a C₁ symmetry axis as a molecular symmetry and does not have a C₂ symmetry axis.
(XS1y) The amine residue has a C₁ symmetry axis as the molecular symmetry and does not have a C₂ symmetry axis or a C₃ symmetry axis.
(XS1z) The amine residue has a C₁ symmetry axis as a molecular symmetry, and has no symmetry axis other than the C₁ symmetry axis.

The amine residue in the amine residue having a phenolic hydroxyl group is as described above. The molecular symmetry of the amine residue under the conditions (XS1x) to (XS1z) refers to the molecular symmetry of the amine residue when the amine residue included in the (XA) resin in the insulating resin layer is regarded as a molecule. Examples of the molecular symmetry include a symmetry axis, a symmetry plane, a symmetry center, and a roto-reflection axis. The above conditions (XS1x) to (XS1z) shall be considered with respect to the symmetry axis among these molecular symmetries.

Having a Cₓ symmetry axis as the molecular symmetry under the above conditions (XS1x) to (XS1z) means that the three-dimensional structure before rotation and the three-dimensional structure after rotation are the same in the three-dimensional structure of the target molecule when the target molecule is rotated by (360/x)° with respect to an arbitrary axis. Note that x represents an integer of 1 or more. That is, having the C₁ symmetry axis as the molecular symmetry means that the three-dimensional structures are the same before and after being rotated by 360° with respect to an arbitrary axis. Having a C₂ symmetry axis as the molecular symmetry means that the three-dimensional structures are the same before and after being rotated by 180° with respect to an arbitrary axis. Having a C₃ symmetry axis as the molecular symmetry means that the three-dimensional structures are the same before and after being rotated by 120° with respect to an arbitrary axis. In addition, having no symmetry axis other than the C₁ symmetry axis as the molecular symmetry means having no Cₓ symmetry axis (1<x≤360) such as the C₂ symmetry axis (axis having the same three-dimensional structure before and after being rotated by 180°) or the C₃ symmetry axis (axis having the same three-dimensional structure before and after being rotated by) 120°.

When considering the symmetry axis in the molecular symmetry of the amine residue under the above conditions (XS1x) to (XS1z) relating to the amine residue having a phenolic hydroxyl group, the three-dimensional structure before rotation of the target amine residue shall take into account all possible conformations as a molecule. That is, in the three-dimensional structure before rotation, when at least one of the possible conformations of the amine residue of interest as a molecule has a C₂ symmetry axis, the above condition (XS1x) is not satisfied, when at least one has a C₂ symmetry axis or a C₃ symmetry axis, the above condition (XS1y) is not satisfied, and when at least one has a Cₓ symmetry axis (1<x≤360), the above condition (XS1z) is not satisfied.

It is also preferable that the amine residue having a phenolic hydroxyl group has an amine residue including at least one of an asymmetric center, an asymmetric axis, an asymmetric plane, and a helical axis.

When the amine residue having a phenolic hydroxyl group has the above configuration, the amine residue having a phenolic hydroxyl group has an asymmetric structure having no C₂ symmetry axis, so that the symmetry of the (XA) resin in the insulating resin layer is reduced. Therefore, it is considered that the orientation and stacking of the (XA) resin in the insulating resin layer are suppressed. As a result, it is presumed that by improving the solubility of the (XA) resin, the residue generation after development at the time of patterning of the insulating resin layer is suppressed, the surface modification action on the substrate surface by the fluorine element, fluoride ions, or the like described above is promoted, and the effect of achieving low voltage drive of light emission characteristics becomes remarkable. In addition, it is considered that the control of the polarization structure and the charge balance in the cured product by the fluorine element, the fluoride ion, or the like described above is promoted. As a result, it is presumed that the ion migration and the electromigration are suppressed, and the effect of improving the reliability and the migration resistance of the light-emitting element becomes remarkable.

The amine residue having a phenolic hydroxyl group preferably has an amine residue represented by Formula (31) emission characteristics, improving reliability of a light-emitting element, and improving migration resistance.

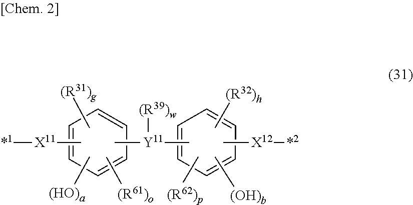

In Formula (31), R³¹ and R³² each independently represent a carboxy group, a mercapto group, or a sulfonic acid group. R³⁹ represents a hydrocarbon group, a hydrocarbon group containing an ether bond, or a hydrocarbon group containing a carbonyl group. R⁶¹ and R⁶² each independently represent an alkyl group having 1 to 10 carbon atoms, a cycloalkyl group having 4 to 10 carbon atoms, an aryl group having 6 to 15 carbon atoms, an alkenyl group having 2 to 10 carbon atoms, an alkoxy group having 1 to 10 carbon atoms, an alkenyloxy group having 2 to 10 carbon atoms, or an acyl group having 1 to 10 carbon atoms. X¹¹ and X¹² each independently represent a direct bond, a hydrocarbon group, a hydrocarbon group containing an ether bond, or a hydrocarbon group containing a carbonylamide group. Y¹¹ represents a sulfonyl group, an alkylene group, a condensed polycyclic structure, a hydrocarbon group containing an ether bond, a direct bond, an ether bond, a sulfide bond, a carbonyl group, a carboxylic acid ester bond, an amide bond, a urea bond, a urethane bond, a carbonate ester bond, a cycloalkylene group, an arylene group, a condensed polycyclic heterocyclic structure, a hydrocarbon group containing a carbonyloxy group, or a hydrocarbon group containing a carbonylamide group. a and b each independently represent an integer of 1 to 4. g and h each independently represent an integer of 0 to 3. o and p each independently represent an integer of 0 to 3. w represents an integer of 0 to 6. Note that 1≤a+g+o≤4 and 1<b+h+p≤4 are satisfied. *¹ and *² each independently represent a bonding point in the resin.

In formula (31), the hydrocarbon group in R³⁹, the hydrocarbon group containing an ether bond, and the hydrocarbon group containing a carbonyl group are preferably an alkyl group having 1 to 10 carbon atoms, a cycloalkyl group having 4 to 10 carbon atoms, an aryl group having 6 to 15 carbon atoms, or an arylalkyl group having 10 to 20 carbon atoms, more preferably an alkyl group having 1 to 8 carbon atoms, and even more preferably an alkyl group having 1 to 6 carbon atoms. When o represents an integer of 1 to 3, the corresponding R⁶¹ is preferably an alkyl group having 1 to 6 carbon atoms, and more preferably a methyl group, an ethyl group, a propyl group, an isopropyl group, a butyl group, an isobutyl group, or an s-butyl group. When p represents an integer of 1 to 3, the corresponding R⁶² is preferably an alkyl group having 1 to 6 carbon atoms, and more preferably a methyl group, an ethyl group, a propyl group, an isopropyl group, a butyl group, an isobutyl group, or an s-butyl group. It is preferable that at least one of o and p is 1. It is also preferable that o and p are 0, and it is more preferable that o and p are 1. It is also preferable that o represents an integer of 1 to 3 and p is 0, and it is more preferable that o is 1. It is also preferable that o is 0 and p represents an integer of 1 to 3, and it is more preferable that p is 1.

From the viewpoint of satisfying the above condition (XS1x), the chemical structure of R³⁹ preferably satisfies the above condition (XS1x). From the viewpoint of satisfying the above condition (XS1x), it is also preferable to satisfy at least one of (a) the chemical structures of R³¹ and R³² are not the same; (b) the substitution positions of R³¹ and R³² bonded to the aromatic ring in Formula (31) are different (asymmetric substitution positions); and (c) g and h each independently represent an integer of 0 to 3 different from each other. From the viewpoint of satisfying the above condition (XS1x), it is also preferable to satisfy at least one of (d) the chemical structures of R⁶¹ and R⁶² are not the same; (e) R⁶¹ and R⁶² bonded to an aromatic ring in Formula (31) have different substitution positions (asymmetric substitution positions); and (f) o and p each independently represent an integer of 0 to 3 different from each other. In addition, from the viewpoint of satisfying the above condition (XS1x), it is also preferable to satisfy at least one of (g) the substitution positions of at least two phenolic hydroxyl groups bonded to the aromatic ring in Formula (31) are different (asymmetric substitution positions); and (h) a and b each independently represent an integer of 1 to 4 different from each other.

In formula (31), the hydrocarbon group in X¹¹ and X¹², the hydrocarbon group containing an ether bond, and the hydrocarbon group containing a carbonylamide group are preferably an alkylene group having 1 to 10 carbon atoms, a cycloalkylene group having 4 to 10 carbon atoms, an arylene group having 6 to 15 carbon atoms, or an arylalkylene group having 10 to 20 carbon atoms. The hydrocarbon group in a case of the hydrocarbon group including a carbonylamide group in X¹¹ and X¹² is more preferably an arylene group having 6 to 15 carbon atoms, and still more preferably an arylene group having 6 to 10 carbon atoms. It is preferable that an arylene group having 6 to 15 carbon atoms is bonded to a carbonyl group in the carbonylamide group. Preferably, the nitrogen atom of the carbonylamide group is bonded to the aromatic ring in Formula (31), and the arylene group having 6 to 15 carbon atoms bonded to the carbonyl group in the carbonylamide group is bonded to *¹ or *² in Formula (31). In Y¹¹, the hydrocarbon group in a case of the hydrocarbon group including an ether bond is preferably an alkylene group having 1 to 10 carbon atoms, a cycloalkylene group having 4 to 10 carbon atoms, or an arylene group having 6 to 15 carbon atoms. In Y¹¹, the number of carbon atoms of the hydrocarbon group including a carbonyloxy group and the hydrocarbon group including a carbonylamide group is preferably 1 to 15, and the hydrocarbon group is preferably an aliphatic structure, an alicyclic structure, an aromatic structure, a condensed polycyclic structure, or a condensed polycyclic heterocyclic structure. The substituents and structures described above may have a hetero atom, and may be either unsubstituted or substituted.

From the viewpoint of satisfying the above condition (XS1x), it is preferable to satisfy at least one of (i) the chemical structures of X¹¹ and X¹² are not the same; (j) the substitution positions of X¹¹ and X¹² bonding to the aromatic ring in Formula (31) are different (asymmetric substitution positions). From the viewpoint of satisfying the condition (XS1x), it is also preferable that the chemical structure of Y¹¹ satisfies the above condition (XS1x).

The phenolic hydroxyl group in the amine residue represented by Formula (31) may react with a structure and/or a group in the resin to form a benzoxazole ring. That is, in the resin having a benzoxazole ring in the structural unit of the resin, the benzoxazole ring may have an amine residue represented by Formula (31).

When the structures in the amine residues having a phenolic hydroxyl group are not the same in chemical structure, it is preferable that at least one of the number of carbon atoms, the number of hydrogen atoms, the number of heteroatoms, a molecular weight, a molecular volume, and an aspect ratio is different between structures to be compared. In addition, when the structures in the amine residues having a phenolic hydroxyl group are not the same in chemical structure, it is also preferable that the structures to be compared are in a relationship of structural isomerism or geometric isomerism. It is also preferable that the structure to be compared has at least one of an asymmetric center, an asymmetric axis, an asymmetric plane, and a helical axis. The same applies to the following description regarding the structure in the amine residue having a phenolic hydroxyl group.

In Formula (31), Y¹¹ is preferably a group represented by Formulas (32), (33), or (34) from the viewpoint of achieving low voltage drive of light emission characteristics, improving reliability of a light-emitting element, and improving migration resistance. When Y¹¹ in Formula (31) is a group represented by Formula (32), (33), or (34), R³⁹ in Formula (31) is a group corresponding to R³⁴ bonded to an atom of a ring member in Formula (32), a group corresponding to R³⁵ bonded to an atom of a ring member in Formula (33), or a group bonded to R³⁶ or R³⁷ in Formula (34).

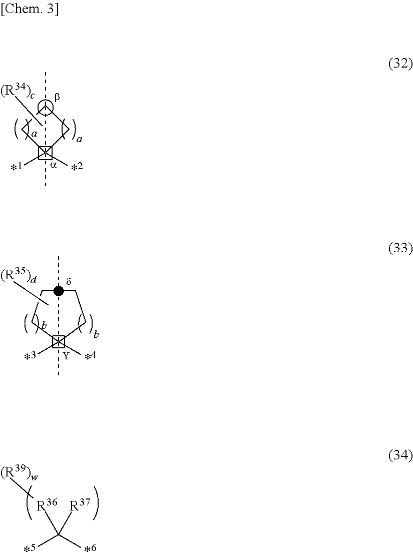

In Formulas (32) to (34), R³⁴ and R³⁵ each independently represent a hydrocarbon group, a hydrocarbon group including an ether bond, or a hydrocarbon group including a carbonyl group. R³⁶ and R³⁷ each independently represent a hydrogen atom, a hydrocarbon group, a hydrocarbon group including an ether bond, or a hydrocarbon group including a carbonyl group. R³⁹ represents a hydrocarbon group, a hydrocarbon group containing an ether bond, or a hydrocarbon group containing a carbonyl group. a and b each independently represent an integer of 1 or 2. c represents an integer of 1 to ((4×a)+2). d represents an integer of 1 to ((4×a)+4). w represents an integer of 0 to 6. *¹ to *⁶ each independently represent a bonding point to an aromatic ring in Formula (31) resin. Formula (32) satisfies the following condition (XY1), Formula (33) satisfies the following condition (XY2), and Formula (34) satisfies the following condition (XY3).
(XY1) When a carbon center bonded to an aromatic ring in Formula (31) is α (represented as □), a carbon atom thereof is at the 1 position, and an (a+2) position of a carbon atom forming a ring is β (represented as ∘), left and right chemical structures separated by broken lines passing through α and β are not the same on the paper.
(XY2) When a carbon center bonded to an aromatic ring in Formula (31) is represented by y (represented by ▪), a carbon atom thereof is at the 1 position, and a midpoint between the (b+2) position and the (b+3) position of a carbon atom forming the ring is represented by δ (represented by •), left and right chemical structures separated by broken lines passing through γ and δ are not the same on the paper.
(XY3) The chemical structures of R³⁶ and R³⁷ in Formula (34) are not the same.

When the group represented by Formula (32) has at least one of an asymmetric center, an asymmetric axis, an asymmetric plane, and a helical axis, Formula (32) satisfies the above condition (XY1). When the group represented by Formula (33) has at least one of an asymmetric center, an asymmetric axis, an asymmetric plane, and a helical axis, Formula (33) satisfies the above condition (XY2), When the group represented by Formula (34) has at least one of an asymmetric center, an asymmetric axis, an asymmetric plane, and a helical axis, Formula (34) satisfies the above condition (XY3),

When considering the above conditions (XY1) to (XY3) according to Formulas (32) to (34), the chemical structures of the target group represented by Formula (32), (33), or (34) take into account all possible conformations of the target group. That is, when at least one of the possible conformations of the group represented by the target Formula (32) has the same chemical structure on the left and right sides separated by a broken line passing through α and β on the paper, the above condition (XY1) is not satisfied. In addition, when at least one of the possible conformations of the group represented by the target Formula (33) has the same chemical structure on the left and right sides separated by broken lines passing through α and γ on the paper, the above condition (XY2) is not satisfied. When at least one of the possible conformations of the group represented by the target Formula (34) has the same chemical structure of R³⁶ and R³⁷, the above condition (XY3) is not satisfied.

In Formulas (32) to (34), R³⁶ and R³⁷ each independently preferably represent a hydrocarbon group, a hydrocarbon group including an ether bond, or a hydrocarbon group including a carbonyl group. The hydrocarbon group in a case of the hydrocarbon group in R³⁴, R³⁵, R³⁶, R³⁷, and R³⁹, the hydrocarbon group including an ether bond, and the hydrocarbon group including a carbonyl group is preferably an alkyl group having 1 to 10 carbon atoms, a cycloalkyl group having 4 to 10 carbon atoms, an aryl group having 6 to 15 carbon atoms, or an arylalkyl group having 10 to 20 carbon atoms, more preferably an alkyl group having 1 to 8 carbon atoms, and still more preferably an alkyl group having 1 to 6 carbon atoms.

When the amine residue having a phenolic hydroxyl group has the above configuration, the amine residue having a phenolic hydroxyl group has an asymmetric structure having no C₂ symmetry axis or a stereoscopically asymmetric structure, so that the symmetry of the (XA) resin in the insulating resin layer is reduced. Therefore, it is considered that the orientation and stacking of the (XA) resin in the insulating resin layer are suppressed. For the same reason as described above, it is presumed that the effects of the achieving low voltage drive of light emission characteristics, the improving the reliability of the light-emitting element, and the improving the migration resistance become remarkable.

It is particularly preferable that the amine residue having a phenolic hydroxyl group satisfies the above condition (XS1x) and has an amine residue represented by Formula (31), and in Formula (31), Y¹¹ is a group represented by Formula (32), (33), or (34), from the viewpoint of achieving low voltage drive of light emission characteristics, improving reliability of a light-emitting element, and improving migration resistance.

In Formula (31), Y¹¹ is preferably a group represented by any one of Formulas (55) to (68) from the viewpoint of the effects of the invention described above.

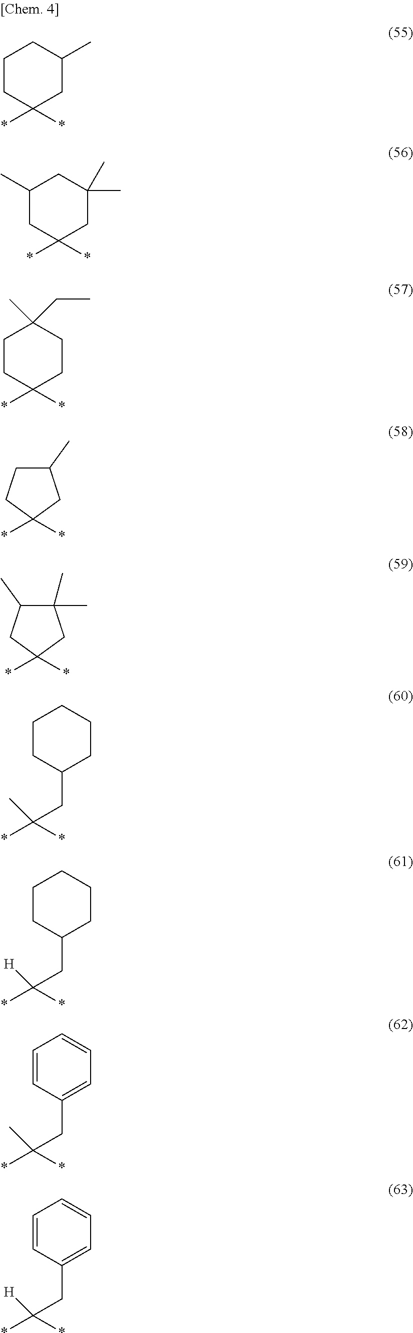

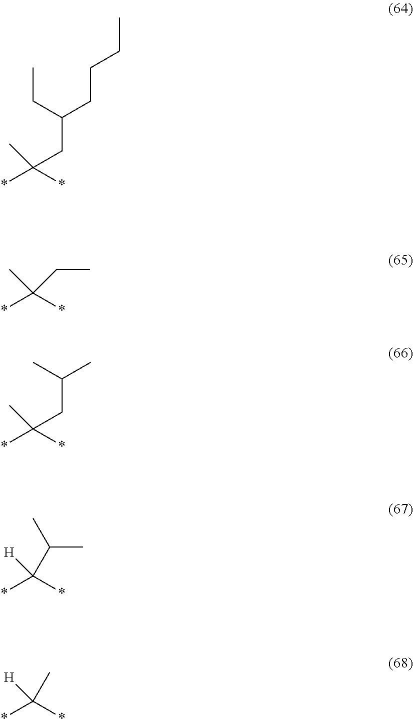

In Formulas (55) to (68), * each independently represents a bonding point in the resin.

In Formula (31), the amine residue having a phenolic hydroxyl group in which Y¹¹ is a group represented by any one of Formulas (55) to (68) is preferably an amine residue represented by any one of Formulas (70) to (99).

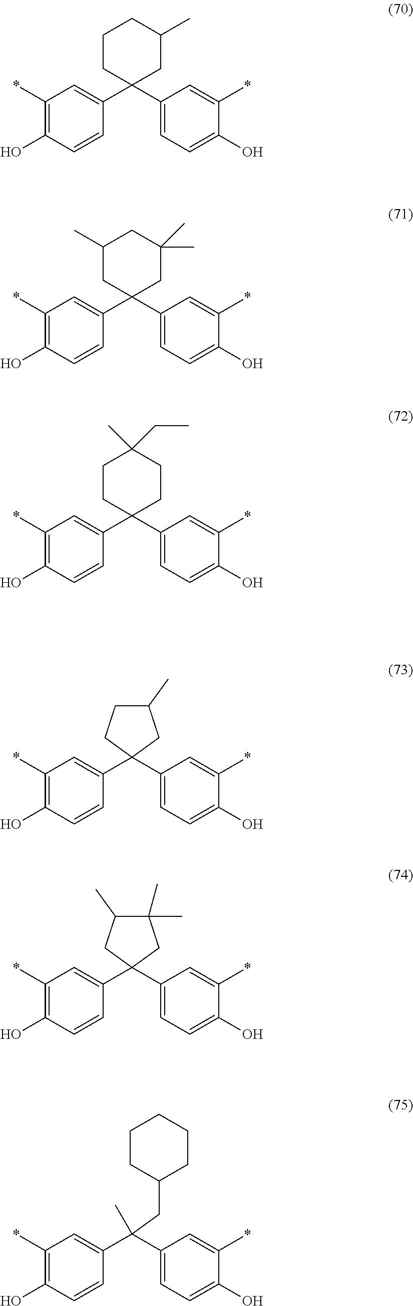 [SMILES: *c1cc(C2(c3ccc(O)c(*)c3)CCCC(C)C2)ccc1O ; *c1cc(C2(c3ccc(O)c(*)c3)CC(C)CC(C)(C)C2)ccc1O ; *c1cc(C2(c3ccc(O)c(*)c3)CCC(C)(CC)CC2)ccc1O ; *c1cc(C2(c3ccc(O)c(*)c3)CCC(C)C2)ccc1O ; *c1cc(C2(c3ccc(O)c(*)c3)CC(C)C(C)(C)C2)ccc1O ; *c1cc(C(C)(CC2CCCCC2)c2ccc(O)c(*)c2)ccc1O]

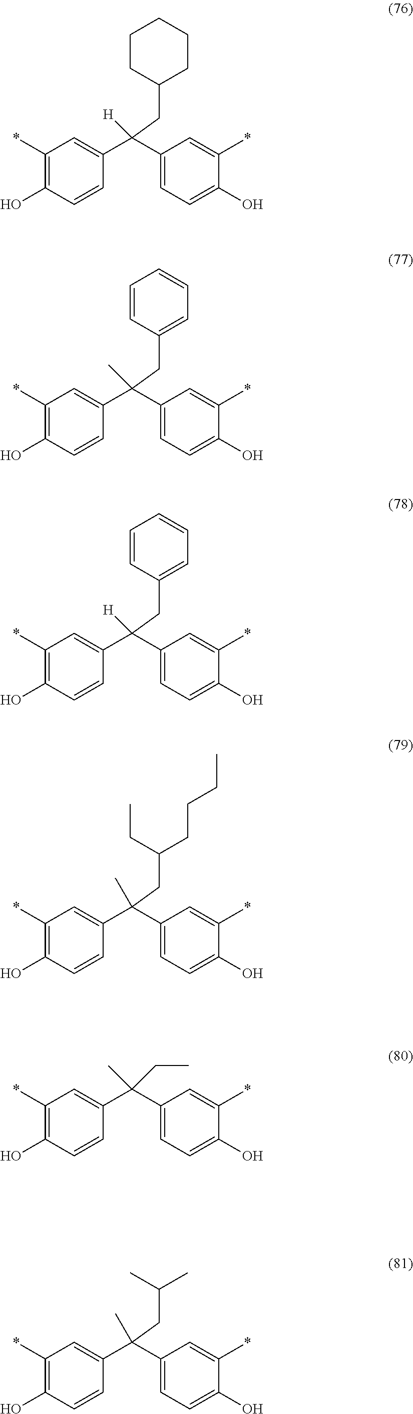 [SMILES: *c1cc(C(CC2CCCCC2)c2ccc(O)c(*)c2)ccc1O ; *c1cc(C(C)(Cc2ccccc2)c2ccc(O)c(*)c2)ccc1O ; *c1cc(C(Cc2ccccc2)c2ccc(O)c(*)c2)ccc1O ; *c1cc(C(C)(CC(CC)CCCC)c2ccc(O)c(*)c2)ccc1O ; *c1cc(C(C)(CC)c2ccc(O)c(*)c2)ccc1O ; *c1cc(C(C)(CC(C)C)c2ccc(O)c(*)c2)ccc1O]

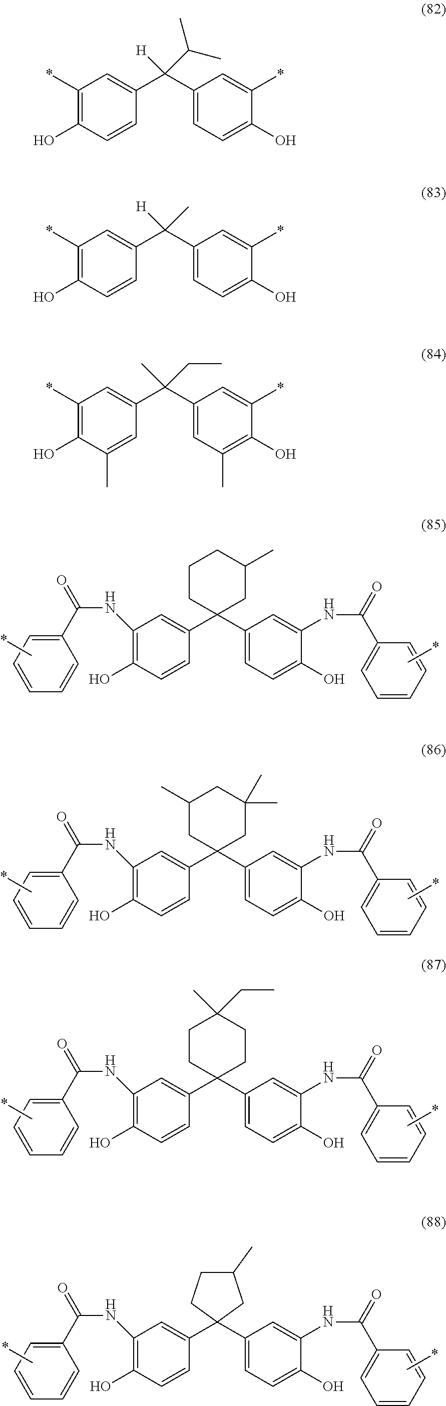

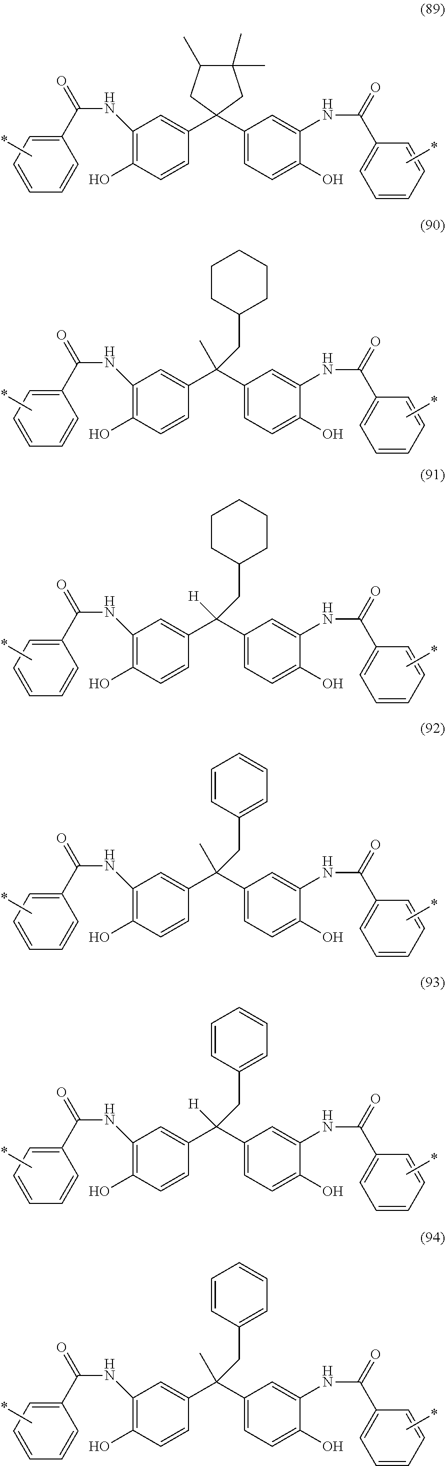

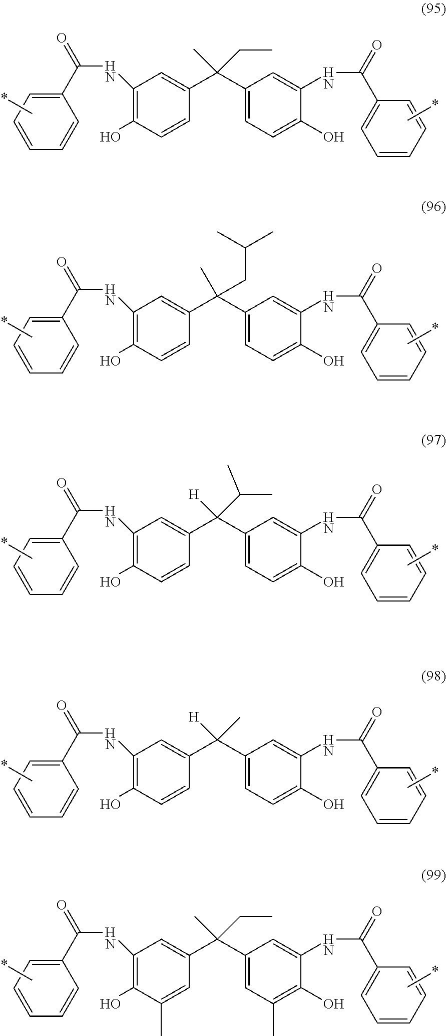

### <Amine Residue Having No Phenolic Hydroxyl Group>

It is also preferable that the (XA1x) resin has an amine residue having no phenolic hydroxyl group. It is also preferable that the (XA1x) resin has two or more amine residues having no phenolic hydroxyl group.

When the insulating resin layer contains the (XA1x) resin and the (XA1x) resin contains one or more resins selected from the group consisting of polyimide-based resins, the (XA1x) resin preferably has an amine residue having a phenolic hydroxyl group and an amine residue having no phenolic hydroxyl group.

From the viewpoints of achieving low voltage drive of light emitting characteristics, improving the reliability of the light-emitting element, and improving migration resistance, it is preferable that the amine residue having no phenolic hydroxyl group has an amine residue that satisfies at least one of the following conditions (XS1x) and (XS2x) (hereinafter, “specific amine residue having no phenolic hydroxyl group”).

In the (XA1x) resin, it is preferable that the amine residue having a phenolic hydroxyl group has an amine residue satisfying the following condition (XS1x) and/or the amine residue having no phenolic hydroxyl group has an amine residue satisfying at least one of the following conditions (XS1x) and (XS2x) (hereinafter, “specific amine residue having no phenolic hydroxyl group”) from the viewpoint of the effects of the invention described above.
(XS1x) The amine residue has a C₁ symmetry axis as a molecular symmetry and does not have a C₂ symmetry axis.
(XS1y) The amine residue has a C₁ symmetry axis as the molecular symmetry and does not have a C₂ symmetry axis or a C₃ symmetry axis.
(XS1z) The amine residue has a C₁ symmetry axis as a molecular symmetry, and has no symmetry axis other than the C₁ symmetry axis.
(XS2x) The amine residue has at least one of an asymmetric center, an asymmetric axis, an asymmetric plane, and a helical axis.
(XS2y) The amine residue has at least one of an asymmetric center and an asymmetric axis.
(XS2z) The amine residue has an asymmetric axis.

The amine residue satisfying the above condition (XS1x) in the amine residue having no phenolic hydroxyl group is more preferably an amine residue satisfying the above condition (XS1y), and still more preferably an amine residue satisfying the above condition (XS1z). The amine residue satisfying the above condition (XS2x) in the amine residue having no phenolic hydroxyl group is more preferably an amine residue satisfying the above condition (XS2y), and still more preferably an amine residue satisfying the above condition (XS2z).

The amine residue in the amine residue having no phenolic hydroxyl group is as described above. Examples and preferred descriptions regarding the above conditions (XS1x) to (XS1z) for the amine residue having a phenolic hydroxyl group are the same as those described above. Examples and preferred descriptions of the amine residue under the above conditions (XS1x) to (XS1z) and (XS2x) to (XS2z) relating to the amine residue having no phenolic hydroxyl group are as described above for the amine residue having a phenolic hydroxyl group. Regarding the molecular symmetry of the amine residue under the above conditions (XS1x) to (XS1z) relating to the amine residue having no phenolic hydroxyl group, and the fact that the amine residue has a Cₓ symmetry axis as the molecular symmetry, and preferred descriptions are as described above for the amine residue having a phenolic hydroxyl group.

When considering the symmetry axis in the molecular symmetry of the amine residue under the above conditions (XS1x) to (XS1z) relating to the amine residue having no phenolic hydroxyl group, as with the amine residue having a phenolic hydroxyl group, the three-dimensional structure before rotation of the target amine residue takes into account all the conformations that can be taken as a molecule. That is, in the three-dimensional structure before rotation, when at least one of the possible conformations of the amine residue of interest as a molecule has a C₂ symmetry axis, the above condition (XS1x) is not satisfied, when at least one has a C₂ symmetry axis or a C₃ symmetry axis, the above condition (XS1y) is not satisfied, and when at least one has a Cₓ symmetry axis (1<x≤360), the above condition (XS1z) is not satisfied.

The asymmetric center, the asymmetric axis, the asymmetric plane, and the helical axis under the above conditions (XS2x) to (XS2z) refer to an asymmetric center, an asymmetric axis, an asymmetric plane, and a helical axis in a molecule when an amine residue in the (XA) resin in the insulating resin layer is used as the molecule.

Examples of the asymmetric center include an asymmetric atom. The asymmetric atom is preferably an asymmetric carbon atom, an asymmetric silicon atom, an asymmetric germanium atom, an asymmetric nitrogen, an asymmetric phosphorus atom, or an asymmetric arsenic atom. Examples of the asymmetric axis include an axis connecting two rings in two ring structures, an axis connecting two ring structures passing through a center atom in two ring structures connected by sharing one center atom, and an axis linearly connecting three atoms connected by two double bonds. The structure having an asymmetric axis is preferably a biphenyl structure, a binaphthyl structure, a spiro structure, or an allene structure. Examples of the asymmetric plane include a plane in which at least two rings face each other in a ring structure formed by connecting at least two rings by a single bond, and a plane in which at least two rings face each other in a metal coordination ring structure including at least two rings coordinated to a metal atom. As the structure having an asymmetric plane, a cyclophane structure or a metallocene structure is preferable, and a paracyclophane structure or a ferrocene structure is more preferable. Examples of the helical axis include an axis of a helical structure in which at least two aromatic rings are continuously condensed. The structure having a helical axis is preferably a polyhelicene structure.

Regarding the asymmetric center, the asymmetric axis, the asymmetric plane, and the helical axis under the above conditions (XS2x) to (XS2z), when an amine residue in the (XA) resin in the insulating resin layer is used as a molecule, the molecule may be a meso compound. The amine residue under the above conditions (XS2x) to (XS2z) preferably has chirality, and more preferably has central chirality, axial chirality, planar chirality, or helicity.

When the amine residue having no phenolic hydroxyl group has the above configuration, the amine residue having no phenolic hydroxyl group has an asymmetric structure having no C₂ symmetry axis or a stereoscopically asymmetric structure, so that the symmetry of the (XA) resin in the insulating resin layer is reduced, Therefore, it is considered that the orientation and stacking of the (XA) resin in the insulating resin layer are suppressed. As a result, for the same reason as the amine residue having a phenolic hydroxyl group, it is presumed that the effects of achieving low voltage drive of light emission characteristics, improving reliability of a light-emitting element, and improving migration resistance become remarkable.

The amine residue having no phenolic hydroxyl group preferably has an amine residue represented by Formula (36) from the viewpoint of achieving low voltage drive of light emission characteristics, improving reliability of a light-emitting element, and improving migration resistance.

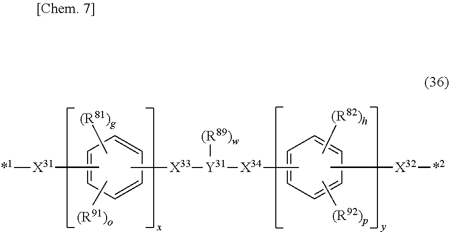

In Formula (36), R⁸¹ and R⁸² each independently represent a carboxy group, a mercapto group, or a sulfonic acid group. R⁸⁹ represents a hydrocarbon group, a hydrocarbon group including an ether bond, or a hydrocarbon group including a carbonyl group. R⁹¹ and R⁹² each independently represent an alkyl group having 1 to 10 carbon atoms, a cycloalkyl group having 4 to 10 carbon atoms, an aryl group having 6 to 15 carbon atoms, an alkenyl group having 2 to 10 carbon atoms, an alkoxy group having 1 to 10 carbon atoms, an alkenyloxy group having 2 to 10 carbon atoms, or an acyl group having 1 to 10 carbon atoms. X³¹ and X³² each independently represent a direct bond, a hydrocarbon group, a hydrocarbon group including an ether bond, or a hydrocarbon group including a carbonylamide group. X³³ and X³⁴ each independently represent a direct bond, a hydrocarbon group, a hydrocarbon group including an ether bond, a hydrocarbon group including a carbonyloxy group, or a hydrocarbon group including a carbonylamide group. Y³¹ represents a sulfonyl group, an alkylene group, a condensed polycyclic structure, a hydrocarbon group including an ether bond, a direct bond, an ether bond, a sulfide bond, a carbonyl group, a carboxylic acid ester bond, an amide bond, a urea bond, a urethane bond, a carbonate ester bond, a cycloalkylene group, an arylene group, a condensed polycyclic heterocyclic structure, a hydrocarbon group including a carbonyloxy group, or a hydrocarbon group including a carbonylamide group. g and h each independently represent an integer of 0 to 4. o and p each independently represent an integer of 0 to 4. x and y each independently represent 0 or 1. w represents an integer of 0 to 6. *¹ and *² each independently represent a bonding point in the resin.

In Formula (36), the hydrocarbon group in R⁸⁹, the hydrocarbon group containing an ether bond, and the hydrocarbon group containing a carbonyl group are preferably an alkyl group having 1 to 10 carbon atoms, a cycloalkyl group having 4 to 10 carbon atoms, an aryl group having 6 to 15 carbon atoms, or an arylalkyl group having 10 to 20 carbon atoms, more preferably an alkyl group having 1 to 8 carbon atoms, and even more preferably an alkyl group having 1 to 6 carbon atoms. When o represents an integer of 1 to 3, the corresponding R⁹¹ is preferably an alkyl group having 1 to 6 carbon atoms, and more preferably a methyl group, an ethyl group, a propyl group, an isopropyl group, a butyl group, an isobutyl group, or an s-butyl group. When p represents an integer of 1 to 3, the corresponding R⁹² is preferably an alkyl group having 1 to 6 carbon atoms, and more preferably a methyl group, an ethyl group, a propyl group, an isopropyl group, a butyl group, an isobutyl group, or an s-butyl group. It is preferable that at least one of o and p is 1. It is also preferable that o and p are 0, and it is more preferable that o and p are 1. It is also preferable that o represents an integer of 1 to 3 and p is 0, and it is more preferable that o is 1. It is also preferable that o is 0 and p represents an integer of 1 to 3, and it is more preferable that p is 1.

From the viewpoint of satisfying the above condition (XS1x), the chemical structure of R⁸⁹ preferably satisfies the above condition (XS1x). From the viewpoint of satisfying the above condition (XS1x), it is also preferable to satisfy at least one of (a) the chemical structures of R⁸¹ and R⁸² are not the same; (b) the substitution positions of R⁸¹ and R⁸² bonded to the aromatic ring in Formula (36) are different (asymmetric substitution positions); and (c) g and h each independently represent an integer of 0 to 4 different from each other. From the viewpoint of satisfying the above condition (XS1x), it is also preferable to satisfy at least one of (d) the chemical structures of R⁹¹ and R⁹² are not the same; (e) R⁹¹ and R⁹² bonded to an aromatic ring in Formula (36) have different substitution positions (asymmetric substitution positions); and (f) o and p each independently represent an integer of 0 to 4 different from each other. On the other hand, from the viewpoint of satisfying the above condition (XS2x), the chemical structure of R⁸⁹ preferably satisfies the above condition (XS2x),

In Formula (36), the hydrocarbon group in a case of the hydrocarbon group in X³¹ and X³², the hydrocarbon group including an ether bond, and the hydrocarbon group including a carbonylamide group is preferably an alkylene group having 1 to 10 carbon atoms, a cycloalkylene group having 4 to 10 carbon atoms, an arylene group having 6 to 15 carbon atoms, or an arylalkylene group having 10 to 20 carbon atoms. The hydrocarbon group in X³³ and X³⁴, the hydrocarbon group including an ether bond, the hydrocarbon group including a carbonyloxy group, and the hydrocarbon group including a carbonylamide group are preferably an alkylene group having 1 to 10 carbon atoms, a cycloalkylene group having 4 to 10 carbon atoms, an arylene group having 6 to 15 carbon atoms, or an arylalkylene group having 10 to 20 carbon atoms. In Y³¹, the hydrocarbon group in the hydrocarbon group containing an ether bond is preferably an alkylene group having 1 to 10 carbon atoms, a cycloalkylene group having 4 to 10 carbon atoms, or an arylene group having 6 to 15 carbon atoms. In Y³¹, the number of carbon atoms of the hydrocarbon group including a carbonyloxy group and the hydrocarbon group including a carbonylamide group is preferably 1 to 15, and the hydrocarbon group is preferably an aliphatic structure, an alicyclic structure, an aromatic structure, a condensed polycyclic structure, or a condensed polycyclic heterocyclic structure. The substituents and structures described above may have a hetero atom, and may be either unsubstituted or substituted.

From the viewpoint of satisfying the above condition (XS1x), it is preferable to satisfy at least one of (i) the chemical structures of X³¹ and X³² are not the same; and (j) the substitution positions of X³¹ and X³² bonding to the aromatic ring in Formula (36) are different (asymmetric substitution positions). From the viewpoint of satisfying the above condition (XS1x), it is also preferable to satisfy at least one of (k) the chemical structures of X³³ and X³⁴ are not the same; and (1) the substitution positions of X³³ and X³⁴ bonding to the aromatic ring in Formula (36) are different (asymmetric substitution positions). From the viewpoint of satisfying the condition (XS1x), it is also preferable that the chemical structure of Y³¹ satisfies the above condition (XS1x). On the other hand, from the viewpoint of satisfying the above condition (XS2x), the chemical structure of Y³¹ preferably satisfies the above condition (XS2x), more preferably satisfies the condition (XS2y), and still more preferably satisfies the above condition (XS2z). From the viewpoint of satisfying the above condition (XS2z), Y³¹ preferably includes a structure having an asymmetric axis. The structure having an asymmetric axis is preferably a biphenyl structure, a binaphthyl structure, a spiro structure, or an allene structure.

When the structures in the amine residues having no phenolic hydroxyl group are not the same in chemical structure, it is preferable that at least one of the number of carbon atoms, the number of hydrogen atoms, the number of heteroatoms, a molecular weight, a molecular volume, and an aspect ratio is different between structures to be compared. In addition, when the structures in the amine residues having no phenolic hydroxyl group are not the same in chemical structure, it is also preferable that the structures to be compared are in a relationship of structural isomerism or geometric isomerism. It is also preferable that the structure to be compared has at least one of an asymmetric center, an asymmetric axis, an asymmetric plane, and a helical axis. The same applies to the following description regarding the structure in the amine residue having no phenolic hydroxyl group.

In Formula (36), Y³¹ is preferably a group represented by Formula (37) or (38) from the viewpoint of the effects of the invention described above. When Y³¹ in Formula (36) is a group represented by Formula (37) or (38), R⁸⁹ in Formula (36) is a group corresponding to R⁸⁴ to R⁸⁷ bonded to a ring member atom in Formula (37) or a group corresponding to R⁹⁴ to R⁹⁶ bonded to a ring member atom in Formula (38).

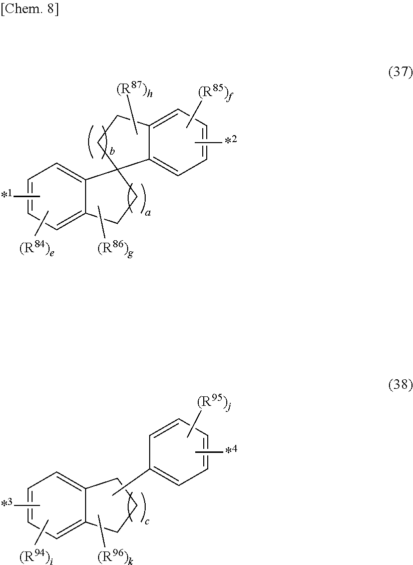

In Formulas (37) and (38), R⁸⁴ to R⁸⁷ and R⁹⁴ to R⁹⁶ each independently represent a hydrocarbon group, a hydrocarbon group including an ether bond, or a hydrocarbon group including a carbonyl group. a, b, and c each independently represent an integer of 1 or 2. e and f each independently represent an integer of 0 to 3. g represents an integer of 0 to ((2×a)+2). h represents an integer of 0 to ((2×b)+2). i represents an integer of 0 to 3. j represents an integer of 0 to 4. k represents an integer of 0 to ((2×c)+3). *¹ to *⁴ each independently represent a bonding point to X³³ or X³⁴ in Formula (36).

In Formulas (37) and (38), the hydrocarbon group in a case of the hydrocarbon group in R⁸⁴, R⁸⁵, R⁸⁶, R⁸⁷, R⁹⁴, R⁹⁵, and R⁹⁶, the hydrocarbon group including an ether bond, and the hydrocarbon group including a carbonyl group is preferably an alkyl group having 1 to 10 carbon atoms, a cycloalkyl group having 4 to 10 carbon atoms, an aryl group having 6 to 15 carbon atoms, or an arylalkyl group having 10 to 20 carbon atoms, more preferably an alkyl group having 1 to 8 carbon atoms, and still more preferably an alkyl group having 1 to 6 carbon atoms.

When the amine residue having no phenolic hydroxyl group has the above configuration, the amine residue having no phenolic hydroxyl group has an asymmetric structure having no C₂ symmetry axis or a stereoscopically asymmetric structure, so that the symmetry of the (XA) resin in the insulating resin layer is reduced. Therefore, it is considered that the orientation and stacking of the (XA) resin in the insulating resin layer are suppressed. For the same reason as described above, it is presumed that the effects of the achieving low voltage drive of light emission characteristics, the improving the reliability of the light-emitting element, and the improving the migration resistance become remarkable.

It is particularly preferable that the amine residue having no phenolic hydroxyl group satisfies at least one of the above conditions (XS1x) and (XS2x), has an amine residue represented by Formula (36), and in Formula (36), Y³¹ is a group represented by Formula (37) or (38) from the viewpoint of achieving low voltage drive of light emission characteristics, improving reliability of a light-emitting element, and improving migration resistance.

The amine residue having no phenolic hydroxyl group preferably has an amine residue satisfying the above condition (XS1x) and further preferably has an amine residue satisfying the above condition (XS2x) from the viewpoint of the effects of the invention described above. The amine residue having no phenolic hydroxyl group preferably has an amine residue that satisfies at least one of the above conditions (XS1x) and (XS2x), and further preferably has an amine residue that does not satisfy any of the above conditions (XS1x) and (XS2x) from the viewpoint of the effects of the invention described above.

When the amine residue having no phenolic hydroxyl group has such a configuration, the amine residue having no phenolic hydroxyl group has an asymmetric structure having no C₂ symmetry axis or a sterically asymmetric structure, and has a structure different from the above structure, so that the symmetry of the (XA) resin in the insulating resin layer as a whole is reduced. Therefore, it is presumed that the orientation and stacking of the (XA) resin in the insulating resin layer are suppressed, and the effects of the invention described above become remarkable for the same reason as described above,

The (XA) resin in the insulating resin layer may further have an amine residue different from an amine residue having a phenolic hydroxyl group and an amine residue having no phenolic hydroxyl group. Examples of such an amine residue include an alicyclic amine residue or an aliphatic amine residue.

In the structural units of the polyimide and its precursor, a resin having an imide cyclization ratio of 50 mol % or more is classified as polyimide. On the other hand, a resin having an imide cyclization ratio of less than 50 mol % is classified as a polyimide precursor. Similarly, a resin having a benzoxazole cyclization ratio of 50 mol % or more in the structural units of polybenzoxazole and a precursor thereof is classified as polybenzoxazole. On the other hand, resins having a benzoxazole cyclization ratio of less than 50 mol % are classified as polybenzoxazole precursors. Similarly, a resin having an imide cyclization ratio of 50 mol % or more in the structural units of polyamideimide and a precursor thereof is classified as polyamideimide. On the other hand, a resin having an imide cyclization ratio of less than 50 mol % is classified as a polyamideimide precursor. Based on the above, resins corresponding to two or more selected from the group consisting of (1) a polyimide or a precursor thereof, (2) a polybenzoxazole or a precursor thereof, and (3) a polyamideimide or a precursor thereof are classified into both resins, That is, the resin corresponding to both the polyimide precursor and the polybenzoxazole precursor is classified into both the polyimide precursor and the polybenzoxazole precursor.

<Resin Different from (XA1x) Resin>

In the element of the present invention, from the viewpoint of the effects of the invention described above, it is also preferable that the insulating resin layer includes the (XA1y) resin: a resin having a phenolic hydroxyl group in the structural unit of resin. In the element of the present invention, it is also preferable that the (XA1) weakly acidic group-containing resin includes the (XA1y) resin from the viewpoint of the effects of the invention described above. The (XA1y) resin preferably includes one or more resins selected from the group consisting of a phenolic resin, polyhydroxystyrene, a phenol group-containing epoxy resin, and a phenol group-containing acrylic resin. The (XA1y) resin may be either a single resin or a copolymer thereof.

It is preferable that the (XA) resin includes a (XA2) resin having no weakly acidic group (hereinafter, “(XA2) resin”) from the viewpoint of achieving low voltage drive of light emission characteristics. The (XA2) resin preferably has a carboxy group, a carboxylic anhydride group, or a sulfonic acid group, and more preferably includes one or more resins selected from the group consisting of a polycyclic side chain-containing resin, an acid-modified epoxy resin, and an acrylic resin, from the viewpoint of achieving low voltage drive of light emission characteristics. The (XA2) resin may be a single resin or a copolymer thereof. The (XA2) resin preferably has a radical polymerizable group, and more preferably has a radical polymerizable group in the structural unit of the resin, from the viewpoint of improving the reliability and migration resistance of the light-emitting element. The radical polymerizable group preferably has an ethylenically unsaturated double bond group, and more preferably has a photoreactive group, an alkenyl group having 2 to 5 carbon atoms, or an alkynyl group having 2 to 5 carbon atoms. The polycyclic side chain-containing resin is preferably a cardo-based resin having a condensed polycyclic structure, a condensed polycyclic alicyclic structure, or a condensed polycyclic heterocyclic structure. The acid-modified epoxy resin is preferably an epoxy (meth)acrylate resin having a condensed polycyclic structure, a condensed polycyclic alicyclic structure, a condensed polycyclic heterocyclic structure, or an aromatic structure. The acrylic resin preferably has a unit having a condensed polycyclic structure, a condensed polycyclic heterocyclic structure, an aromatic structure, or an epoxy group.

From the viewpoint of improving the reliability of the light-emitting element, the (XA2) resin preferably contains a resin having one or more structures selected from the group consisting of an imide structure, an amide structure, an oxazole structure, and a siloxane structure (hereinafter, “imide structure and the like”) in the structural unit of the resin. The (XA2) resin preferably includes one or more resins selected from the group consisting of a polyimide, a polyimide precursor, a polybenzoxazole, a polybenzoxazole precursor, a polyamideimide, a polyamideimide precursor, a polyamide, a polysiloxane, a maleimide resin, a maleimide-styrene resin, a maleimide-triazine resin, a maleimide-oxazine resin, and copolymers thereof, and more preferably includes one or more resins selected from the group consisting of a polyimide, a polyimide precursor, a polybenzoxazole, a polybenzoxazole precursor, a polyamideimide, a polyamideimide precursor, and copolymers thereof (hereinafter, “polyimide-based resin having no weakly acidic group”). The polyimide-based resin having no weakly acidic group may further be a copolymer with a polyamide. The (XA2) resin may be a single resin or a copolymer thereof. A polyimide-based resin having a weakly acidic group and a polyimide-based resin having no weakly acidic group may be collectively referred to as a polyimide-based resin.

When each of the (XA1x) resin, the (XA1y) resin, and the (XA2) resin has a structure or a group constituting another resin among these resins, these resins are classified into any of the resins by the classification method shown in Table 1-1 below. When a resin can be classified as two or more of (XA1x), (XA1y), and (XA2) resins, the classification method determines which resin the resin falls into.

TABLE 1-1

| | | | Structural | | |
|---|---|---|---|---|---|
| | | Structural | unit | | |
| | (WA) | unit having | containing | Radical | |
| | Weakly | imide | phenolic | polymer- | Classi- |
| | acidic | structure | hydroxyl | izable | fication |
| | group | or the like | group | group | of resin |
| Resin 1 | Present | Present | Present | Present | (XA1x) resin |
| Resin 2 | Present | Present | Present | Absent | (XA1x) resin |
| Resin 3 | Present | Present | Absent | Present | (XA1x) resin |
| Resin 4 | Present | Present | Absent | Absent | (XA1x) resin |
| Resin 5 | Present | Absent | Present | Present | (XA1y) resin |
| Resin 6 | Present | Absent | Present | Absent | (XA1y) resin |
| Resin 7 | Absent | Present | Absent | Present | (XA2) resin |
| Resin 8 | Absent | Present | Absent | Absent | (XA2) resin |
| Resin 9 | Absent | Absent | Absent | Present | (XA2) resin |
| Resin 10 | Absent | Absent | Absent | Absent | (KA2) resin |

### <(XD) Colorant in Insulating Resin Layer>

In the element of the present invention, the insulating resin layer preferably contains an (XD) colorant from the viewpoint of suppressing external light reflection. The (XD) colorant refers to a compound that is colored by absorbing any light within the wavelength (380 to 780 nm) range of visible light. The (XD) colorant is preferably a pigment or a dye. The (XD) colorant preferably includes a blacking agent or a colorant mixture of two or more colorants. The blacking agent preferably includes an organic black pigment and/or an inorganic black pigment. The black color in the (XD) colorant is as described in paragraphs to of International Publication No. 2019/087985. The (XD) colorant in the insulating resin layer is preferably the (D) colorant described later, and a compound having a structure derived from the (D) colorant is also preferable.

From the viewpoints of achieving low voltage drive of light emitting characteristics, improving the reliability of the light-emitting element, and improving migration resistance, it is preferred that the insulating resin layer of the element of the present invention contains an organic black pigment and/or an inorganic black pigment, the organic black pigment includes one or more types selected from the group consisting of benzofuranone-based black pigments, perylene-based black pigments, and azo-based black pigments, the inorganic black pigment includes one or more types selected from the group consisting of nitrides containing metal elements, carbides containing metal elements, and oxynitrides containing metal elements, and the metal element is one or more types selected from the group consisting of zirconium, vanadium, niobium, hafnium, and tantalum. The benzofuranone-based black pigment preferably includes a compound having at least two benzofuran-2(3H)-one structures that may share a benzene ring or at least two benzofuran-3(2H)-one structures that may share a benzene ring, a geometric isomer thereof, a salt thereof, or a salt of a geometric isomer thereof. The perylene-based black pigment preferably includes a compound having a 3,4,9,10-perylenetetracarboxylic acid bisbenzimidazole structure, a geometric isomer thereof, a salt thereof, or a salt of a geometric isomer thereof. The azo-based black pigment preferably includes a compound having an azomethine structure and a carbazole structure, or a salt thereof.

With the above configuration, it is considered that these pigments promote the surface modification action on the surface of the conductive inorganic layer in the opening of the insulating resin layer. Therefore, it is presumed that the effects of achieving low voltage drive of light emission characteristics and improving the luminance become remarkable. In addition, since these pigments are excellent in light-shielding property and insulation property per unit mass as compared with general pigments, the effect of improving the reliability and migration resistance of the light-emitting element becomes remarkable.

In the element of the present invention, it is also preferable that the pigment in the insulating resin layer has a coating layer from the viewpoint of achieving low voltage drive of light emission characteristics, improving reliability of the light-emitting element, and improving migration resistance. The coating layer refers to a layer that coats the surface of the pigment, and examples thereof include a layer formed by a surface treatment with a silane coupling agent or a coating treatment with a resin. The coating layer preferably has one or more layers selected from the group consisting of a silica coating layer, a metal oxide coating layer, and a metal hydroxide coating layer.

### <(XG) Inorganic Particles in Insulating Resin Layer>

In the element of the present invention, the insulating resin layer preferably contains (XG) inorganic particles from the viewpoint of improving the reliability and migration resistance of the light-emitting element. The (XG) inorganic particles refer to particles including an element selected from the group consisting of a metal element, a metalloid element, and a semiconductor element as a main component element. The element as a main component in the inorganic particles refers to an element that is included most on a mass basis in the constituent elements of the inorganic particles. With the above configuration, the heat resistance of the insulating resin layer is improved by the robust structure of the (XG) inorganic particles in the insulating resin layer, and outgassing is suppressed, so that the effects of improving the reliability and migration resistance of the light-emitting element become remarkable.

The (XG) inorganic particles preferably include Si, Al, Ti, V, Zn, Zr, Nb, Sn, Li, Cr, Mn, Fe, Co, Ni, Cu, Sr, Ag, Ba, La, Ce, Ta, W, or Re as a main component element, and more preferably include silicon as a main component element. The element of the main component in the inorganic particles is determined on the basis of the mass of any of the above elements alone. As the (XG) inorganic particles, silica particles, alumina particles, titania particles, vanadium oxide particles, chromium oxide particles, iron oxide particles, cobalt oxide particles, copper oxide particles, zinc oxide particles, zirconium oxide particles, niobium oxide particles, tin oxide particles, or cerium oxide particles are preferable, and silica particles are more preferable. With the above configuration, reflection and scattering of incident external light on the surface of the insulating resin layer are reduced, so that the effect of suppressing external light reflection becomes remarkable.

<Compound Derived from Thermal Colorant or Oxidative Colorant in Insulating Resin Layer>

In the element of the present invention, from the viewpoint of suppressing external light reflection, the insulating resin layer preferably includes a compound having a structure derived from a thermal colorant and/or a compound having a structure derived from an oxidative colorant. Here, the structure derived from the thermal colorant and the structure derived from the oxidative colorant mean a structure after the thermal colorant and the oxidative colorant are structurally changed by heating or a structure after the thermal colorant and the oxidative colorant are decomposed by heating, respectively. As the structure in which the insulating resin layer has a structure derived from a thermal colorant and/or a structure derived from an oxidative colorant, a quinone structure and/or a quinoid structure is more preferable. The structure derived from the thermal colorant and the structure derived from the oxidative colorant may include the structure of the thermal colorant or the structure of the oxidative colorant described later.

In the element of the present invention, the insulating resin layer preferably includes a compound having a quinone structure and/or a quinoid structure derived from a compound having an aromatic structure in which at least three phenolic hydroxyl groups are bonded, emission characteristics, improving reliability of the light-emitting element, and improving migration resistance. In addition, in the element of the present invention, from the same viewpoint of the effect of the present invention, it is also preferable that the insulating resin layer includes a compound having a crosslinked structure (hereinafter, “specific crosslinked structure”) between a compound having an aromatic structure in which at least three phenolic hydroxyl groups are bonded and a compound having a structure represented by Formula (11). The number of specific crosslinked structures in the compound having a specific crosslinked structure is preferably 2 or more, more preferably 3 or more, still more preferably 4 or more, and particularly preferably 6 or more from the viewpoint of the effects of the invention described above. On the other hand, the upper limit of the number of specific crosslinked structures is not particularly limited, but may be 20 or less from the viewpoint of the effects of the invention described above,

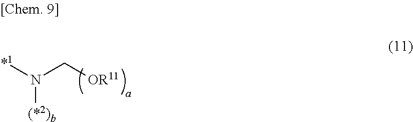

In Formula (11), R¹¹ represents a hydrogen atom or an alkyl group having 1 to 10 carbon atoms. *¹ and *² each independently represent a bonding point, but a carbonyl group is not adjacent to a nitrogen atom. a represents 1 or 2. b represents 0 or 1. Note that a+b=2. From the viewpoint of the effects of the invention described above, it is preferable that at least one of *¹ and *² is a bonding point with an aromatic structure, an aromatic heterocyclic structure, a condensed polycyclic structure, or a condensed polycyclic heterocyclic structure. It is also preferable that both *¹ and *² are bonding points with an aromatic structure, an aromatic heterocyclic structure, a condensed polycyclic structure, or a condensed polycyclic heterocyclic structure. At the bonding points *¹ and +2, from the viewpoint of the effects of the invention described above, the aromatic structure is preferably a benzene structure, a biphenyl structure, or a terphenyl structure, the aromatic heterocyclic structure is preferably a triazine structure, an isocyanuric acid structure, a pyrrole structure, an imidazole structure, or a triazole structure, the condensed polycyclic structure is preferably a fluorene structure or a naphthalene structure, and the condensed polycyclic heterocyclic structure is preferably a carbazole structure, an indole structure, a benzimidazole structure, or a benzotriazole structure. At the bonding point of *¹ and *², a triazine structure is more preferable as the aromatic heterocyclic structure.

From the viewpoint of the effects of the invention described above, a compound having an aromatic structure in which at least three phenolic hydroxyl groups are bonded is preferably 1,2,4-trihydroxybenzene or pyrogallol. The compound having the structure represented by Formula (11) preferably has at least one crosslinking group at a nitrogen atom, and the crosslinking group is preferably an alkoxymethyl group and/or a methylol group. As the alkoxymethyl group, a methoxymethyl group, an ethoxymethyl group, or a butoxymethyl group is preferable, and a methoxymethyl group is more preferable. As the compound having a specific crosslinked structure, a compound having one or more structures selected from the group consisting of a structure represented by Formula (12), a structure represented by the Formula (13), a quinone structure having a structure represented by Formula (12) or (13), and a quinoid structure having a structure represented by Formula (12) or (13) is preferable from the viewpoint of the effects of the invention described above.

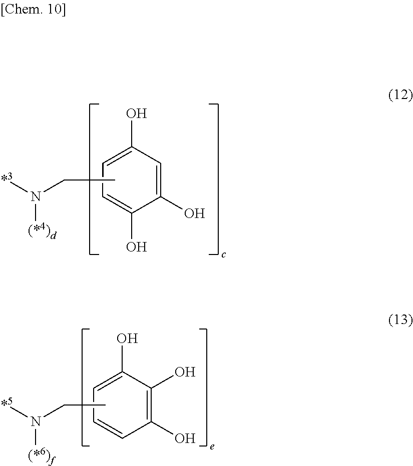

In Formulas (12) and (13), *³, *⁴, *⁵, and *⁶ each independently represent a bonding point, but a carbonyl group is not adjacent to a nitrogen atom. c represents 1 or 2. d represents 0 or 1. Note that c+d=2. e represents 1 or 2. f represents 0 or 1. Note that e+f=2. Examples and preferred descriptions for *³, *⁴, *⁵, and *⁶ are as described for *¹ and *² above.

With the above configuration, it is considered that these compounds promote the surface modification action on the surface of the conductive inorganic layer in the opening of the insulating resin layer. Therefore, it is presumed that the effects of achieving low voltage drive of light emission characteristics and improving the luminance become remarkable. In addition, these compounds contribute to improving the light-shielding property, and have a structure corresponding to a residue after forming a crosslinked structure in a film by thermal reaction. Therefore, the improvement in the degree of crosslinking in the film also contributes to the improvement in heat resistance and the suppression of outgassing, so that the effects of improving the reliability and migration resistance of the light-emitting element become remarkable.

### <Compound in Insulating Resin Layer>

In the element of the present invention, the insulating resin layer preferably includes an (XC1x) compound having one or more compounds selected from the group consisting of: a carboxylic acid having an indene structure, a carboxylic acid ester having an indene structure, a sulfonic acid having an indene structure, and a sulfonic acid aryl ester having an indene structure, and/or an (XC2x) compound having a fluorene structure, a carbazole structure, an indole structure, or a diphenyl sulfide structure, and having a structure in which an imino group is bonded to these structures and/or a structure in which a carbonyl group is bonded to these structures, from the viewpoint of achieving low voltage drive of light emission characteristics, improving the reliability of the light-emitting element, and improving the migration resistance. The (XC1x) compound in the insulating resin layer is more preferably a compound having a 1H-indene-3 carboxylic acid ester-7-sulfonic acid aryl ester structure and/or a compound having a 1H-indene-1 sulfonic acid aryl ester-3 carboxylic acid ester structure. As the (XC1x) compound in the insulating resin layer, a compound having a 1,2-naphthoquinonediazide-5 sulfonic acid ester structure and/or a compound having a 1,2-naphthoquinonediazide-4 sulfonic acid ester structure in the (C1) naphthoquinonediazide compound described later is preferable, and a compound having a structure derived from these compounds is also preferable. As the (XC2x) compound in the insulating resin layer, a compound having an oxime ester structure and/or a compound having an oxime ester carbonyl structure in the (C2) photopolymerization initiator described later is preferable, and a compound having a structure derived from these compounds is also preferable.

With the above configuration, it is considered that these compounds promote the surface modification action on the surface of the conductive inorganic layer in the opening of the insulating resin layer. Therefore, it is presumed that the effects of achieving low voltage drive of light emission characteristics and improving the luminance become remarkable. In addition, these compounds have a structure corresponding to a residue after a crosslinked structure is formed in a film by radical polymerization and/or thermal reaction. Therefore, since the improvement in the degree of crosslinking in the film contributes to the improvement in heat resistance and the suppression of outgassing, the effects of improving the reliability and migration resistance of the light-emitting element become remarkable.

In the element of the present invention, the insulating resin layer preferably includes a (XH) nitrogen-containing compound from the viewpoint of achieving low voltage drive of light emission characteristics, improving reliability of the light-emitting element, and improving migration resistance. The (XH) nitrogen-containing compound preferably includes one or more compounds selected from the group consisting of a cyclic amide compound, an amide compound, a cyclic urea compound, a urea compound, an oxazolidone compound, and an isoxazolidone compound (hereinafter, “specific nitrogen-containing compound”), and satisfies the following condition (X4). When the insulating resin layer includes one or more resins selected from the group consisting of polyimide-based resins, the insulating resin layer preferably includes the (XH) nitrogen-containing compound, and more preferably satisfies the following condition (X4) from the viewpoint of the effects of the invention described above.
(X4) The total content of the cyclic amide compound, the amide compound, the cyclic urea compound, the urea compound, the oxazolidone compound, and the isoxazolidone compound in the insulating resin layer is 0.010 mass % or more and 5.0 mass % or less.

From the viewpoint of the effects of the invention described above, the specific nitrogen-containing compound preferably includes one or more compounds selected from the group consisting of a cyclic amide compound represented by Formula (20), an amide compound represented by Formula (21), a cyclic urea compound represented by Formula (22), a urea compound represented by Formula (23), an oxazolidone compound represented by Formula (24), and an isoxazolidone compound represented by Formula (25).

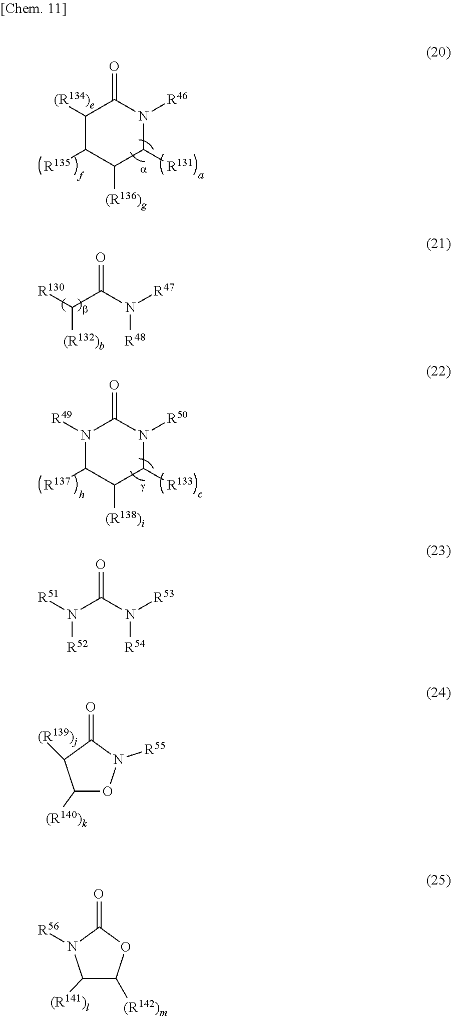

In Formulas (20) to (25), R⁴⁶ to R⁵⁶ each independently represent a hydrogen atom, an alkyl group having 1 to 6 carbon atoms, a cycloalkyl group having 4 to 10 carbon atoms, an aryl group having 6 to 15 carbon atoms, an alkenyl group having 2 to 6 carbon atoms, or a hydroxyalkyl group having 1 to 6 carbon atoms. R¹³⁰ represents a hydrogen atom, an alkyl group having 1 to 6 carbon atoms, an alkoxy group having 1 to 6 carbon atoms, a hydroxyalkyl group having 1 to 6 carbon atoms, a hydroxyalkoxy group having 1 to 6 carbon atoms, a hydroxy group, an amino group, a monoalkylamino group having 1 to 6 carbon atoms, or a dialkylamino group having 2 to 12 carbon atoms. R¹³¹ to R¹⁴² each independently represent an alkyl group having 1 to 6 carbon atoms. a, B, and γ each independently represent an integer of 0 to 6. a, b, c, e, f, g, h, i, j, k, l, and m each independently represent an integer of 0 to 2. In a case where α is 0, a is 0. In a case where β is 0, b is 0. In a case where γ is 0, c is 0. The substituents and structures described above may have a hetero atom, and may be either unsubstituted or substituted.

Specific nitrogen-containing compounds are preferably N-methyl-2-pyrrolidone, N-ethyl-2-pyrrolidone, N-butyl-2-pyrrolidone, N-cyclohexyl-2-pyrrolidone, N-vinyl-2-pyrrolidone, N,N-dimethylformamide, N,N-diethylformamide, N,N-dimethylacetamide, N,N-dimethylpropionamide, N,N-dimethylisobutyramide, N,N-dimethyl-3-methoxypropionamide, N,N-dimethyl-3-butoxypropionamide, 1,3-dimethyl-2-imidazolidinone, 1,3-diethyl-2-imidazolidinone, N,N′-dimethylpropyleneurea, 1, 1, 3, 3-tetramethylurea, 1, 1, 3, 3-tetraethylurea, N-methyl-2-oxazolidone, N-ethyl-2-oxazolidone, N-methyl-3-isoxazolidone or N-ethyl-3-isoxazolidone.

The total content of the specific nitrogen-containing compound in the insulating resin layer is preferably 0.030 mass % or more, more preferably 0.050 mass % or more, still more preferably 0.070 mass % or more, and particularly preferably 0.10 mass % or more from the viewpoint of the effects of the invention described above. On the other hand, the total content of the specific nitrogen-containing compound is preferably 4.0 mass % or less, more preferably 3.5 mass % or less, still more preferably 3.0 mass % or less from the viewpoint of the effects of the invention described above. The total content of the specific nitrogen-containing compound is preferably 2.5 mass % or less, more preferably 2.0 mass % or less, still more preferably 1.5 mass % or less, still more preferably 1.0 mass& or less, particularly preferably 0.70 mass % or less, and most preferably 0.50 mass % or less.

With the above configuration, it is considered that these compounds promote the surface modification action on the surface of the conductive inorganic layer in the opening of the insulating resin layer. Therefore, it is presumed that the effects of achieving low voltage drive of light emission characteristics and improving the luminance become remarkable. In addition, these compounds have a function as a catalyst that promotes a crosslinking reaction in the film by a thermal reaction. Therefore, since the improvement in the degree of crosslinking in the film contributes to the improvement in heat resistance and the suppression of outgassing, the effects of improving the reliability and migration resistance of the light-emitting element become remarkable.

### <Light-Emitting Layer and Pixel Area>

The display device of the present invention preferably has a light-emitting layer. The light-emitting layer may be either an organic layer or an inorganic layer and may have an organic layer and an inorganic layer. The light-emitting layer preferably has a laminated structure formed on the first electrode and between the first electrode and the second electrode. With such a configuration, a pixel area can be formed. The light-emitting layer preferably has an organic EL layer. The organic EL layer preferably further includes one or more layers selected from the group consisting of a hole injection layer, a hole transport layer, an electron transport layer, and an electron injection layer. The organic EL display preferably has such a configuration. The light-emitting layer preferably has an inorganic semiconductor layer, and more preferably has a micro LED or a mini LED. It is also suitable for the micro LED display or the mini LED display to have such a configuration. The display device of the present invention preferably includes a light-emitting layer portion in plan view. The above-described light-emitting layer in plan view corresponds to a light-emitting layer portion. In plan view, the pixel area is preferably a portion where the light-emitting layer portion is formed on the first electrode portion in the opening of the pixel division layer portion.

### <Sealing Layer>

The display device of the present invention preferably has a sealing layer from the viewpoint of improving the reliability of the light-emitting element. The sealing layer is a layer that seals a laminated structure having a light-emitting layer, shields from the outside world, and suppresses intrusion of moisture, gas, and the like. The sealing layer is preferably a cured product obtained by curing the composition, or an inorganic layer containing a metal element or silicon. The sealing layer preferably transmits a wavelength of visible light.

### <Color Filter Layer>

The display device of the present invention preferably includes a color filter layer from the viewpoint of improving light emission luminance and suppressing external light reflection. The color filter layer is a layer that is located on the light extraction side away from the pixel division layer and the pixel area and adjusts the emission spectrum and the reflected light. The color filter layer is preferably colored at a wavelength of visible light by coloring of components such as a resin in the photosensitive composition. Here, coloring means being red, orange, yellow, green, blue, or purple.

### <Black Matrix Layer>

The display device of the present invention preferably has a black matrix layer from the viewpoint of suppressing external light reflection. The black matrix layer is a layer that is located on the light extraction side away from the pixel division layer and the pixel area and adjusts the light emitting region. The black matrix layer is preferably black. The black matrix layer can be made black by coloring components such as a resin in the photosensitive composition.

### <Wavelength Conversion Layer>

The display device of the present invention preferably includes a wavelength conversion layer from the viewpoint of improving the luminance and the color purity of the emitted color. The wavelength conversion layer is a layer that is located on the light extraction side away from the pixel division layer and the pixel area, and adjusts the emission spectrum of the display device by wavelength-converting the light emitted from the light-emitting layer. The wavelength conversion layer preferably includes a quantum dot, a fluorescent compound, or a phosphorescent compound, and more preferably has a quantum dot. The wavelength conversion layer is also preferably formed from a composition including a quantum dot, a fluorescent compound, or a phosphorescent compound. The composition may be either a photosensitive composition or a non-photosensitive composition. When the display device has a wavelength conversion layer, the light-emitting layer is preferably an organic EL layer that emits blue light or white light, or an inorganic semiconductor layer that emits blue light or white light. When the wavelength conversion layer has quantum dots, the quantum dot display preferably has such a configuration. When the wavelength conversion layer has a fluorescent compound or a phosphorescent. compound, it is also suitable that the organic EL display, the micro LED display, or the mini LED display has such a configuration.

It is preferable that the display device of the present invention further includes a wavelength conversion layer and/or a color filter layer, and the wavelength conversion layer includes a quantum dot, a fluorescent compound, or a phosphorescent compound, from the viewpoint of improving the luminance, improving the emission color purity, and suppressing external light reflection.

### <TFT Element Layer>

The display device of the present invention preferably further includes a TFT element layer. The TFT element layer more preferably includes a semiconductor layer, a source electrode, a drain electrode, a gate electrode, and a gate insulating layer. When the display device of the present invention includes a TFT element layer, it is preferable that the display device further includes an interlayer insulating layer that insulates between the conductive layer on the TFT element layer and the TFT element layer, and interlayer insulating layers that insulate between the plurality of conductive layers on the TET element layer. Examples of the semiconductor layer include a silicon semiconductor layer such as polycrystalline silicon (p-Si), an oxide semiconductor layer such as indium gallium zinc oxide (IGZO), and low temperature polycrystalline oxide (LTPO) in which polycrystalline silicon and an oxide semiconductor are used in combination.

### <TFT Planarization Layer and TFT Protective Layer>

The display device of the present invention preferably further includes a TFT planarization layer and/or a TFT protective layer. The TFT planarization layer and the TFT protective layer are preferably at least two layers. In the display device of the present invention, the insulating resin layer is preferably the TFT planarization layer, and the conductive inorganic layer is preferably a metal wiring layer. The conductive inorganic layer is preferably the metal wiring layer below the TFT planarization layer. The TFT planarization layer or the TFT protective layer is a layer that planarizes or protects the surface of the laminated structure including the TFT element. The TFT planarization layer and the TFT protective layer are preferably black. The TFT planarization layer and the TFT protective layer can be made black by coloring components such as a resin in the photosensitive composition. The pixel area described above is preferably formed so as to overlap the TFT planarization layer and/or the TFT protective layer from the viewpoint of suppressing external light reflection and improving luminance.

### <Interlayer Insulating Layer>

The display device of the present invention preferably further includes an interlayer insulating layer from the viewpoint of improving the integration density by multilayering of wirings, electrodes, and the like and improving the resolution of the display device. The interlayer insulating layer is preferably at least two layers. The interlayer insulating layer is a layer that insulates a conductive layer such as a wiring or an electrode in the laminated structure. The interlayer insulating layer is preferably an interlayer insulating layer that insulates the conductive layer below the TFT planarization layer. The interlayer insulating layer is preferably black. The interlayer insulating layer can be made black by coloring components such as a resin in the photosensitive composition.

<Method for Forming Conductive Inorganic Layer or the Like in which Detection Intensity of Each Ion is in Specific Range>

In the element of the present invention or the display device of the present invention, examples of the method for forming the conductive inorganic layer, the first electrode, or the metal wiring layer in which the detection intensity of a fluorine ion, a chlorine ion, a bromine ion, or a sulfur ion falls within a specific range include the following methods (I) to (V). As the forming method, two or more methods selected from the group consisting of the following methods (I) to (V) may also be used. The fluorine element, the chlorine element, the bromine element, and the sulfur element may be collectively referred to as a fluorine element or the like. In addition, a compound having a fluorine atom or a fluoride ion in the structure, a component including a fluorine element, and a component including a fluoride ion may be collectively referred to as compound or the like including a fluorine atom or the like.
(I) A method in which a pattern of a composition on a conductive inorganic layer or the like is formed using a photosensitive composition in which the content of a compound or the like including a fluorine atom or the like is a specific value or less to expose the surface of the conductive inorganic layer or the like (hereinafter, “method (I)”).
(II) A method in which a coating film of a composition is formed on a conductive inorganic layer or the like using a non-photosensitive composition in which the content of a compound or the like including a fluorine atom or the like is a specific value or less, and then the obtained coating film is subjected to pattern processing to expose the surface of the conductive inorganic layer or the like (hereinafter, “method (II)”).
(III) A method in which a solution including a compound or the like including a fluorine atom or the like is brought into contact with a surface of a conductive inorganic layer or the like (hereinafter, “method (III)”).
(IV) A method in which a compound or the like including a fluorine atom or the like is gasified or a solution including the compound or the like is gasified and brought into contact with a surface of a conductive inorganic layer or the like (hereinafter, “method (IV)”).
(V) A method in which a compound or the like including a fluorine atom or the like is ionized or a solution or gas including the compound or the like is ionized and brought into contact with a surface of the conductive inorganic layer or the like (hereinafter, “method (V)”).

The method (I) is a method in which, when an insulating resin layer is formed using a photosensitive composition, the surface of the conductive inorganic layer or the like is surface-modified with a fluorine element or the like at the time of forming the pattern of a photosensitive composition. As a pattern forming method, a method of forming a pattern by a photolithography method is preferable.

The method (II) is a method in which, when an insulating resin layer is formed using a non-photosensitive composition, the surface of a conductive inorganic layer or the like is surface-modified with a fluorine element or the like at the time of forming a coating film of the non-photosensitive composition. As a pattern processing method of the obtained coating film, a method of performing pattern processing by a wet etching method or a dry etching method is preferable. As the patterning method, a method of patterning a coating film by using a photoresist and opening the coating film at once during development of the photoresist is also preferable.

The method (III), method (IV), and method (V) are methods for surface-modifying the surface of a conductive inorganic layer of the like using a solution, a gas, and an ion, respectively. As the method (III), a method using an acidic solution including fluoride ions is also preferable, and a method using hydrofluoric acid, buffered hydrofluoric acid, or fluoronitric acid is also preferable. As the method (IV), a method using a chemical vapor deposition method or a vacuum evaporation method is also preferable. As the method (IV), a method of irradiating with active actinic radiation under the above-described gas atmosphere is also preferable. As the method (V), a plasma chemical vapor deposition method, a sputtering method, or an ion implantation method is also preferable. As the method (V), a method using a reactive gas etching method, a plasma etching method, or a reactive ion etching method is also preferable.

The above forming methods preferably include a step of washing the conductive inorganic layer, the first electrode, or the metal wiring layer before the steps of the above methods (I) to (V). The cleaning step is preferably performed by a wet etching method, a dry etching method, an ashing method, or a method of irradiating active actinic radiation in a gas atmosphere. In the washing step, a compound or the like not including the fluorine atom or the like, or a solution or gas including the compound or the like is used. The solution to be used may be an acidic solution or an alkaline solution. The gas to be used may be a gas including oxygen, ozone, nitrogen, or argon. As the dry etching method, a reactive gas etching method, a plasma etching method, or a reactive ion etching method may be used.

### <Display Device According to Third and Fourth Aspects>

A display device according to a third aspect of the present invention includes the element of the present invention. It is preferable that the display device according to the third aspect of the present invention further includes a light-emitting element, the conductive inorganic layer is a metal wiring layer, and the insulating resin layer is a barrier layer and/or a planarization layer. Furthermore, in the display device according to the third aspect of the present invention, it is preferable that the light-emitting element and the metal wiring layer are electrically connected, the light-emitting element is a semiconductor chip, the barrier layer is formed between adjacent light-emitting elements, and the planarization layer is formed so as to cover at least a part of the light-emitting element.

In addition, it is also preferable that a display device according to the fourth aspect of the present invention further includes a light-emitting element and a metal wiring layer, the conductive inorganic layer is a redistribution layer, and the insulating resin layer is an interlayer insulating layer of the redistribution layer. Furthermore, in the display device according to the fourth aspect of the present invention, it is preferable that the light-emitting element and the metal wiring layer and/or the light-emitting element and the redistribution layer are electrically connected, and the light-emitting element is a semiconductor chip. In addition, in the display device according to the fourth aspect of the present invention, in plan view, the area of the redistribution layer is preferably larger than the area of the light-emitting element from the viewpoint of improving the integration density and suppressing the transmission loss between the wirings.

Examples of the display device according to the third and fourth aspects of the present invention include a micro LED display or a mini LED display.

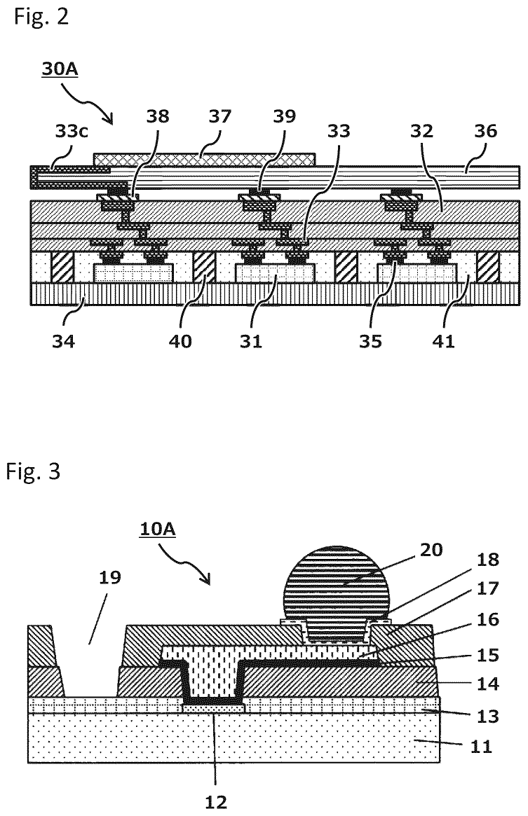

FIG. 2 is a schematic cross-sectional view illustrating an example of a display device 30A including an interlayer insulating layer, a barrier layer, and a planarization layer. The display device 30A includes a plurality of light-emitting elements 31 and a plurality of barrier layers 40 on a counter substrate 34, a planarization layer 41 is provided on the light-emitting elements 31, and an interlayer insulating layer 32 is provided on the planarization layer 41. The light-emitting element 31 is preferably a semiconductor chip. Being on the light-emitting element 31 may be not only the surface of the light-emitting element 31 but also the upper side of a support substrate or the light-emitting element 31. In the aspect illustrated in FIG. 2, a configuration in which the barrier layer 40 is provided between the plurality of adjacent light-emitting elements 31, the planarization layer 41 is formed so as to cover the light-emitting elements 31, and the plurality of interlayer insulating layers 32 are laminated on the planarization layer 41 is exemplified, but the interlayer insulating layer 32 may be a single layer. The light-emitting element 31 includes a pair of electrode terminals 35 on a surface opposite to a surface in contact with the counter substrate 34, and each electrode terminal 35 is electrically connected to the metal wiring 33 extending in the planarization layer 41 and the interlayer insulating layer 32. When the plurality of metal wirings 33 are covered with the planarization layer 41 or the interlayer insulating layer 32, these layers function as an insulating film, so that the electrical insulation property is maintained. Configuring the metal wiring to retain electrical insulation means that a portion of the metal wiring requiring electrical insulation is covered with a cured product obtained by curing a resin-containing composition. Furthermore, since the light-emitting element 31 is electrically connected to the driving element 37 included in the light-emitting element driving substrate 36 provided at a position facing the counter substrate 34 via the metal wiring 33 and the metal wiring 33c, light emission of the light-emitting element 31 can be controlled. The light-emitting element driving substrate 36 is electrically connected to the metal wiring 33 via solder bumps 39. Furthermore, a barrier metal 38 is provided to prevent diffusion of metal such as the metal wiring 33. The metal wiring 33c may penetrate the light-emitting element driving substrate 36 and be electrically connected to the driving element 37. The side of the light-emitting element 31 in contact with the counter substrate 34 in the display device 30A (the lower side in FIG. 2) is the light extraction side. From the viewpoint of improving the reliability of the light-emitting element, the display device 30A is preferably manufactured in a Chip-first (RDL-last) structure in which the light-emitting element 31, which is a semiconductor chip, is disposed on a support substrate or the like, and then the metal wiring 33 and the interlayer insulating layer 32 are formed. Thereafter, it is preferable that the light-emitting element driving substrate 36 is bonded, then the support substrate or the like is peeled off, and then the counter substrate 34 is bonded.

On the other hand, from the viewpoint of suppressing a decrease in panel yield and shortening the process time and improving productivity, the display device 30A is preferably manufactured in an RDL-first (Chip-last) structure in which the metal wiring 33 and the interlayer insulating layer 32 are formed on the light-emitting element driving substrate 36, and then the light-emitting element 31 as a semiconductor chip is disposed. Thereafter, the counter substrate 34 is preferably bonded.

The light-emitting element 31 is preferably a PN junction diode in which a P-type semiconductor and an N-type semiconductor are joined. The length of one side of the light-emitting element 31 is preferably 5 to 700 μm, and more preferably 5 to 100 μm. The interlayer insulating layer 32, the barrier layer 40, and the planarization layer 41 are preferably a cured product of a patterned photosensitive composition. A configuration in which the thickness of the planarization layer 41 is larger than the thickness of the barrier layer 40 is also preferable. In addition, a configuration in which the planarization layer 41 covers a part of the surface of the barrier layer 40 opposite to the surface in contact with the counter substrate 34 is also preferable, and a configuration in which the planarization layer 41 covers all of the surface of the barrier layer 40 opposite to the surface in contact with the counter substrate 34 is more preferable. One or more layers selected from the group consisting of the interlayer insulating layer 32, the barrier layer 40, and the planarization layer 41 are also preferably a cured product of the photosensitive composition of the present invention described later. The interlayer insulating layer 32 more preferably includes the above polyimide-based resin from the viewpoint of improving mechanical properties. By including the above polyimide-based resin, the warpage of the wafer or substrate is suppressed, and the effects of improving the accuracy of the exposure step and the conveyance step of the wafer or the substrate and suppressing the decrease in yield become remarkable. The barrier layer 40 preferably includes the above (XD) colorant from the viewpoint of suppressing external light reflection and improving the reliability of the light-emitting element. The barrier layer 40 preferably includes the above (XG) inorganic particles from the viewpoint of improving the luminance and improving the reliability of the light-emitting element.

### <Electronic Component and Hollow Structure>

The electronic component of the present invention includes the element of the present invention. In the electronic component of the present invention, the conductive inorganic layer is preferably a metal wiring layer, and the insulating resin layer is preferably an insulating layer of a metal wiring, a protective layer of a metal wiring, or an interlayer insulating layer of a metal wiring. Examples of the electronic component include a semiconductor device, an antenna, a metal-clad laminate, a wiring substrate, a semiconductor package, an active component including a semiconductor device, and a passive component.

A hollow structure of the present invention includes the element of the present invention. The electronic component of the present invention preferably has a hollow structure. In addition, the hollow structure of the present invention has a hollow structure support material and a hollow structure roof material. In the hollow structure of the present invention, it is preferable that the insulating resin layer is a hollow structure support material or a hollow structure roof material, and the conductive inorganic layer is a metal electrode or a metal wiring layer. The hollow structure support material and the hollow structure roof material preferably include the above polyimide-based resin from the viewpoint of improving heat resistance and reliability. Examples of the electronic component having a hollow structure include micro electro mechanical systems (MEMS).

### <Semiconductor Device>

A semiconductor device of the present invention includes the element of the present invention. It is preferable that the semiconductor device of the present invention further includes a semiconductor chip and a sealing material covering the semiconductor chip, and the conductive inorganic layer is a redistribution layer, and the insulating resin layer is an interlayer insulating layer of the redistribution layer. In addition, in the semiconductor device of the present invention, in plan view, the area of the redistribution layer is preferably larger than the area of the semiconductor chip from the viewpoint of improving the integration density and suppressing the transmission loss between the wirings. The sealing material covering the semiconductor chip is preferably in direct contact with the interlayer insulating layer of the redistribution layer. In addition, the sealing material covering the semiconductor chip preferably includes an epoxy resin, and more preferably includes a cured epoxy resin, from the viewpoint of improving heat resistance and reliability. Examples of the semiconductor device include a semiconductor device having a fan-out wafer level package structure, a fan-out panel level package structure, or an antenna-in-package structure. These package structures in the semiconductor device of the present invention may be either of structures including a single die or a multi-die, and a structure including a multi-die is preferable from the viewpoint of improving the integration density and suppressing transmission loss between wirings. The structure including the multi-die preferably has a chiplet structure, more preferably includes one or more types of dies selected from the group consisting of a logic, a memory, an analog IC (analog integrated circuit), an RF circuit (radio frequency circuit), and a power semiconductor, and still more preferably includes two or more types of dies.

FIG. 3 illustrates a schematic cross-sectional view illustrating an example of a pad portion of a semiconductor device 10A having bumps. On a silicon substrate 11 of the semiconductor device 10A, a passivation layer 13 is formed on an input/output A1 pad 12, and a via hole is formed in a passivation layer 13. On the passivation layer 13, an insulating layer 14 that is a cured product of a patterned photosensitive composition is formed, and a metal layer 15 of Cr, Ti or the like is formed so as to be connected to the Al pad 12, and a metal wiring 16 of Al, Cu or the like is formed by electrolytic plating or the like. The metal layer 15 etches the periphery of a solder bump 20 to insulate each pad. A barrier metal layer 18 and the solder bump 20 are formed on the insulated pad. An insulating layer 17, which is a cured product of a patterned photosensitive composition, is formed on the metal wiring 16. The photosensitive composition for forming the insulating layer 17 can form a pattern with a thick film in formation of a scribe line 19. The insulating layer 14 and/or the insulating layer 17 is also preferably a cured product of the photosensitive composition of the present invention described later. When the insulating layer 14 and/or the insulating layer 17 includes the above polyimide-based resin, since the mechanical properties are excellent in heating at a low temperature, warpage of the wafer is suppressed, and the effect of improving the accuracy of processes such as exposure and conveyance of the wafer becomes remarkable. In addition, since the stress of the sealing resin at the time of mounting the semiconductor can be alleviated, the damage of a low-k layer is suppressed, and the effect of improving the reliability of the semiconductor device becomes remarkable.

### <Other Electronic Articles>

An antenna of the present invention includes the element of the present invention. In the antenna of the present invention, it is preferable that the conductive inorganic layer is a metal wiring or a ground wiring, and the insulating resin layer is an insulating layer of the metal wiring, a protective layer of the metal wiring, or an interlayer insulating layer between the metal wiring and the ground wiring. Examples of the antenna include a microstrip line antenna and a strip line antenna.

The metal-clad laminate of the present invention includes the element of the present invention. In the metal-clad laminate of the present invention, it is preferable that the conductive inorganic layer is a metal wiring, and the insulating resin layer is an insulating layer of the metal wiring, a protective layer of the metal wiring, or a solder resist layer of the metal wiring. Examples of the metal-clad laminate include a printed circuit board.

### <Photosensitive Composition>

Hereinafter, the photosensitive composition of the present invention will be described. It is noted that the present invention is not limited to the following embodiments, and various modifications can naturally be made as long as the modifications can achieve the object of the invention and do not depart from the gist of the invention.

The photosensitive composition of the present invention has the following constitution.

A photosensitive composition including an (A) binder resin and a (C) photosensitive agent, and further including a (B) radical polymerizable compound and/or an (F) crosslinking agent, in which
the (A) binder resin includes an (A1) weakly acidic group-containing resin, and the (A1) weakly acidic group-containing resin has one or more groups selected from the group consisting of a (WA) weakly acidic group: a phenolic hydroxyl group, a hydroxyimide group, a hydroxyamide group, a silanol group, and a mercapto group,
the photosensitive composition
satisfies the following condition (1a), and
further includes water, and satisfies the following condition (3).
(1a) A content of a fluorine element in a total solid content of the photosensitive composition is 1, 000 ppm by mass or less.
(3) A content of water in the photosensitive composition is 0.010 mass % or more and 3.0 mass % or less.

With the above configuration, the photosensitive composition of the present invention can obtain a cured product included in a display device that is capable of suppressing residues after development, has excellent light emission characteristics capable of low voltage drive in obtaining a desired current density, and has excellent reliability of a light-emitting element. In addition, a cured product included in an electronic component or a semiconductor device having excellent migration resistance can be obtained. This is presumed to be because when the content of the compound or the like including a fluorine atom or the like in the photosensitive composition is set to a specific value or less, the content of the fluorine element or fluoride ion in these components or the anion including the fluorine element derived from these components is set to a specific value or less, and therefore protons in the photosensitive composition are locally activated by an interaction such as hydrogen bonding of each component in the photosensitive composition. Therefore, it is considered that the effect of suppressing the residue after development is achieved by the dissolution promoting action on the developer. In addition, since the surface of the substrate is surface-modified by these components, it is presumed that the effect of suppressing residues after development is achieved by preventing residue adhesion at the opening, and the effects of achieving low voltage drive of light emission characteristics and improving the luminance become remarkable. Furthermore, it is considered that by including a specific amount of water in the photosensitive composition, the hydrogen bond between the water molecule and the fluorine atom improves the stability of the component including the fluorine element and the anion including the fluorine element in the photosensitive composition, and contributes to the effect of suppressing the residue after development.

In addition, it is considered that by intentionally setting the content of the compound or the like including a fluorine atom or the like in the photosensitive composition to a specific value or less, the detection intensity of these ions on the surface of the resulting cured product is adjusted, and the polarization structure and charge balance in the cured product are controlled. As a result, it is presumed that the effect of high reliability or excellent migration resistance of the light-emitting element is achieved by suppressing ion migration and electromigration caused by metal impurities and ion impurities that adversely affect the light emission characteristics or electrical insulation properties. In addition, it is presumed that a highly reliable effect in a display device, an electronic component, or a semiconductor device is achieved by suppressing migration or aggregation of a metal in an electrode or a metal in a metal wiring.

Note that the total solid content of the composition refers to the total mass of all components except the solvent in the composition. The solid content concentration can be calculated as a solid content concentration calculated from the mass before and after heating by heating 1 g of the composition at 150° C for 30 minutes to evaporate to dryness and measuring the mass remaining after heating.

### <(A) Binder Resin>

The photosensitive composition of the present invention contains an (A) binder resin. The (A) binder resin is preferably a resin in which a crosslinked structure is formed and cured by a reaction. The reaction is not particularly limited, and is caused, for example, by heating, irradiation with an energy ray, or the like, and the crosslinked structure may be formed by an (F) crosslinking agent described later. The (A) binder resin preferably has heat resistance in which at least a part of the binder resin or a cured product thereof remains in a cured product obtained by curing the composition. The (A) binder resin is preferably a thermally cured resin.

The (A) binder resin is preferably a resin capable of imparting positive type or negative type photosensitivity to the composition by the later-described (C) photosensitive agent and forming a positive type or negative type pattern. The (A) binder resin is more preferably an alkali-soluble resin having an acidic group in the structural unit of the resin or an organic solvent-soluble resin having an organic solvent-soluble structure. From the viewpoint of improving the sensitivity for exposure, the (A) binder resin preferably has a radical polymerizable group, and more preferably has a radical polymerizable group in the structural unit of the resin. The radical polymerizable group is preferably a group having an ethylenically unsaturated double bond group, and more preferably a photoreactive group, an alkenyl group having 2 to 5 carbon atoms, or an alkynyl group having 2 to 5 carbon atoms.

In the photosensitive composition of the present invention, the (A) binder resin includes an (A1) weakly acidic group-containing resin, and the (A1) weakly acidic group-containing resin has one or more groups selected from the group consisting of (WA) weakly acidic groups: a phenolic hydroxyl group, a hydroxyimide group, a hydroxyamide group, a silanol group, and a mercapto group. The (A1) weakly acidic group-containing resin preferably includes (A1x) resin: resin having one or more structures selected from the group consisting of an imide structure, an amide structure, an oxazole structure, and a siloxane structure (hereinafter, “imide structure and the like”) in the structural unit of the resin, and/or (Aly) resin: resin having a phenolic hydroxyl group in the structural unit of the resin.

The (A1) weakly acidic group-containing resin preferably includes the (A1x) resin from the viewpoint of achieving low voltage drive of light emission characteristics, improving reliability of the light-emitting element, and improving migration resistance. The (A1x) resin preferably includes one or more resins selected from the group consisting of a polyimide, a polyimide precursor, a polybenzoxazole, a polybenzoxazole precursor, a polyamideimide, a polyamideimide precursor, a polyamide, a polysiloxane, a maleimide resin, a maleimide-styrene resin, a maleimide-triazine resin, a maleimide-oxazine resin, and copolymers thereof, and more preferably includes one or more resins selected from the group consisting of a polyimide, a polyimide precursor, a polybenzoxazole, a polybenzoxazole precursor, a polyamideimide, a polyamideimide precursor, and copolymers thereof (hereinafter, “polyimide-based resin having a weakly acidic group”). The polyimide-based resin having a weakly acidic group may be further a copolymer with a polyamide. The (A1x) resin may be a single resin or a copolymer thereof.

It is also preferable that the (A1) weakly acidic group-containing resin includes the (Aly) resin from the viewpoint of suppressing residues after development, improving the reliability of the light-emitting element, and improving the migration resistance. The (Aly) resin preferably includes one or more resins selected from the group consisting of a phenolic resin, polyhydroxystyrene, a phenol group-containing epoxy resin, and a phenol group-containing acrylic resin. The (Aly) resin may be a single resin or a copolymer thereof.

The (A) binder resin preferably contains an (A2) resin having no weakly acidic group (hereinafter, “(A2) resin”) from the viewpoint of residue suppression after development. From the viewpoint of suppressing residues after development, the (A2) resin preferably has a carboxy group, a carboxylic anhydride group, or a sulfonic acid group, and more preferably includes one or more resins selected from the group consisting of a cardo-based resin, an epoxy (meth)acrylate resin, and an acrylic resin. The (A2) resin may be a single resin or a copolymer thereof. From the viewpoint of improving the sensitivity for exposure, the (A2) resin preferably has a radical polymerizable group, and more preferably has a radical polymerizable group in the structural unit of the resin. Examples and preferred descriptions of the radical polymerizable group are as described for the above (A) binder resin.

The (A2) resin preferably includes a resin having one or more structures selected from the group consisting of an imide structure, an amide structure, an oxazole structure, and a siloxane structure (hereinafter, “imide structure and the like”) in the structural unit of the resin from the viewpoint of improving the reliability of the light-emitting element having light emission characteristics. The (A2) resin preferably includes one or more resins selected from the group consisting of a polyimide, a polyimide precursor, a polybenzoxazole, a polybenzoxazole precursor, a polyamideimide, a polyamideimide precursor, a polyamide, a polysiloxane, a maleimide resin, a maleimide-styrene resin, a maleimide-triazine resin, a maleimide-oxazine resin, and copolymers thereof, and more preferably includes one or more resins selected from the group consisting of a polyimide, a polyimide precursor, a polybenzoxazole, a polybenzoxazole precursor, a polyamideimide, a polyamideimide precursor, and copolymers thereof (hereinafter, “polyimide-based resin having no weakly acidic group”). The polyimide-based resin having no weakly acidic group may further be a copolymer with a polyamide. The (A2) resin may be a single resin or a copolymer thereof. A polyimide-based resin having a weakly acidic group and a polyimide-based resin having no weakly acidic group may be collectively referred to as a polyimide-based resin.

### <(B) Radical Polymerizable Compound>

The photosensitive composition of the present invention further contains a (B) radical polymerizable compound (hereinafter, “(B) compound”) and/or an (F) crosslinking agent. The (B) radical polymerizable compound refers to a compound having a radical polymerizable group. Examples and preferred descriptions of the radical polymerizable group are as described for the above (A) binder resin. The radical polymerizable group is preferably a (meth)acryloyl group from the viewpoint of improving the sensitivity for exposure. The number of radical polymerizable groups in the (B) compound is preferably 2 or more, more preferably 3 or more, still more preferably 4 or more from the viewpoint of improving the sensitivity for exposure. On the other hand, the number of radical polymerizable groups is preferably 12 or less, more preferably 10 or less, still more preferably 8 or less, and particularly preferably 6 or less from the viewpoint of suppressing residues after development.

The (F) crosslinking agent will be described later.

### <(C) Photosensitive Agent>

The photosensitive composition of the present invention includes a (C) photosensitive agent. The (C) photosensitive agent refers to a compound that gives positive type or negative type photosensitivity to a composition by bond cleavage, reaction, or structural change by exposure to generate another compound. The (C) photosensitive agent preferably includes one or more compounds selected from the group consisting of a (C1) naphthoquinonediazide compound (hereinafter, “(C1) compound”), a (C2) photopolymerization initiator (hereinafter, “(C2) compound”), a (C3) photoacid generator (hereinafter, “(C3) compound”), and a (C4) photobase generator (hereinafter, “(C4) compound”). The (C1) compound refers to a compound whose structure is changed by exposure to generate an indene carboxylic acid and/or a sulfoindene carboxylic acid. The (C2) compound refers to a compound that undergoes bond cleavage and/or reaction upon exposure to generate radicals. The (C3) compound refers to a compound that undergoes bond cleavage and/or reaction upon exposure to light to generate an acid. The (C4) compound refers to a compound that undergoes bond cleavage and/or reaction upon exposure to generate a base. Note that the (C1) compound is not included in the (C3) compound.

The (C1) compound preferably includes a compound having a 1,2-naphthoquinonediazide-5-sulfonic acid ester structure (hereinafter, “5-ester structure”) and/or a compound having a 1,2-naphthoquinonediazide-4-sulfonic acid ester structure (hereinafter, “4-ester structure”), and more preferably includes a compound having a 5-ester structure and a compound having a 4-ester structure, from the viewpoint of improving the sensitivity for exposure, suppressing the residue after development, and improving the resolution after development. The (C1) compound preferably has a 5-ester structure of a phenolic hydroxyl group or a 4-ester structure of a phenolic hydroxyl group. The (C2) compound preferably includes a compound having an oxime ester structure (hereinafter, “α-oxime structure”) and/or a compound having an oxime ester carbonyl structure (hereinafter, “β-oxime structure”) from the viewpoint of improving the sensitivity for exposure, improving the reliability of the light-emitting element, and improving the migration resistance.

### <(F) Crosslinking Agent>

The (F) crosslinking agent refers to a compound having a crosslinking group, a cationically polymerizable group, or an anionically polymerizable group capable of reacting with a resin or the like. From the viewpoint of improving the reliability and migration resistance of the light-emitting element, the (F) crosslinking agent preferably has one or more groups selected from the group consisting of an alkoxyalkyl group, a hydroxyalkyl group, an epoxy group, an oxetanyl group, and a blocked isocyanate group (hereinafter, “specific crosslinking group”). The alkoxyalkyl group is preferably an alkoxymethyl group or an alkoxyethyl group, and more preferably a methoxymethyl group or a methoxyethyl group. The hydroxyalkyl group is preferably a methylol group or an ethylol group. The number of specific crosslinking groups contained in the (F) crosslinking agent is preferably 2 or more, more preferably 3 or more, still more preferably 4 or more, and particularly preferably 6 or more, from the viewpoint of improving the reliability of the light-emitting element and improving the migration resistance. On the other hand, the number of specific crosslinking groups is preferably 12 or less, more preferably 10 or less, still more preferably 8 or less from the viewpoint of suppressing residues after development.

### <(D) Colorant, Thermal Colorant, Oxidative Colorant, (E) Dispersant, and (G) Inorganic Particles>

From the viewpoint of suppressing external light reflection, the photosensitive composition of the present invention preferably further includes the (D) colorant. The (D) colorant refers to a compound that is colored by absorbing any light within the wavelength (380 to 780 nm) range of visible light. The (D) colorant is preferably a pigment or a dye. The (D) colorant preferably includes a blacking agent or a colorant mixture of two or more colorants. The blacking agent preferably includes an organic black pigment and/or an inorganic black pigment.

From the viewpoint of suppressing external light reflection, the photosensitive composition of the present invention preferably further contains a thermal colorant and/or an oxidative colorant. The thermal colorant refers to a compound that is colored by absorbing any light within the wavelength (380 to 780 nm) range of visible light after heating in an inert atmosphere. The oxidative colorant refers to a compound that absorbs any light within the wavelength (380 to 780 nm) range of visible light to color after heating in an oxygen-containing gas atmosphere. The thermal colorant and the oxidative colorant are preferably compounds having a structure that changes in structure after heating or a structure that decomposes after heating. The thermal colorant and the oxidative colorant preferably include a compound having an aromatic structure in which at least two phenolic hydroxyl groups are bonded, and more preferably include a compound having an aromatic structure in which at least three phenolic hydroxyl groups are bonded.

From the viewpoint of improving the dispersion stability of the pigment, the photosensitive composition of the present invention preferably further includes the (E) dispersant. The (E) dispersant refers to a compound having a structure that interacts with the surface of a pigment and a structure that inhibits approach of pigments to each other. The (E) dispersant preferably has a basic group, an acidic group, or a salt structure thereof, and more preferably has a basic group or a salt structure thereof.

The photosensitive composition of the present invention preferably further includes (G) inorganic particles from the viewpoint of improving the reliability of the light-emitting element and improving the migration resistance. The (G) inorganic particles refer to particles including an element selected from the group consisting of a metal element, a metalloid element, and a semiconductor element as a main component element. The element as a main component in the inorganic particles refers to an element that is included most on a mass basis in the constituent elements of the inorganic particles. The (G) inorganic particles preferably have a hydroxy group and/or a silanol group on the particle surface. The (G) inorganic particles preferably include silica particles from the viewpoint of suppressing external light reflection.

### <Content of Fluorine Element>

The photosensitive composition of the present invention preferably satisfies the following condition (1a) described later from the viewpoint of suppressing residues after development, achieving low voltage drive of light emission characteristics, improving the reliability of the light-emitting element, and improving the migration resistance. From the viewpoint of the effects of the present invention described above, the photosensitive composition of the present invention more preferably further satisfies the following condition (2a) described later.

In the photosensitive composition of the present invention, it is preferable that the (A) binder resin, the (C) photosensitive agent, the (B) radical polymerizable compound, or the (F) crosslinking agent have a fluorine atom or a fluoride ion in the structure, or the photosensitive composition further includes a component including a fluorine element and/or a component including a fluoride ion, and satisfies the following condition (1a). The photosensitive composition of the present invention more preferably further satisfies the following condition (2a).
(1a) The content of the fluorine element in the total solid content of the photosensitive composition is 1, 000 ppm by mass or less.
(2a) The content of fluoride ions in the total solid content of the photosensitive composition is 1, 000 ppm by mass or less.

As the component including a fluorine element, a phenol compound having a substituent including a fluorinated alkyl group, a fluorinated alkyl compound, a fluorinated cycloalkyl compound, or a fluorinated aryl. compound is preferable. As the component including a fluoride ion, a component including an ammonium ion, a primary ammonium ion, a secondary ammonium ion, a tertiary ammonium ion, or a quaternary ammonium ion as a cationic species is preferable. The quaternary ammonium ion preferably has a linear or branched hydrocarbon group. The hydrocarbon group is preferably an alkyl group having 1 to 15 carbon atoms, a cycloalkyl group having 4 to 10 carbon atoms, an aryl group having 6 to 15 carbon atoms, an alkenyl group having 2 to 6 carbon atoms, or a hydroxyalkyl group having 1 to 6 carbon atoms, more preferably an alkyl group having 1 to 10 carbon atoms, and still more preferably an alkyl group having 1 to 6 carbon atoms.

The content of the fluorine element in the total solid content of the photosensitive composition is preferably 0 ppm by mass or more, more preferably 0.010 ppm by mass or more, still more preferably 0.030 ppm by mass or more, still more preferably 0.050 ppm by mass or more, particularly preferably 0.070 ppm by mass or more, and most preferably 0.10 ppm by mass or more from the viewpoint of suppressing residues after development, achieving low voltage drive of light emission characteristics, improving the reliability of the light-emitting element, and improving the migration resistance. On the other hand, from the viewpoint of the effects of the invention described above, the content of the fluorine element is preferably 1, 000 ppm by mass or less, more preferably 500 ppm by mass or less, still more preferably 300 ppm by mass or less, and particularly preferably 100 ppm by mass or less. Furthermore, the content of the fluorine element is preferably 50 ppm by mass or less, more preferably 30 ppm by mass or less, still more preferably 10 ppm by mass or less, even more preferably 5 ppm by mass or less, particularly preferably 3 ppm by mass or less, and most preferably 1 ppm by mass or less.

The preferred range of the content of the fluoride ion in the total solid content of the photosensitive composition is also the same as the preferred range of the content of the fluorine element in the total solid content of the photosensitive composition.

The content of the fluorine element in the total solid content of the photosensitive composition may be 0 ppm by mass. The content of fluoride ions in the total solid content of the photosensitive composition may also be 0 ppm by mass. When the content of the fluorine element and/or the content of the fluoride ion in the total solid content of the photosensitive composition is more than 0 ppm by mass, the photosensitive composition of the present invention preferably has a fluorine atom or a fluoride ion in the structure of the (A) binder resin, the (C) photosensitive agent, the (B) compound, or the (F) crosslinking agent, or the photosensitive composition further contains a component containing a fluorine element and/or a component including a fluoride ion.

When the storage stability of the photosensitive composition is poor, for example, foreign matter generation after storage at room temperature may be a problem. When foreign matter is generated during storage of the photosensitive composition, foreign matter remains in the insulating resin layer or the pattern opening during formation of the insulating resin layer or the like in the element of the present invention. Such foreign matter causes, for example, a decrease in reliability of the light-emitting element in the display device of the present invention and a decrease in migration resistance in the electronic component of the present invention. When the content of the fluorine element in the total solid content of the photosensitive composition of the present invention is in a specific range, generation of foreign matters during storage is suppressed, and the effect of improving storage stability becomes remarkable.

### <Contents of Chlorine Element, Bromine Element, and Sulfur Element>

It is preferable that the photosensitive composition of the present invention satisfies at least one of the following conditions (1b), (1c), and (1d) described later from the viewpoint of suppressing residues after development, achieving low voltage drive of light emission characteristics, improving the reliability of the light-emitting element, and improving the migration resistance. From the viewpoint of the effects of the invention described above, the photosensitive composition of the present invention more preferably satisfies at least one of the following conditions (2b), (2c), and (2d) described later.

In the photosensitive composition according to the present invention, from the viewpoint of suppressing a residue after development, achieving low voltage drive of light emission characteristics, improving reliability of a light-emitting element, and improving migration resistance, it is preferable that the (A) binder resin, the (C) photosensitive agent, the (B) radical polymerizable compound, or the (F) crosslinking agent has a chlorine atom, a bromine atom, a sulfur atom, a chloride ion, a bromide ion, or the following sulfur-based anion in a structure thereof, or the photosensitive composition further includes a component including a chlorine element, a bromine element, or a sulfur element and/or a component containing a chloride ion, a bromide ion, or the following sulfur-based anion,

Further, it is preferable that at least one of the following conditions (1b), (1c), and (1d) is satisfied.

Sulfur-based anion: One or more ions selected from the group consisting of a sulfide ion, a hydrogen sulfide ion, a sulfate ion, and a hydrogen sulfate ion
(1b) The content of the chlorine element in the total solid content of the photosensitive composition is 0.010 ppm by mass or more and 1, 000 ppm by mass or less.
(1c) The content of the bromine element in the total solid content of the photosensitive composition is 0.010 ppm by mass or more and 1,000 ppm by mass or less.
(1d) The content of the sulfur element in the total solid content of the photosensitive composition is 0.010 ppm by mass or more and 1, 000 ppm by mass or less.

The photosensitive composition of the present invention more preferably further satisfies at least one of the following conditions (2b), (2c), and (2d) from the viewpoint of the effects of the invention described above.
(2b) The content of chloride ions in the total solid content of the photosensitive composition is 0.010 ppm by mass or more and 1,000 ppm by mass or less.
(2c) The content of bromide ions in the total solid content of the photosensitive composition is 0.010 ppm by mass or more and 1,000 ppm by mass or less.
(2d) The content of the above sulfur-based anion in the total solid content of the photosensitive composition is 0.010 ppm by mass or more and 1, 000 ppm by mass or less.

As the component including the chlorine element or the bromine element, a phenol compound having a substituent including an alkyl chloride group, an alkyl chloride compound, a cycloalkyl chloride compound, an aryl chloride compound, a phenol compound having a substituent including an alkyl bromide group, an alkyl bromide compound, a cycloalkyl bromide compound, or an aryl bromide compound is preferable. As the component including a sulfur element, a thiol compound, a sulfide compound, a disulfide compound, a sulfoxide compound, a sulfone compound, a sultone compound, or a thiophene compound is preferable. Illustrative and preferred descriptions of cationic species in the components including chloride ions, bromide ions, and sulfur-based anions are as described above in the components including fluoride ions.

The content of the chlorine element in the total solid content of the photosensitive composition is preferably 0.010 ppm by mass or more, more preferably 0.030 ppm by mass or more, still more preferably 0.050 ppm by mass or more, still more preferably 0.070 ppm by mass or more, and particularly preferably 0.10 ppm by mass or more from the viewpoint of the effects of the invention described above. On the other hand, the content of the chlorine element is preferably 1, 000 ppm by mass or less, more preferably 500 ppm by mass or less, still more preferably 300 ppm by mass or less, and particularly preferably 100 ppm by mass or less from the viewpoint of the effects of the invention described above. Furthermore, the content of the chlorine element is preferably 50 ppm by mass or less, more preferably 30 ppm by mass or less, still more preferably 10 ppm by mass or less, still more preferably 5 ppm by mass or less, particularly preferably 3 ppm by mass or less, and most preferably 1 ppm by mass or less.

Preferred ranges of the content of the bromine element, the content of the sulfur element, the content of the chloride ion, the content of the bromide ion, and the content of the sulfur-based anion in the total solid content of the photosensitive composition are also the same as the above preferred ranges of the content of the chlorine element in the total solid content of the photosensitive composition.

One or more selected from the group consisting of the content of the chlorine element, the content of the bromine element, and the content of the sulfur element in the total solid content of the photosensitive composition may be 0 ppm by mass. One or more selected from the group consisting of the content of chloride ions, the content of bromide ions, and the content of sulfur-based anions in the total solid content of the photosensitive composition may be 0 ppm by mass. When one or more content selected from the group consisting of a content of a chlorine element, a content of a bromine element, a content of a sulfur element, a content of a chloride ion, a content of a bromide ion, and a content of a sulfur-based anion in the total solid content of the photosensitive composition (hereinafter, the “content and the like of chlorine element and chloride ions in the total solid content of the photosensitive composition”) exceeds 0 ppm by mass, the photosensitive composition of the present invention preferably has a chlorine atom, a bromine atom, a sulfur atom, a chloride ion, a bromide ion, or the following sulfur-based anion in the structure of the (A) binder resin, the (C) photosensitive agent, the (B) compound, or the (F) crosslinking agent. When the content and the like of chlorine element and chloride ions in the total solid content of the photosensitive composition exceeds 0 ppm by mass, the photosensitive composition of the present invention preferably further contains a component containing chlorine element, bromine element, or sulfur element and/or a component containing chloride ion, bromide ion, or the following sulfur-based anion.

### <Content of Water>

The photosensitive composition of the present invention further includes water, and satisfies the following condition (3).
(3) The content of water in the photosensitive composition is 0.010 mass % or more and 3.0 mass& or less.

The content of water in the photosensitive composition is preferably 0.010 mass % or more, more preferably 0.030 mass % or more, still more preferably 0.050 mass or more, still more preferably 0.070 mass % or more, and particularly preferably 0.10 mass % or more, from the viewpoint of suppression of residues after development, achieving low voltage drive of light emission characteristics, improving reliability of a light-emitting element, and improving migration resistance. On the other hand, the content of water is preferably 3.0 mass % or less, more preferably 2.5 mass % or less, still more preferably 2.2 mass % or less, and particularly preferably 2.0 mass % or less from the viewpoint of the effects of the invention described above. Furthermore, the content of water is preferably 1.7 mass % or less, more preferably 1.5 mass % or less, still more preferably 1.2 mass % or less, still more preferably 1.0 mass % or less, particularly preferably 0.70 mass % or less, and most preferably 0.50 mass % or less.

As described above, when the storage stability of the photosensitive composition is poor, it causes a decrease in reliability and a decrease in migration resistance of the light-emitting element. When the content of water in the photosensitive composition of the present invention is within a specific range, generation of foreign matters during storage is suppressed, and the effect of improving storage stability becomes remarkable.

### <Other Additives and Solvents>

The photosensitive composition of the present invention preferably further includes a dissolution promoter, a sensitizer, a chain transfer agent, a polymerization inhibitor, a silane coupling agent, an ink repellent agent, or a surfactant. As these additives, known additives may be used. The photosensitive composition of the present invention preferably further includes a solvent. When the photosensitive composition of the present invention includes a pigment and further includes a dispersant, the solvent is preferably a compound having an acetate bond, a propionate bond, or a butyrate bond from the viewpoint of improving the dispersion stability of the pigment.

### <Cured Product of Photosensitive Composition>

The cured product of the present invention is obtained by curing the photosensitive composition of the present invention. The curing refers to a state in which a crosslinked structure is formed by a reaction and the fluidity of the film is lost, or refers to that state. The curing reaction may be caused by heating, irradiation with an energy ray, or the like, without being particularly limited, and is preferably caused by heating. A state in which a crosslinked structure is formed in a component constituting the photosensitive composition by heating and the fluidity of the film is lost is referred to as thermal curing. As the heating condition, for example, a condition of heating at 150 to 500° C for 5 to 300 minutes is preferable.

The cured product of the present invention is preferably black. The optical density of the cured product of the present invention at a wavelength of visible light per film thickness of 1 μm is preferably 0.5 or more, more preferably 0.7 or more, still more preferably 1.0 or more, still more preferably 1.2 or more, and particularly preferably 1.5 or more from the viewpoint of suppressing external light reflection and improving the reliability of the light-emitting element. On the other hand, the optical density is preferably 3.0 or less, more preferably 2.5 or less, and still more preferably 2.0 or less from the viewpoint of achieving low voltage drive of light emission characteristics. The optical density referred to herein is preferably an optical density in a cured product obtained by heating and curing the composition.

The element of the present invention preferably includes the cured product of the present invention. An article of the present invention preferably includes the cured product of the present invention. Examples of the article include a display device, an electronic component, an electronic device, a moving body, a building, a window, and the like. The display device of the present invention preferably includes the cured product of the present invention.

### <Method for Producing Cured Product>

A method for producing a cured product of the present invention includes the steps of: (1) forming a coating film of the photosensitive composition of the present invention on a substrate; (2) irradiating the coating film of the photosensitive composition with active actinic radiation via a photomask to expose the coating film; (3) developing the exposed coating film using a developer to form a pattern of the photosensitive composition; and (4) heating the pattern of the photosensitive composition to obtain a cured pattern of the photosensitive composition. In these steps, the methods described in paragraphs to of International Publication No. 2019/087985 may be applied. In the step of forming a coating film, it is preferable to form a film by prebaking after coating. The step of obtaining a cured pattern is preferably a step of heating for thermally curing the pattern.

### EXAMPLES

Hereinafter, the present invention will be described more specifically with reference to Examples, Reference Examples, and Comparative Examples, but the present invention is not limited to these ranges. Note that names corresponding to abbreviations of compounds used in the following description or tables are collectively shown in Table 1-2.

TABLE 1-2

| Abbreviation | Corresponding name |
|---|---|
| 6FAP | 2,2-bis(3-amino-4-hydroxyphenyl)hexafluoropropane |
| 6FDA | 4,4′-hexafluoropropane-2,2-diyl-bis(1,2-phthalic anhydride) |
| ABP S | Bis(3-amino-4-hydroxyphenyl)sulfone |
| ADP E | Bis(3-amino-4-hydroxyphenyl)ether |
| APB-N | 1,3-bis(3-aminophenoxy)benzene |
| APB-F | 1,3-bis(4-amino-3-hydroxyphenoxy)benzene |
| APC | Argentum-Palladium-Cuprum(silver-palladium-copper alloy) |
| BAFL | 9,9-bis(3-amino-4-hydroxyphenyl)fluorene |
| BAP | 2,2-bis(3-amino-4-hydroxyphenyl)propane |
| BGPF | 9,9-bis(4-glycidoxyphenyl)fluorene |
| BnMA | Benzyl methacrylate |
| BSAA | 2,2-bis(4-(3,4-dicarboxyphenoxy)phenyl)propane dianhydride |
| DAE | Bis(4-aminophenyl)ether |
| DDS | Bis (3-aminophenyl)sulfone |
| DFA | N,N-dimethylformamide dimethyl acetal |
| EDM | Diethylene glycol ethyl methyl ether |
| EL | Ethyl lactate |
| FDA | 9,9-bis(4-aminophenyl)fluorene |
| GBL | γ-butyrolactone |
| GMA | Glycidyl methacrylate |
| HAB | (4,4′-diamino-3,3′-dihydroxy)biphenyl |
| HAD | Formaldehyde |
| HST | 4-hydroxystyrene |
| ITO | Indium tin oxide |
| KBM-503 | 3-methacryloyloxypropyltrimethoxysilane |
| | (manufactured by Shin-Etsu Chemical Co., Ltd.) |
| MA | Maleic anhydride |
| MAA | Methacrylic acid |
| MBA | 3-methoxy-n-butyl acetate |
| MCS | m-cresol |
| MEK-ST-40 | Silica particle dispersion liquid using methyl ethyl ketone as dispersion solvent |
| | (manufactured by Nissan Chemical Corporation) |
| MOP | 4-methoxyphenol |
| a-TB | (4,4′-diamino-2,2′-dimethyl)biphenyl |
| NA | 5-norbornene-2,3-dicarboxylic acid anhydride |
| NC-3000-H | Epoxy resin having a structural unit including a biphenyl skeleton, |
| | a benzene skeleton, and one epoxy group (manufactured by Nippon Kayaku Co., Ltd.} |
| ODB-HST | Mixture of dicarboxylic acid derivatives obtained by reacting bis(4-carboxyphenyl) |
| | ether with 1-hydroxy-1,2,3-benzotriazole |
| ODPA | Oxydiphtbalic dianhydride |
| PGMEA | Propylene glycol monomethyl ether acetate |
| PHA | Phthalic anhydride |
| SiDA | 1,3-bis(3-aminopropyl)tetramethyldisiloxane |
| STR | Styrene |
| TCDM | Methacrylic acid tricyclo[5.2.1.02,6]decan-6-yl; |
| | methylol-tricyclodecane methacrylate |
| THPHA | 1,2,3,6-tetrahydrophthalic anhydride |
| TMAC | Trimellitic anhydride chloride |
| TMAH | Tetramethylammonium hydroxide |

### Synthesis Example of Each Resin

As the (A) binder resin, the composition of each resin obtained in Synthesis Examples 1 to 62 is collectively shown in Table 1-3 to Table 1-8. Each resin was synthesized by a known method by appropriately changing a monomer compound to be a monomer and a copolymerization ratio based on a method described in a known document. The copolymerization ratio of the monomers is as shown in Table 1-3 to Table 1-8.

The hydroxy group-containing diamines (HA-1) and (HA-2) having the following structures used in Synthesis Examples 9 and 23 were synthesized by a known method based on the synthesis method described in Synthesis Example 1 in paragraphs [0374] to [0376] of WO 2016/056451 A. The resins obtained in Synthesis Examples 9 and 23 using (HA-1) and (HA-2) which are hydroxy group-containing diamines having the following structures are polyimide precursors having an imide cyclization ratio of less than 50% and also polybenzoxazole precursors having a benzoxazole cyclization ratio of less than 50%.

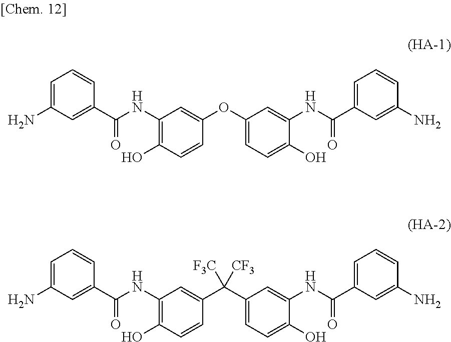 [SMILES: Nc1cccc(C(=O)Nc2cc(Oc3ccc(O)c(NC(=O)c4cccc(N)c4)c3)ccc2O)c1 ; Nc1cccc(C(=O)Nc2cc(C(c3ccc(O)c(NC(=O)c4cccc(N)c4)c3)(C(F)(F)F)C(F)(F)F)ccc2O)c1]

The structures of the diamines (DA70), (DA71), (DA75) to (DA80), (DA82), (DA84), (DA86), (DA90), (DA92), (DA94), and (DA100) to (DA104) used in the respective Synthesis Examples are shown below. These compounds were synthesized by a known method. The structures of tetracarboxylic dianhydrides (AH1) and (AH2) used in each Synthesis Example are shown below,

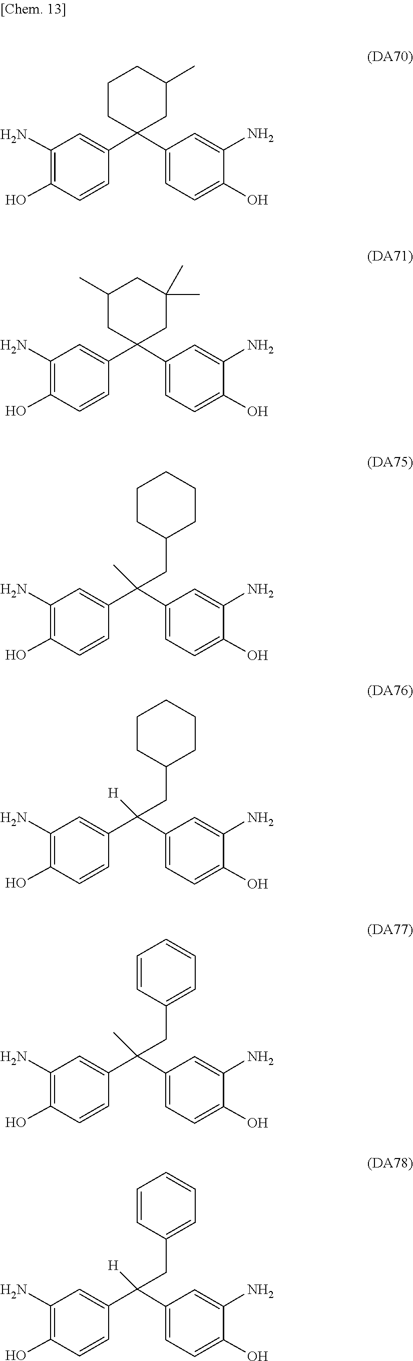 [SMILES: CC1CCCC(c2ccc(O)c(N)c2)(c2ccc(O)c(N)c2)C1 ; CC1CC(C)(C)CC(c2ccc(O)c(N)c2)(c2ccc(O)c(N)c2)C1 ; CC(CC1CCCCC1)(c1ccc(O)c(N)c1)c1ccc(O)c(N)c1 ; Nc1cc(C(CC2CCCCC2)c2ccc(O)c(N)c2)ccc1O ; CC(Cc1ccccc1)(c1ccc(O)c(N)c1)c1ccc(O)c(N)c1 ; Nc1cc(C(Cc2ccccc2)c2ccc(O)c(N)c2)ccc1O]

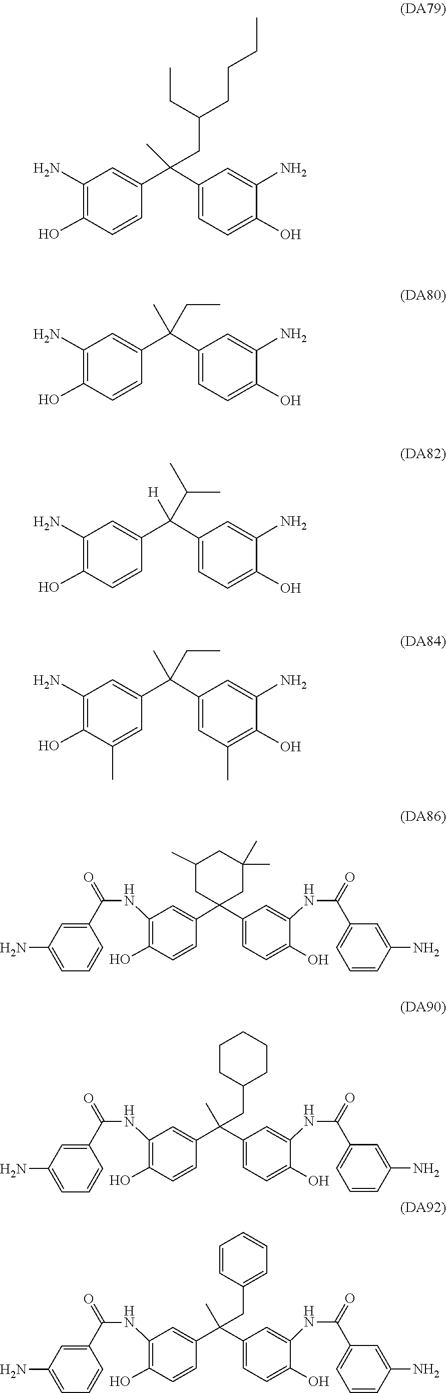

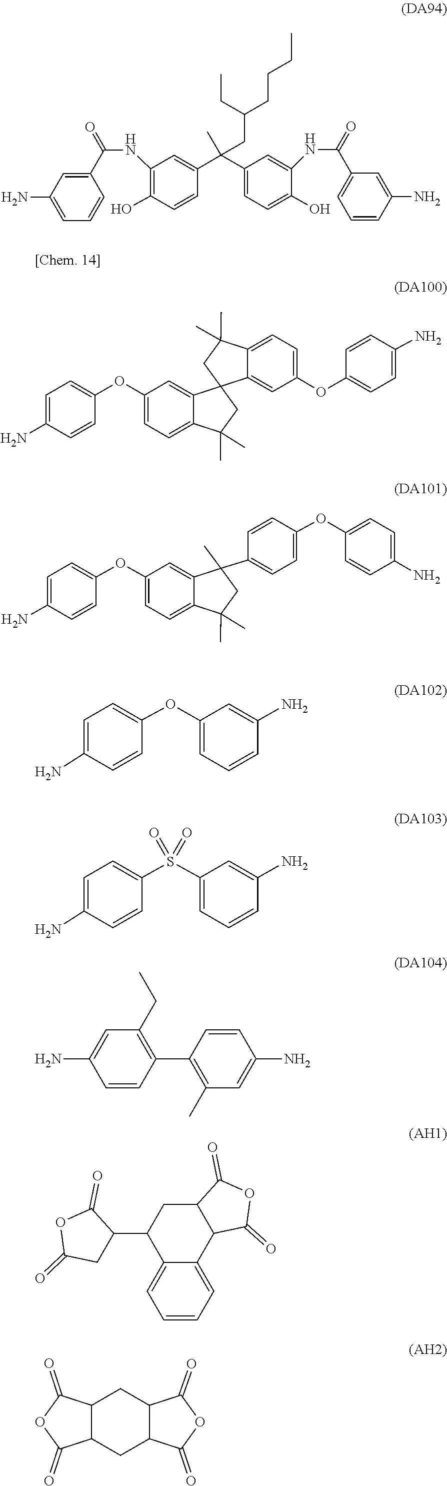

In the (XA) resin in the insulating resin layer, the amine residue derived from any one of the diamines (DA70), (DA71), (DA75) to (DA80), (DA82), (DA84), (DA86), (DA90), (DA92), and (DA94) corresponds to an amine residue having a phenolic hydroxyl group, and satisfies the above conditions (XS1x), (XS1y), and (XS1z). The amine residue derived from any one of (DA70), (DA71), (DA79), (DA86), and (DA94) has an asymmetric carbon atom that is an asymmetric center. The amine residue derived from any one of the diamines (DA70), (DA71), (DA86), and (DA90) also satisfies the above condition (XY1). The amine residue derived from any one of the diamines (DA75) to (DA80), (DA82), (DA84), (DA92), and (DA94) also satisfies the above condition (XY3). The resin obtained in Synthesis Examples 42 to 45 using the diamines (DA86), (DA90), (DA92), and (DA94) is a polyimide precursor having an imide cyclization ratio of less than 50%, and is also a polybenzoxazole precursor having a benzoxazole cyclization ratio of less than 50%. The resin obtained in Synthesis Example 31 using the diamine (DA94) is a polyimide having an imide cyclization ratio of 50% or more, and is also a polybenzoxazole precursor having a benzoxazole cyclization ratio of less than 50%.

In the (XA) resin in the insulating resin layer, the amine residue derived from any one of the diamines (DA100) to (DA104) corresponds to an amine residue having no phenolic hydroxyl group. In addition, since the amine residue derived from the diamine (DA100) has a spiro structure which is an asymmetric axis, the above conditions (XS2x), (XS2y), and (XS2z) are satisfied. The amine residue derived from the diamine (DA101) satisfies the above conditions (XS1x), (XS1y), and (XS1z). Since the amine residue derived from the diamine (DA101) has an asymmetric carbon atom which is an asymmetric center, the above conditions (XS2x) and (XS2y) are also satisfied. The amine residue derived from any one of the diamines (DA102) to (DA104) satisfies the above conditions (XS1x), (XS1y), and (XS1z).

In Synthesis Examples 3 to 17, 23, and 32 to 56, the amic acid structure in the resin was reacted with DFA as an esterifying agent to convert the structure to an amic acid ester structure having a methyl group.

In Synthesis Example 27, GMA having an epoxy group was reacted with a carboxy group derived from MAA in the resin, and ring-opening addition was performed on all the epoxy groups of GMA.

TABLE 1-3

| | | Monomer [mol ratio] | | | | | | | Weight | Acid equivalent | Double |
|---|---|---|---|---|---|---|---|---|---|---|---|
| | | Carboxylic | | | | | End- | | average | Phenol equivalent | bond |
| | | acid | | | | | sealing | Esterifying | molecular | Carboxylic acid equivalent | equivalent |
| | Polymer | derivative | | Amine derivative | | | agent | agent | weight | [g/mol] | [g/mol] |
| Synthesis | Polyimide | BSAA | — | BAP | DAE | SiDA | MA | — | 26,000 | Acid equivalent: 660 | — |
| Example 1 | (PI-1) | (80) | | (50) | (45) | (5) | (40) | | | Phenol equivalent: 660 | |
| Synthesis | Polyimide | BSAA | — | ABPS | DAE | SiDA | MA | — | 28,000 | Acid equivalent: 670 | — |
| Example 2 | (PI-2) | (80) | | (50) | (45) | (5) | (40) | | | Phenol equivalent: 670 | |
| Synthesis | Polyimide | BSAA | — | BAP | DAE | SiDA | MA | DEA | 18,000 | Acid equivalent: 370 | — |
| Example 3 | precursor | (80) | | (50) | (45) | (5) | (40) | (200) | | Phenol equivalent: 700 | |
| | (PIP-1) | | | | | | | | | Carboxylic acid | |
| | | | | | | | | | | equivalent: 790 | |
| Synthesis | Polyimide | BSAA | — | ABPS | DAE | SiDA | MA | DEA | 20,000 | Acid equivalent: 410 | — |
| Example 4 | precursor | (80) | | (50) | (45) | (5) | (40) | (200) | | Phenol equivalent: 700 | |
| | (PIP-2) | | | | | | | | | Carboxylic acid | |
| | | | | | | | | | | equivalent: 980 | |
| Synthesis | Polyimide | BSAA | — | BAFL | DAE | SiDA | MA | DEA | 18,000 | Acid equivalent: 400 | — |
| Example 5 | precursor | (80) | | (50) | (45) | (5) | (40) | (200) | | Phenol equivalent: 760 | |
| | (PIP-3) | | | | | | | | | Carboxylic acid | |
| | | | | | | | | | | equivalent: 860 | |
| Synthesis | Polyimide | BSAA | — | APB-P | DAE | SiDA | MA | DEA | 18,000 | Acid equivalent: 390 | — |
| Example 6 | precursor | (80) | | (50) | (45) | (5) | (40) | (200) | | Phenol equivalent: 730 | |
| | (PIP-4) | | | | | | | | | Carboxylic acid | |
| | | | | | | | | | | equivalent: 830 | |
| Synthesis | Polyimide | BSAA | — | HAB | DAE | SiDA | MA | DEA | 18,000 | Acid equivalent: 360 | — |
| Example 7 | precursor | (80) | | (50) | (45) | (5) | (40) | (200) | | Phenol equivalent: 670 | |
| | (PIP-5) | | | | | | | | | Carboxylic acid | |
| | | | | | | | | | | equivalent: 770 | |
| Synthesis | Polyimide | BSAA | — | ADPE | DAE | SiDA | MA | DEA | 18,000 | Acid equivalent: 360 | — |
| Example 8 | precursor | (80) | | (50) | (45) | (5) | (40) | (200) | | Phenol equivalent: 680 | |
| | (PIP-6) | | | | | | | | | Carboxylic acid | |
| | | | | | | | | | | equivalent: 770 | |
| Synthesis | Polyimide | BSAA | — | HA-1 | DAE | SiDA | MA | DEA | 20,000 | Acid equivalent: 470 | — |
| Example 9 | precursor | (30) | | (50) | (45) | (5) | (40) | (200) | | Phenol equivalent: 800 | |
| | (PIP-7) | | | | | | | | | Carboxylic acid | |
| | | | | | | | | | | equivalent: 1,110 | |
| Synthesis | Polyimide | BSAA | — | BAP | DDS | SiDA | MA | DEA | 20,000 | Acid equivalent: 420 | — |
| Example 10 | precursor | (80) | | (50) | (45) | (5) | (40) | (200) | | Phenol equivalent: 710 | |
| | (PIP-8) | | | | | | | | | Carboxylic acid | |
| | | | | | | | | | | equivalent: 990 | |
| Synthesis | Polyimide | BSAA | — | BAP | FDA | SiDA | MA | DEA | 18,000 | Acid equivalent: 410 | — |
| Example 11 | precursor | (80) | | (50) | (45) | (5) | (40) | (200) | | Phenol equivalent: 760 | |
| | (PIP-9) | | | | | | | | | Carboxylic acid | |
| | | | | | | | | | | equivalent: 870 | |
| Synthesis | Polyimide | BSAA | — | BAP | APB-N | SiDA | MA | DEA | 18,000 | Acid equivalent: 390 | — |
| Example 12 | precursor | (80) | | (50) | (45) | (5) | (40) | (200) | | Phenol equivalent: 740 | |
| | (PIP-10) | | | | | | | | | Carboxylic acid | |
| | | | | | | | | | | equivalent: 840 | |

TABLE 1-4

| | | | | | | | | | | Acid equivalent | Double |
|---|---|---|---|---|---|---|---|---|---|---|---|
| | | Monomer [mol ratio] | | | | | | | Weight | Phenol equivalent | bond |
| | | Carboxylic | | | | | End- | Ester- | average | Carboxylic | equiv- |
| | | acid | | | | | sealing | ifying | molecular | acid equivalent | alent |
| | Polymer | derivative | | Amine derivative | | | agent | agent | weight | [g/mol] | [g/mol] |
| Synthesis | Polyimide | BSAA | — | BAP | m-TB | SiDA | MA | DFA | 18,000 | Acid equivalent: 370 | — |
| Example | precursor | (80) | | (50) | (45) | (5) | (40) | (200) | | Phenol equivalent: 700 | |
| 13 | (PIP-11) | | | | | | | | | Carboxylic acid | |
| | | | | | | | | | | equivalent: 800 | |
| Synthesis | Polyimide | BSAA | — | BAP | DAE | SiDA | MA | DFA | 18,000 | Acid equivalent: 460 | — |
| Example | precursor | (80) | | (30) | (65) | (5) | (40) | (200) | | Phenol equivalent: | |
| 14 | (PIP-12) | | | | | | | | | 1,140 | |
| | | | | | | | | | | Carboxylic acid | |
| | | | | | | | | | | equivalent: 780 | |
| Synthesis | Polyimide | BSAA | — | BAD | DAE | SiDA | MA | DFA | 18,000 | Acid equivalent: 310 | — |
| Example | precursor | (80) | | (70) | (25) | (5) | (40) | (200) | | Phenol equivalent: 510 | |
| 15 | (PIP-13) | | | | | | | | | Carboxylic acid | — |
| | | | | | | | | | | equivalent: 800 | |
| Synthesis | Polyimide | BSAA | — | BAP | DAE | SiDA | MA | DFA | 18,000 | Acid equivalent: 430 | |
| Example | precursor | (80) | | (50) | (45) | (5) | (40) | (300) | | Phenol equivalent: 700 | |
| 16 | (PIP-14) | | | | | | | | | Carboxylic acid | |
| | | | | | | | | | | equivalent: 1,090 | |
| Synthesis | Polyimide | BSAA | ODB- | BAP | DAE | SiDA | MA | DFA | 20,000 | Acid equivalent: 260 | — |
| Example | precursor | (20) | HBT | (75) | (20) | (5) | (40) | (50) | | Phenol equivalent: 350 | |
| 17 | (PIP-15) | | (60) | | | | | | | Carboxylic acid | |
| | | | | | | | | | | equivalent: 1,010 | |
| Synthesis | Poly- | ODB- | — | BAP | — | SiDA | MA | — | 26,000 | Acid equivalent: 400 | — |
| Example | benzoxazole | HBT | | (95) | | (5) | (40) | | | Phenol equivalent: 600 | |
| 18 | (PB-1) | (80) | | | | | | | | Carboxylic acid | |
| | | | | | | | | | | equivalent: 1,140 | |
| Synthesis | Poly- | ODB- | — | BAP | — | — | MA | — | 20,000 | Acid equivalent: 200 | — |
| Example | benzoxazole | HBT | | (100) | | | (40) | | | Phenol equivalent: 240 | |
| 19 | precursor | (80) | | | | | | | | Carboxylic acid | |
| | (PBP-1) | | | | | | | | | equivalent: 1,190 | |
| Synthesis | Poly- | ODB- | — | ABPS | — | — | MA | — | 22,000 | Acid equivalent: 210 | — |
| Example | benzoxazole | HBT | | (100) | | | (40) | | | Phenol equivalent: | |
| 20 | precursor | (80) | | | | | | | | 250 | |
| | (PBP-2) | | | | | | | | | Carboxylic acid | |
| | | | | | | | | | | equivalent: 1,250 | |
| Synthesis | Poly- | TMAC | — | BAP | — | — | MA | — | 25,000 | Acid equivalent: 210 | — |
| Example | amideimide | (80) | | (100) | | | (40) | | | Phenol equivalent: | |
| 21 | (PAI-1) | | | | | | | | | 210 | |
| Synthesis | Polyimide | BSAA | — | 6FAP | — | SiDA | MA | — | 27,000 | Acid equivalent: 420 | — |
| Example | (PI-3) | (80) | | (95) | | (5) | (40) | | | Phenol equivalent: | |
| 22 | | | | | | | | | | 420 | |
| Synthesis | Polyimide | 6FDA | — | 6FAP | HA-2 | SiDA | MA | DFA | 20,000 | Acid equivalent: 500 | — |
| Example | precursor | (80) | | (45) | (50) | (5) | (40) | (200) | | Phenol equivalent: | |
| 23 | (PIP-16) | | | | | | | | | 980 | |
| | | | | | | | | | | Carboxylic acid | |
| | | | | | | | | | | equivalent: 1,000 | |
| Synthesis | Poly- | ODB- | — | 6FAP | — | — | NA | — | 22,000 | Acid equivalent: 260 | — |
| Example | benzoxazole | HBT | | (100) | | | (40) | | | Phenol equivalent: | |
| 24 | precursor | (80) | | | | | | | | 310 | |
| | (PBP-3) | | | | | | | | | Carboxylic acid | |
| | | | | | | | | | | equivalent: 1,530 | |

TABLE 1-5

| | | Monomer [mol ratio] | | | | | | |
|---|---|---|---|---|---|---|---|---|
| | | | | | Radical | | Acid equivalent | |
| | | Poly- | Poly- | | polymerizable | Weight | (=carboxylic | Double |
| | | functional | functional | Carboxylic | group-containing | average | acid | bond |
| | | epoxy | carboxylic acid | acid | carboxylic | molecular | equivalent) | equivalent |
| | Polymer | compound | dianhydride | anhydride | acid compound | weight | [g/mol] | [g/mol] |
| Synthesis | Polycyclic side | BGPF | ODPA | PHA | MAA | 4,700 | 470 | 470 |
| Example | chain- | (100) | (90) | (20) | (200) | | | |
| 25 | containing resin | | | | | | | |
| | (CR-1) | | | | | | | |
| | | Monomer [mol ratio] | | | | | | |
| | | | | | Radical | | Acid equivalent | |
| | | | | | polymerizable | Weight | (=carboxylic | Double |
| | | | | Carboxylic | group-containing | average | acid | bond |
| | | Polyfunctional | | acid | carboxylic | molecular | equivalent) | equivalent |
| | Polymer | epoxy compound | | anhydride | acid compound | weight | [g/mol] | [g/mol] |
| Synthesis | Acid-modified | NC-3000-H | | THPHA | MAA | 4,500 | 570 | 510 |
| Example | epoxy resin | (Epoxy equivalent: | | (0.18 mol) | (0.20 mol) | | | |
| 26 | (AE-1) | 290 g/mol) | | (mol ratio: | (mol ratio: 100) | | | |
| | | (Epoxy group standard: | | 90) | | | | |
| | | 0.2 mol) | | | | | | |
| | | (Epoxy group standard | | | | | | |
| | | mol ratio: 100) | | | | | | |
| | | Monomer [mol ratio] | | | | | Acid equivalent | |
| | | Acidic | Aromatic | Alicyclic | Radical | Weight | (=carboxylic | Double |
| | | copoly- | copoly- | copoly- | polymerizable | average | acid | bond |
| | | merization | merization | merization | group-containing | molecular | equivalent) | equivalent |
| | Polymer | component | component | component | epoxy compound | weight | [g/mol] | [g/mol] |
| Synthesis | Acrylic resin | MAA | BnMA | TCDM | GMA | 15,000 | 540 | 810 |
| Example | (AC-1) | (50) | (45) | (5) | (20) | | | |
| 27 | | | | | | | | |

| | | Monomer [mol ratio] | | Weight | Acid equivalent | Double |
|---|---|---|---|---|---|---|
| | | | Aldehyde compound | average | (=phenol | bond |
| | | | Bis(alkoxymethyl) | molecular | equivalent) | equivalent |
| | Polymer | Phenol compound | compound | weight | [g/mol] | [g/mol] |
| Synthesis | Phenolic resin | MCS | HAD | 3,000 | 120 | — |
| Example | (PR-1) | (100) | (100) | | | |
| 28 | | | | | | |
| | | | | Weight | Acid equivalent | Double |
| | | Monomer [mol ratio] | | average | (=phenol | bond |
| | | Hydroxystyrene copoly- | Styrene copolymerization | molecular | equivalent) | equivalent |
| | Polymer | merization component | component | weight | [g/mol] | [g/mol] |
| Synthesis | Poly- | HST | STR | 9,500 | 150 | — |
| Example | hydroxystyrene | (80) | (20) | | | |
| 29 | (PHS-1) | | | | | |

TABLE 1-6

| | | Monomer [mol ratio] | | | | |
|---|---|---|---|---|---|---|
| | | Carboxylic | | | | |
| | | acid | | | | |
| | Polymer | derivative | | Amine derivative | | |
| Synthesis | Polyimide | BSAA | — | DA79 | DA104 | SiDA |
| Example 30 | (PI-4) | (80) | | (70) | (25) | (5) |
| Synthesis | Polyimide | BSAA | — | DA94 | DA104 | SiDA |
| Example 31 | (PI-5) | (80) | | (70) | (25) | (5) |
| Synthesis | Polyimide precursor | BSAA | — | DA79 | DA104 | SiDA |
| Example 32 | (PIP-17) | (80) | | (70) | (25) | (5) |
| Synthesis | Polyimide precursor | BSAA | — | DA70 | DA104 | SiDA |
| Example 33 | (PIP-18) | (30) | | (70) | (25) | (5) |
| Synthesis | Polyimide precursor | BSAA | — | DA71 | DA104 | SiDA |
| Example 34 | (PIP-19) | (80) | | (70) | (25) | (5) |
| Synthesis | Polyimide precursor | BSAA | — | DA75 | DA104 | SiDA |
| Example 35 | (PIP-20) | (80) | | (70) | (25) | (5) |
| Synthesis | Polyimide precursor | BSAA | — | DA76 | DA104 | SiDA |
| Example 36 | (PIP-21) | (80) | | (70) | (25) | (5) |
| Synthesis | Polyimide precursor | BSAA | — | DA77 | DA104 | SiDA |
| Example 37 | (PIP-22) | (80) | | (70) | (25) | (5) |
| Synthesis | Polyimide precursor | BSAA | — | DA78 | DA104 | SiDA |
| Example 38 | (PIP-23) | (30) | | (70) | (25) | (5) |
| Synthesis | Polyimide precursor | BSAA | — | DA80 | DA104 | SiDA |
| Example 39 | (PIP-24) | (80) | | (70) | (25) | (5) |
| Synthesis | Polyimide precursor | BSAA | — | DA82 | DA104 | SiDA |
| Example 40 | (PIP-25) | (80) | | (70) | (25) | (5) |
| | | Monomer | | | | |
| | | [mol ratio] | | Weight | Acid equivalent | Double |
| | | End- | | average | Phenol equivalent | bond |
| | | sealing | Esterifying | molecular | Carboxylic acid equivalent | equivalent |
| | | agent | agent | weight | [g/mol] | [g/mol] |
| | Synthesis | MA | — | 26,000 | Acid equivalent: 540 | — |
| | Example 30 | (40) | | | Phenol equivalent: 540 | |
| | Synthesis | MA | — | 26,000 | Acid equivalent: 660 | — |
| | Example 31 | (40) | | | Phenol equivalent: 660 | |
| | Synthesis | MA | DFA | 18,000 | Acid equivalent: 350 | — |
| | Example 32 | (40) | (200) | | Phenol equivalent: 560 | |
| | | | | | Carboxylic acid equivalent: 890 | |
| | Synthesis | MA | DFA | 18,000 | Acid equivalent: 330 | — |
| | Example 33 | (40) | (200) | | Phenol equivalent: 540 | |
| | | | | | Carboxylic acid equivalent: 850 | |
| | Synthesis | MA | DFA | 18,000 | Acid equivalent: 340 | — |
| | Example 34 | (40) | (200) | | Phenol equivalent: 550 | |
| | | | | | Carboxylic acid equivalent: 880 | |
| | Synthesis | MA | DFA | 18,000 | Acid equivalent: 340 | — |
| | Example 35 | (40) | (200) | | Phenol equivalent: 550 | |
| | | | | | Carboxylic acid equivalent: 880 | |
| | Synthesis | MA | DFA | 18,000 | Acid equivalent: 340 | — |
| | Example 36 | (40) | (200) | | Phenol equivalent: 540 | |
| | | | | | Carboxylic acid equivalent: 860 | |
| | Synthesis | MA | DFA | 18,000 | Acid equivalent: 340 | — |
| | Example 37 | (40) | (200) | | Phenol equivalent: 550 | |
| | | | | | Carboxylic acid equivalent: 870 | |
| | Synthesis | MA | DFA | 18,000 | Acid equivalent: 330 | — |
| | Example 38 | (40) | (200) | | Phenol equivalent: 540 | |
| | | | | | Carboxylic acid equivalent: 860 | |
| | Synthesis | MA | DFA | 18,000 | Acid equivalent: 320 | — |
| | Example 39 | (40) | (200) | | Phenol equivalent: 520 | |
| | | | | | Carboxylic acid equivalent: 820 | |
| | Synthesis | MA | DFA | 18,000 | Acid equivalent: 320 | — |
| | Example 40 | (40) | (200) | | Phenol equivalent: 520 | |
| | | | | | Carboxylic acid equivalent: 820 | |

TABLE 1-7

| | | Monomer [mol ratio] | | | | |
|---|---|---|---|---|---|---|
| | | Carboxylic | | | | |
| | | acid | | | | |
| | Polymer | derivative | | Amine derivative | | |
| Synthesis | Polyimide | BSAA | — | DA84 | DA104 | SiDA |
| Example 41 | precursor | (80) | | (70) | (25) | (5) |
| | (PIP-26) | | | | | |
| Synthesis | Polyimide | BSAA | — | DA86 | DA104 | SiDA |
| Example 42 | precursor | (80) | | (70) | (25) | (5) |
| | (PIP-27) | | | | | |
| Synthesis | Polyimide | BSAA | — | DA90 | DA104 | SiDA |
| Example 43 | precursor | (80) | | (70) | (25) | (5) |
| | (PIP-28) | | | | | |
| Synthesis | Polyimide | BSAA | — | DA92 | DA104 | SiDA |
| Example 44 | precursor | (80) | | (70) | (25) | (5) |
| | (PIP-29) | | | | | |
| Synthesis | Polyimide | BSAA | — | DA94 | DA104 | SiDA |
| Example 45 | precursor | (80) | | (70) | (25) | (5) |
| | (PIP-30) | | | | | |
| Synthesis | Polyimide | BSAA | — | DA79 | DA100 | SiDA |
| Example 46 | precursor | (80) | | (70) | (25) | (5) |
| | (PIP-31) | | | | | |
| Synthesis | Polyimide | BSAA | — | DA79 | DA103 | SiDA |
| Example 47 | precursor | (80) | | (70) | (25) | (5) |
| | (PIP-32) | | | | | |
| Synthesis | Polyimide | BSAA | AH1 | DA79 | DA104 | SiDA |
| Example 48 | precursor | (40) | (40) | (70) | (25) | (5) |
| | (PIP-33) | | | | | |
| Synthesis | Polyimide | BSAA | AH2 | DA79 | DA104 | SiDA |
| Example 49 | precursor | (40) | (40) | (70) | (25) | (5) |
| | (PIP-34) | | | | | |
| Synthesis | Polyimide | BSAA | — | DA79 | DDS | SiDA |
| Example 50 | precursor | (80) | | (70) | (25) | (5) |
| | (PIP-35) | | | | | |
| Synthesis | Polyimide | BSAA | — | DA79 | FDA | SiDA |
| Example 51 | precursor | (80) | | (70) | (25) | (5) |
| | (PIP-36) | | | | | |
| Synthesis | Polyimide | BSAA | — | BAP | DA104 | SiDA |
| Example 52 | precursor | (80) | | (70) | (25) | (5) |
| | (PIP-37) | | | | | |
| | | Monomer | | | | |
| | | [mol ratio] | | Weight | Acid equivalent | Double |
| | | End- | | average | Phenol equivalent | bond |
| | | sealing | Esterifying | molecular | Carboxylic acid equivalent | equivalent |
| | | agent | agent | weight | [g/mol] | [g/mol] |
| | Synthesis | MA | DFA | 18,000 | Acid equivalent: 330 | — |
| | Example 41 | (40) | (200) | | Phenol equivalent: 530 | |
| | | | | | Carboxylic acid equivalent: 840 | |
| | Synthesis | MA | DFA | 20,000 | Acid equivalent: 410 | — |
| | Example 42 | (40) | (200) | | Phenol equivalent: 670 | |
| | | | | | Carboxylic acid equivalent: 1,060 | |
| | Synthesis | MA | DFA | 20,000 | Acid equivalent: 410 | — |
| | Example 43 | (40) | (200) | | Phenol equivalent: 670 | |
| | | | | | Carboxylic acid equivalent: 1,060 | |
| | Synthesis | MA | DFA | 20,000 | Acid equivalent: 410 | — |
| | Example 44 | (40) | (200) | | Phenol equivalent: 670 | |
| | | | | | Carboxylic acid equivalent: 1,060 | |
| | Synthesis | MA | DFA | 20,000 | Acid equivalent: 420 | — |
| | Example 45 | (40) | (200) | | Phenol equivalent: 680 | |
| | | | | | Carboxylic acid equivalent: 1,080 | |
| | Synthesis | MA | DFA | 18,000 | Acid equivalent: 370 | — |
| | Example 46 | (40) | (200) | | Phenol equivalent: 610 | |
| | | | | | Carboxylic acid equivalent: 960 | |
| | Synthesis | MA | DFA | 20,000 | Acid equivalent: 370 | — |
| | Example 47 | (40) | (200) | | Phenol equivalent: 560 | |
| | | | | | Carboxylic acid equivalent: 1,090 | |
| | Synthesis | MA | DFA | 16,000 | Acid equivalent: 310 | — |
| | Example 48 | (40) | (200) | | Phenol equivalent: 500 | |
| | | | | | Carboxylic acid equivalent: 790 | |
| | Synthesis | MA | DFA | 16,000 | Acid equivalent: 290 | — |
| | Example 49 | (40) | (200) | | Phenol equivalent: 480 | |
| | | | | | Carboxylic acid equivalent: 750 | |
| | Synthesis | MA | DFA | 20,000 | Acid equivalent: 370 | — |
| | Example 50 | (40) | (200) | | Phenol equivalent: 560 | |
| | | | | | Carboxylic acid equivalent: 1,090 | |
| | Synthesis | MA | DFA | 18,000 | Acid equivalent: 360 | — |
| | Example 51 | (40) | (200) | | Phenol equivalent: 580 | |
| | | | | | Carboxylic acid equivalent: 920 | |
| | Synthesis | MA | DFA | 18,000 | Acid equivalent: 320 | — |
| | Example 52 | (40) | (200) | | Phenol equivalent: 510 | |
| | | | | | Carboxylic acid equivalent: 810 | |

TABLE 1-8

| | | Monomer [mol ratio] | | | | |
|---|---|---|---|---|---|---|
| | | Carboxylic acid | | | | |
| | Polymer | derivative | | Amine derivative | | |
| Synthesis | Polyimide | BSAA | — | BAP | DA100 | SiDA |
| Example 53 | precursor | (80) | | (70) | (25) | (5) |
| | (PIP-38) | | | | | |
| Synthesis | Polyimide | BSAA | — | BAP | DA101 | SiDA |
| Example 54 | precursor | (80) | | (70) | (25) | (5) |
| | (PIP-39) | | | | | |
| Synthesis | Polyimide | BSAA | — | BAP | DA102 | SiDA |
| Example 55 | precursor | (80) | | (70) | (25) | (5) |
| | (PIP-40) | | | | | |
| Synthesis | Polyimide | BSAA | — | BAP | DA103 | SiDA |
| Example 56 | precursor | (80) | | (70) | (25) | (5) |
| | (PIP-41) | | | | | |
| Synthesis | Polybenzoxazole | ODB-HBT | — | DA79 | — | SiDA |
| Example 57 | (PB-2) | (80) | | (95) | | (5) |
| Synthesis | Polybenzoxazole | ODB-HBT | — | DA79 | — | — |
| Example 58 | precursor | (80) | | (100) | | |
| | (PBP-4) | | | | | |
| Synthesis | Polybenzoxazole | ODB-HBT | — | DA71 | — | — |
| Example 59 | precursor | (80) | | (100) | | |
| | (PBP-5) | | | | | |
| Synthesis | Polybenzoxazole | ODB-HBT | — | DA82 | — | — |
| Example 60 | precursor | (80) | | (100) | | |
| | (PBP-6) | | | | | |
| Synthesis | Polybenzoxazole | ODB-HBT | — | DA84 | — | — |
| Example 61 | precursor | (80) | | (100) | | |
| | (PBP-7) | | | | | |
| Synthesis | Polyamideimide | TMAC | — | DA79 | — | — |
| Example 62 | (PAI-2) | (80) | | (100) | | |
| | | | | Weight | Acid equivalent | |
| | | Monomer [mol ratio] | | average | Phenol equivalent | Double bond |
| | | End-sealing | Esterifying | molecular | Carboxylic acid equivalent | equivalent |
| | | agent | agent | weight | [g/mol] | [g/mol] |
| | Synthesis | MA | DFA | 18,000 | Acid equivalent: 340 | — |
| | Example 53 | (40) | (200) | | Phenol equivalent: 560 | |
| | | | | | Carboxylic acid equivalent: 890 | |
| | Synthesis | MA | DFA | 18,000 | Acid equivalent: 340 | — |
| | Example 54 | (40) | (200) | | Phenol equivalent: 550 | |
| | | | | | Carboxylic acid equivalent: 870 | |
| | Synthesis | MA | DFA | 18,000 | Acid equivalent: 310 | — |
| | Example 55 | (40) | (200) | | Phenol equivalent: 510 | |
| | | | | | Carboxylic acid equivalent: 800 | |
| | Synthesis | MA | DFA | 20,000 | Acid equivalent: 340 | — |
| | Example 56 | (40) | (200) | | Phenol equivalent : 510 | |
| | | | | | Carboxylic acid equivalent: 990 | |
| | Synthesis | MA | — | 26,000 | Acid equivalent: 480 | — |
| | Example 57 | (40) | | | Phenol equivalent: 720 | |
| | | | | | Carboxylic acid equivalent: 1,370 | |
| | Synthesis | MA | — | 20,000 | Acid equivalent: 240 | — |
| | Example 58 | (40) | | | Phenol equivalent: 290 | |
| | | | | | Carboxylic acid equivalent: 1,440 | |
| | Synthesis | MA | — | 20,000 | Acid equivalent: 240 | — |
| | Example 59 | (40) | | | Phenol equivalent: 280 | |
| | | | | | Carboxylic acid equivalent: 1, 400 | |
| | Synthesis | MA | — | 20,000 | Acid equivalent: 210 | — |
| | Example 60 | (40) | | | Phenol equivalent: 250 | |
| | | | | | Carboxylic acid equivalent: 1,230 | |
| | Synthesis | MA | — | 20,000 | Acid equivalent: 220 | — |
| | Example 61 | (40) | | | Phenol equivalent: 260 | |
| | | | | | Carboxylic acid equivalent: 1,300 | |
| | Synthesis | MA | — | 25,000 | Acid equivalent: 260 | — |
| | Example 62 | (40) | | | Phenol equivalent: 260 | |

The structural units and structures of the resins obtained in the respective Synthesis Examples and the resins used in the respective Examples, Reference Examples, and Comparative Examples are collectively shown in Table 2-1 to Table 2-4,

TABLE 2

| | | Imide cyclization | |
|---|---|---|---|
| | | ratio | |
| | Content of specific element | Benzoxazole cyclization | (A) Structural unit and |
| (A) Binder resin | in structure of resin | ratio | structure of binder resin |
| Polyimide (PI-1) | — | Imide cyclization | Structural unit having |
| | | ratio = 100% | imide structure |
| Polyimide (PI-2) | Sulfur element = 2.4 mass % | Imide cyclization | |
| | | ratio = 100% | |
| Polyimide precursor | — | Imide cyclization | Structural unit having |
| (PIP-1) | | ratio = 10% | imide structure and |
| Polyimide precursor | Sulfur element = 2.3 mass % | Imide cyclization | amide structure |
| (PIP-2) | | ratio = 20% | |
| Polyimide precursor | — | Imide cyclization | |
| (PIP-3) | | ratio = 10% | |
| Polyimide precursor | — | Imide cyclization | |
| (PIP-4) | | ratio = 10% | |
| Polyimide precursor | — | Imide cyclization | |
| (PIP-5) | | ratio = 10% | |
| Polyimide precursor | — | Imide cyclization | |
| (PIP-6) | | ratio = 10% | |
| Polyimide precursor | — | Imide cyclization | |
| (PIP-7) | | ratio = 20% | |
| | | Benzoxazole cyclization | |
| | | ratio = 0% | |
| Polyimide precursor | Sulfur element = 2.0 mass % | Imide cyclization | |
| (PIP-8) | | ratio = 20% | |
| Polyimide precursor | — | Imide cyclization | |
| (PIP-9) | | ratio = 10% | |
| Polyimide precursor | — | Imide cyclization | |
| (PIP-10) | | ratio = 10% | |
| Polyimide precursor | — | Imide cyclization | |
| (PIP-11) | | ratio = 10% | |
| Polyimide precursor | — | Imide cyclization | |
| (PIP-12) | | ratio = 10% | |
| Polyimide precursor | — | Imide cyclization | |
| (PIP-13) | | ratio = 10% | |
| Polyimide precursor | — | Imide cyclization | |
| (PIP-14) | | ratio = 10% | |
| Polyimide precursor | — | Imide cyclization | |
| (PIP-15) | | ratio = 10% | |
| | | Benzoxazole cyclization | |
| | | ratio = 0% | |
| Polybenzoxazole | — | Benzoxazole cyclization | Structural unit having |
| (PB-1) | | ratio = 60% | amide structure and |
| | | | oxazole structure |
| Polybenzoxazole precursor | — | Benzoxazole cyclization | Structural unit having |
| (PBP-1) | | ratio = 0% | amide structure |
| Polybenzoxazole precursor | Sulfur element = 6.4 mass % | Benzoxazole cyclization | |
| (PBP-2) | | ratio = 0% | |
| Polyamideimide (PAI-1) | — | Imide cyclization | Structural unit having |
| | | ratio = 100% | imide structure and amide |
| | | Benzoxazole cyclization | structure |
| | | ratio = 0% | |
| Polyimide (PI-3) | Fluorine element = 13.8 mass % | Imide cyclization | Structural unit having |
| | | ratio = 100% | imide structure |
| Polyimide precursor | Fluorine element = 22.7 mass % | Imide cyclization | Structural unit having |
| (PIP-16) | | ratio = 10% | imide structure and amide |
| | | Benzoxazole cyclization | structure |
| | | ratio = 0% | |
| Polybenzoxazole precursor | Fluorine element = 18. 7 mass % | Benzoxazole cyclization | Structural unit having |
| (PBP-3) | | ratio = 0% | amide structure |

| (A) Binder resin | (A) Structural unit and structure of binder resin |
|---|---|
| Polycyclic side chain- | Cardo-based resin structure having fluorene structure; |
| containing resin | Radical polymerizable group: methacryloyl group (methacrylic acid residue) |
| (CR-1) | |
| Acid-modified epoxy resin | Epoxy methacrylate resin structure having biphenyl structure; |
| (AE-1) | Radical polymerizable group: methacryloyl group (methacrylic acid residue) |
| Acrylic resin | Acrylic resin structure; Radical polymerizable group: methacryloyl group |
| (AC-1) | (glycidyl methacrylate residue) |
| Phenolic resin | Phenolic resin structure |
| (PR-1) | |
| Polyhydroxystyrene | Polyhydroxystyrene structure |
| (PHS-1) | |

| | | Imide cyclization | |
|---|---|---|---|
| | | ratio | |
| | Content of specific element | Benzoxazole cyclization | (A) Structural unit and |
| (A) Binder resin | in structure of resin | ratio | structure of binder resin |
| Polyimide (PI-4) | — | Imide cyclization | Structural unit having |
| | | ratio = 100% | imide structure |
| Polyimide (PI-5) | — | Imide cyclization | |
| | | ratio = 100% | |
| Polyimide precursor | — | Imide cyclization | Structural unit having |
| (PIP-17) | | ratio = 10% | imide structure and |
| Polyimide precursor | — | Imide cyclization | amide structure |
| (PIP-18) | | ratio = 10% | |
| Polyimide precursor | — | Imide cyclization | |
| (PIP-19) | | ratio = 10% | |
| Polyimide precursor | — | Imide cyclization | |
| (PIP-20) | | ratio = 10% | |
| Polyimide precursor | — | Imide cyclization | |
| (PIP-21) | | ratio = 10% | |
| Polyimide precursor | — | Imide cyclization | |
| (PIP-22) | | ratio = 10% | |
| Polyimide precursor | — | Imide cyclization | |
| (PIP-23) | | ratio = 10% | |
| Polyimide precursor | — | Imide cyclization | |
| (PIP-24) | | ratio = 10% | |
| Polyimide precursor | — | Imide cyclization | |
| (PIP-25) | | ratio = 10% | |
| Polyimide precursor | — | Imide cyclization | |
| (PIP-26) | | ratio = 10% | |
| Polyimide precursor | — | Imide cyclization | |
| (PIP-27) | | ratio = 10% | |
| | | Benzoxazole cyclization | |
| | | ratio = 0% | |
| Polyimide precursor | — | Imide cyclization | |
| (PIP-28) | | ratio = 10% | |
| | | Benzoxazole cyclization | |
| | | ratio = 0% | |
| Polyimide precursor | — | Imide cyclization | |
| (PIP-29) | | ratio = 10% | |
| | | Benzoxazole cyclization | |
| | | ratio = 0% | |
| Polyimide precursor | — | Imide cyclization | |
| (PIP-30) | | ratio = 10% | |
| | | Benzoxazole cyclization | |
| | | ratio = 0% | |
| Polyimide precursor | — | Imide cyclization | Structural unit having |
| (PIP-31) | | ratio = 10% | imide structure and |
| Polyimide precursor | Sulfur element = 1.0 mass % | Imide cyclization | amide structure |
| (PIP-32) | | ratio = 20% | |
| Polyimide precursor | — | Imide cyclization | |
| (PIP-33) | | ratio = 10% | |
| Polyimide precursor | — | Imide cyclization | |
| (PIP-34) | | ratio = 10% | |
| Polyimide precursor | Sulfur element = 1.0 mass % | Imide cyclization | |
| (PIP-35) | | ratio = 20% | |
| Polyimide precursor | — | Imide cyclization | |
| (PIP-36) | | ratio = 10% | |
| Polyimide precursor | — | Imide cyclization | |
| (PIP-37) | | ratio = 10% | |
| Polyimide precursor | — | Imide cyclization | |
| (PIP-38) | | ratio = 10% | |
| Polyimide precursor | — | Imide cyclization | |
| (PIP-39) | | ratio = 10% | |
| Polyimide precursor | — | Imide cyclization | |
| (PIP-40) | | ratio = 10% | |
| Polyimide precursor | Sulfur element = 1.1 mass % | Imide cyclization | |
| (PIP-41) | | ratio = 20% | |
| Polybenzoxazole | — | Benzoxazole cyclization | Structural unit having |
| (PB-2) | | ratio = 60% | amide structure and |
| | | | oxazole structure |
| Polybenzoxazole precursor | — | Benzoxazole cyclization | Structural unit having |
| (PBP-4) | | ratio = 0% | amide structure |
| Polybenzoxazole precursor | — | Benzoxazole cyclization | |
| (PBP-5) | | ratio = 0% | |
| Polybenzoxazole precursor | — | Benzoxazole cyclization | |
| (PBP-6) | | ratio = 0% | |
| Polybenzoxazole precursor | — | Benzoxazole cyclization | |
| (PBP-7) | | ratio = 0% | |
| Polyamideimide | — | Imide cyclization | Structural unit having |
| (PAI-2) | | ratio == 100% | imide structure and amide |
| | | Benzoxazole cyclization | structure |
| | | ratio = 0% | |

### Preparation Examples of Pigment Dispersion Liquids

As a pigment dispersion liquid, the compositions of the dispersion liquids obtained in Preparation Examples Bk-1 to Bk-5 are collectively shown in Table 2-5. In Preparation Examples Bk-1 to Bk-5, each pigment dispersion liquid was prepared by the following method. A list and description of the (D) colorant and the (E) dispersant used in each of Examples, Reference Examples, and Comparative Examples are collectively shown in Table 2-5.

### Preparation Examples Bk-1 to Bk-5 Preparation of Pigment Dispersion Liquids (Bk-1) to (Bk-5)

On the basis of the method described in paragraphs [0138] to [0140] and Preparation Example 1 of WO 2022/196261 A, a wet media dispersion treatment was performed by a circulation method using a colorant described in Table 2-5 and ADP which is a polyalkylene amine-based/polyoxyalkylene ether-based dispersant as a dispersant such that the average primary particle size of the pigment was the value described in Table 2-5, Thereafter, filtration was performed with a filter of 0.80 μmφ to obtain pigment dispersion liquids (Bk-1) to (Bk-5) having a solid content concentration of 15 mass % and colorant/dispersant=100/35 (mass ratio). The average primary particle size of the pigment in the obtained pigment dispersion liquid is shown in Table 2-5. In addition, the average primary particle size of the pigment in the film of the cured product (hereinafter, “cured film”) produced by the method described in Examples, the crystallite size of the pigment in the pigment dispersion liquid, and the crystallite size of the pigment in the cured film are also shown in Table 2-5.

TABLE 2-5

| | | | | | Average | Average | | |
|---|---|---|---|---|---|---|---|---|
| | | | | | primary | primary | Crystallite | Crystallite |
| | | Composition | | | particle size | particle size | size in | size of |
| | Pigment | [parts by mass] | | | in pigment | of pigment | pigment | pigment |
| | dispersion | | (E) | | dispersion | in cured | dispersion | in cured |
| | liquid | (D) Colorant | Dispersant | Solvent | liquid [nm] | film [nm] | liquid [nm] | film [nm] |
| Preparation | Pigment | Bk-S0100CF | ADP | PGMEA | 80 | 60 | — | — |
| Example | dispersion liquid | (100) | (35) | | | | | |
| Bk-1 | (Bk-1) | | | | | | | |
| Preparation | Pigment | Bk-FK4280 | | | 100 | 80 | — | — |
| Example | dispersion liquid | (100) | | | | | | |
| Bk-2 | (Bk-2) | | | | | | | |
| Preparation | Pigment | Bk-CBF1 | | | 60 | 60 | — | — |
| Example | dispersion liquid | (100) | | | | | | |
| Bk-3 | (Bk-3) | | | | | | | |
| Preparation | Pigment | Bk-CPR1 | | | 80 | 80 | — | — |
| Example | dispersion liquid | (100) | | | | | | |
| Bk-4 | (Bk-4) | | | | | | | |
| Preparation | Pigment | Bk-ZrN | | | — | — | 15 | 15 |
| Example | dispersion liquid | (100) | | | | | | |
| Bk-5 | (Bk-5) | | | | | | | |

| (D) Colorant | |
|---|---|
| (E) Dispersant | Description of (D) colorant and description of (E) dispersant |
| Bk-S0100CF | Mixture of compounds having two benzofuran-2-(3H)-one structures or two benzofuran-3(2H)-one |
| | structures; “IRGAPHOR” (registered trademark) BLACK S0100CF (manufactured by BASF SE; |
| | benzofuranone-based black pigment having a primary particle size of 40 to 80 nm) |
| Bk-FK4280 | Compound having 3,4,9,10-perylene tetracarboxylic acid bisbenzimidazole structure; |
| | “LUMOGEN” (registered trademark) BLACK FK4280 (manufactured by BASE SE; perylene-based black |
| | pigment having a primary particle size of 50 to 100 nm) |
| Bk-CBF1 | Benzofuranone-based black pigment having a coating layer (average coverage with respect to pigment: |
| | 97.5%); Silica coating layer: silica (10.0 parts by mass in terms of SiO₂ with respect to 100 parts by mass |
| | of pigment); Metal oxide coating layer: alumina (2.0 parts by mass in terms of Al₂O₃ with respect to 100 |
| | parts by mass of pigment); Benzofuranone-based black pigment having a coating layer described in |
| | paragraphs [0503] to [0505] of WO 2019/087985 A and Coating Example 1 |
| Bk-CPRI | Perylene-based black pigment having a coating layer (average coverage with respect to pigment: 84.5%) |
| | Silica coating layer: silica + silica (3.0 + 7.0 parts by mass in terms of SiO2 with respect to 100 parts by |
| | mass of pigment * two layers of silica coating layer) |
| | Perylene-based black pigment having a coating layer obtained by the synthesis method described in |
| | paragraphs [0186] to [0188] and paragraph [0191] of WO 2018/038083 and Example 18 |
| Bk-ZrN | Composite fine particles composed of zirconium nitride particles and aluminum particles produced by |
| | thermal plasma method (manufactured by Nisshin Engineering Inc.; crystallite size = 30 nm, Al element |
| | content = 4 wt %) |
| ADP | Polyalkylene amine-based-polyoxyalkylene ether-based dispersant having tertiary amino group |
| | (amine value: 20 mgKOH/g (solid content concentration: 100 mass %)) |
| | Pigment Dispersant 1 described in paragraphs [0138] to [0141] of JP 2020-070352 A and Synthesis |
| | Example 2 |
| A.R. 52 | C.I. Acid Red 52 (xanthene-based red dye) |
| B.B. 7 | C.I. Basic Blue 7 (triarylmethane-based blue dye) |
| A.R. 52-B.B. 7 | A dye obtained by mixing and stirring at A.R. 52/B.B. 7 = 1/1 (mol ratio), filtering the precipitated salt, |
| | washing with water three times, and then drying |
| S.R. 18 | C.I. Solvent Red 18 (azo-based red dye) |
| D.Y. 201 | C.I. Disperse Yellow 201 (methine-based yellow dye) |

### Synthesis Example of Silica Particle Dispersion Liquid

### Synthesis Example 30 Synthesis of Silica Particle (SP-1) Dispersion Liquid

On the basis of the method described in paragraph to paragraph of WO 2022/196261 A and Synthesis Example 3, a dispersion liquid of silica particles (SP-1) was obtained using MEK-ST-40 as a silica particle dispersion liquid, KBM-503 as a surface modifier, and MOP as a polymerization inhibitor. In the silica particles (SP-1) as inorganic particles, the functional group on the particle surface is a methacryloyl group, the distribution range of the primary particle size is 10 to 16 nm, the average primary particle size is 12 nm, the range of the aspect ratio is 1.0 to 1.1, the average aspect ratio is 1.1, and the content of the sodium element is 100 ppm by mass.

### Evaluation Methods in Examples, Reference Examples, and Comparative Examples

Evaluation methods in Examples, Reference Examples, and Comparative Examples are shown below. A glass substrate (manufactured by Geomatec Co., Ltd.; hereinafter, “ITO/Ag substrate”) obtained by forming a film of APC (silver/palladium/copper=98.07/0.87/1.06 (mass ratio)) of 100 nm on glass by sputtering and further forming a film of ITO of 10 nm on an upper layer of the APC layer by sputtering was used after UV-03 cleaning treatment was performed for 100 seconds using a desktop optical surface treatment apparatus (PL16-110; manufactured by Sen Lights Corporation). A Tempax glass substrate (manufactured by AGC Techno Glass Co., Ltd.) was used without being pretreated. The other substrate was heated at 130° C for 2 minutes using a hot plate (HP-1SA; manufactured by As One Corporation) to perform a dehydration bake treatment, and then used. In film thickness measurement, with the use of a surface roughness and contour shape measuring instrument (SURFCOM 1400D; manufactured by Tokyo Seimitsu Co., Ltd.), under the conditions of the measurement magnification of 10, 000 times, the measurement length of 1.0 mm, and the measurement speed of 0.30 mm/s, the film thickness was measured.

### (1) Weight Average Molecular Weight of Resin

In the measurement of the weight average molecular weights of the polyimide (PI-1) to (PI-3), the polyimide precursors (PIP-1) to (PIP-16), the polybenzoxazole (PB-1), the polybenzoxazole precursors (PBP-1) to (PBP-3), and the polyamideimide (PAI-1), an N-methyl-2-pyrrolidone solution of 0.10 mass % of each resin was prepared and used as a measurement sample. A gel permeation chromatography (hereinafter, “GPC”) analyzer (Waters 2690; manufactured by Waters Corporation) was used, N-methyl-2-pyrrolidone in which lithium chloride and phosphoric acid were each dissolved at 0.050 mol/L was used as a mobile phase, and the weight average molecular weight in terms of polystyrene was measured and determined. For other resins, a GPC analyzer (HLC-8220; manufactured by Tosoh Corporation) was used, tetrahydrofuran or N-methyl-2-pyrrolidone was used as a mobile phase, and the weight average molecular weight in terms of polystyrene was measured and determined by a method near normal temperature according to “JIS K7252-3 (2008)”.

### (2) Imide Cyclization Ratio and Benzoxazole Cyclization Ratio of Resin

Regarding the imide cyclization ratio, each of the above resins was dissolved in GBL so as to have a concentration of 35 mass % to prepare a resin solution. Each of the obtained resin solutions was placed on a silicon wafer with a spin coater (1H-DX; manufactured by Mikasa Co., Ltd.) and then baked at 120° C for 180 seconds to prepare a resin film having a film thickness of 4 to 5 μm. The produced silicon wafer with a resin film was divided into two parts, and one part was placed in a clean oven (CLH-21CD-S; manufactured by Koyo Thermo Systems Co., Ltd.) and heated at 140° C for 30 minutes in a nitrogen atmosphere with an oxygen concentration of 20 ppm by mass or less, and then the temperature was further raised and the one part was heated at 320° C for 60 minutes to completely cyclize to the imide ring (resin film after heating). The other was used as it was without heat treatment (resin film before heating). The transmitted infrared absorption spectrum of the resin film before and after heating was measured using an infrared spectrophotometer (FT-720; manufactured by Horiba, Ltd.). The presence of an absorption peak (near 1, 780 cm⁻¹, near 1, 377 cm⁻¹) of the imide structure due to the polyimide was confirmed, and a peak intensity (X) around 1, 377 cm⁻¹ before heating and a peak intensity (Y) around 1, 377 cm⁻¹ after heating were determined. The imide cyclization ratio in the resin film before heating was calculated from the following formula.

Imide cyclization ratio [%]=(X/Y)×100.

Regarding the benzoxazole cyclization ratio, a resin film having a film thickness of 4 to 5 μm was prepared by the same method as described above. The produced silicon wafer with a resin film was divided into two parts, and one part was heated at 320° C for 30 minutes using a buzzer hot plate (HPD-3000BZN; manufactured by As One Corporation) to completely cyclize to the benzoxazole ring (resin film after heating). The other was used as it was without heat treatment (resin film before heating). The transmitted infrared absorption spectrum of the resin film before and after heating was measured using an infrared spectrophotometer (FT-720; manufactured by Horiba, Ltd.). The presence of an absorption peak of a benzoxazole structure derived from polybenzoxazole (a peak derived from C═C (C═N) stretching vibration around 1, 570 cm⁻¹) was confirmed, and the peak intensity (P) around 1, 570 cm⁻¹ before heating and the peak intensity (Q) around 1, 570 cm⁻¹ after heating were determined. The benzoxazole cyclization ratio in the resin film before heating was calculated from the following formula.

Benzoxazole cyclization ratio [%]=(P/Q)×100.

### (3) Content of Specific Compound in Composition or Cured Film

The content of the specific nitrogen-containing compound in the composition or the cured film was measured by gas chromatography mass spectrometry and liquid chromatography mass spectrometry using a calibration curve by a standard substance. Note that the content in the total solid content of the composition was calculated from the obtained measured value and the following formula.

(Content of specific compound in total solid content of composition)=(content of specific compound in composition)×100/(solid content concentration of composition [mass %]).

### (4) Content of Specific Element in Resin, Composition, or Cured Film

The contents of fluorine element, chlorine element, bromine element, and sulfur element in the resin, the composition, or the cured film were measured by combustion ion chromatography under the following measurement conditions. Each resin was separated by GPC fractionation and then used. When the resin was composed of resins having a structure in which structural units constituting the resin are different, the resins were separated by GPC fractionation and then used. The resin in the composition was used after the composition was subjected to dichloromethane extraction, ultracentrifugation, and separation of each resin from dichloromethane insolubles by GPC fractionation in any case where the composition included a single resin or a resin having a structure in which structural units constituting the resin are different. A resin, a composition, or a cured film was combusted and decomposed in a combustion tube of an analyzer, the generated gas was absorbed into an absorption liquid, and a part of the absorption liquid was analyzed by ion chromatography. When the element content is not described, it indicates that the element is not detected. Note that the content in the total solid content of the composition was calculated from the obtained measured value and the following formula.

(Content in total solid content of composition)=(content in composition)×100/(solid content concentration of composition [mass %])

### <Combustion/Absorption Conditions>

System: AQF-2100H, GA-210 (manufactured by Mitsubishi Chemical Corporation)
Electric furnace temperature: Inlet 900° C, Outlet 1000° C
Gas: Ar/O₂ 200 ml/min, O₂ 400 ml/min
Absorption liquid: H₂O₂ 0.1 mass %
Absorption liquid amount: 5 mL

### <Ion Chromatography/Anion Analysis Conditions>

System: ICS1600 (manufactured by Dionex Corporation)
Mobile phase: 2.7 mmol/L Na₂CO₃, 0.3 mmol/L NaHCO₃
Flow rate: 1.50 mL/min
Detector: Electrical conductivity detector
Injection amount: 100 μL.

### (5) Content of Specific Anion in Resin, Composition, or Cured Film

The contents of fluoride ions, chloride ions, bromide ions, and sulfur-based anions in the resin, the composition, or the cured film were measured by ion chromatography under the following measurement conditions. The resin and the resin in the composition were used after each resin was separated by GPC fractionation, or dichloromethane extraction, ultracentrifugation, and GPC fractionation by the method described in the above (4). A resin, a composition, or a cured film was added to ultrapure water and shaken at room temperature to extract an ionic component. The extraction liquid was treated with a solid phase extraction cartridge, and then anion components were analyzed by ion chromatography. When the anion component could not be measured under the following ion chromatography analysis condition 1, the anion component was measured under the following ion chromatography analysis condition 2. When the ion content is not described, it indicates that the ion is not detected. Note that the content in the total solid content of the composition was calculated from the obtained measured value and the following formula.

(Content of specific anion in total solid content of composition)=(Content of specific anion in composition)×100/(Solid content concentration of composition [mass %])

### <Ion Chromatography Analysis Condition 1 (Anion Component)>

Apparatus: IC-2010 (manufactured by Tosoh Corporation)
Separation column: 4.6 mmφ×100 mm, TSKgel Super IC-Anion HS
Eluent: Sodium hydrogen carbonate
Column temperature: 40° C
Detector: Electrical conductivity meter
Sample injection amount: 250 μL

### <Ion Chromatography Analysis Condition 2 (Anion Component)>

Apparatus: IC-2010 (manufactured by Tosoh Corporation)
Separation column: 4.6 mmφ×100 mm, TSKgel Super IC-Anion HS
Eluent: Sodium carbonate/sodium hydrogen carbonate
Column temperature: 40° C
Detector: Electrical conductivity meter
Sample injection amount: 250 μL.

### (6) Water Content in Composition

The water content in the composition was measured by volumetric titration using a Karl Fischer moisture meter (MKS-520; manufactured by Kyoto Electronics Manufacturing Co., Ltd.) and a Karl Fischer reagent as a titration reagent according to “JIS K0113 (2005)”.

### (7) Development Residue

An FPD/LSI inspection microscope (OPTIPHOT-300; manufactured by Nikon Corporation) was used to observe the resolution pattern of the developed film prepared in each Example. As an index of development residues, the presence or absence of residues in a 20 μm line and space pattern was observed, and the presence area of residues in the opening was calculated. It was determined as follows, and A+, A, B+, B, C+, and C in which the presence area of the residue was 20% or less were regarded as acceptable.
A+: No residue
A: The residue existing area is 3% or less.
B+: The residue existing area is more than 3% and 6% or less.
B: The residue existing area is more than 6% and 10% or less.
C+: The residue existing area is more than 10% and 15% or less.
C: The residue existing area is more than 15% and 20% or less.
D: The residue existing area is more than 20% and 50% or less.
E: The residue existing area is more than 50% and 100% or less.

### (8) Light-Shielding Property (Optical Density Value (Hereinafter, “OD Value”))

A cured film of the composition was prepared on a Tempax glass substrate (manufactured by AGC Techno Glass Co., Ltd.) by the method described in Example 1 below. The incident light intensity (I₀) and the transmitted light intensity (I) at three points in the plane of the prepared cured film were measured using a transmission densitometer (X-Rite 361T (V); manufactured by X-Rite, Incorporated). As an index of the light-shielding property, the OD value per film thickness of 1 μm was calculated by the following formula, and the average value of the OD values at three points in the plane was calculated.

OD value=log₁₀(I₀/I).

(9) Ion Detection Intensity at Position of Depth of 5 Nm from Surface of Conductive Inorganic Layer and Insulating Resin Layer

In the following organic EL display produced by the method described in Example 1, the ion detection intensity was measured by time-of-flight secondary ion mass spectrometry. Etching ion species accelerated by applying a bias were collided with the pixel area from the light-emitting layer side. Primary ion species accelerated by applying a bias were collided from the light-emitting layer side while etching was performed in the depth direction from the light-emitting layer side toward the substrate side. The secondary ions released at that time were measured, and the depth profile in the depth direction from the light-emitting layer side toward the substrate side was measured. In the depth profile, a point at which the detection intensity of ion species of an element constituting the first electrode (conductive inorganic layer) was 100 or more was defined as a surface of the first electrode. When the transparent conductive oxide layer including indium as a main component element was provided on the outermost layer on the light-emitting layer side of the first electrode, the point at which the detection intensity of indium oxide ions (InO₂⁻) was 100 or more was defined as the surface of the first electrode. In addition, the position at a depth of 5 nm from the surface of the first electrode was determined by measuring a depth profile in a depth direction from the light-emitting layer side toward the substrate side from the surface of the first electrode to a surface opposite to the substrate side with the surface of the first electrode on the side in contact with the organic layer including the light-emitting layer determined as described above as a starting point, measuring the thickness of the first electrode, and calculating the sputter rate of the first electrode from these values.

Similarly, etching ion species accelerated by applying a bias were collided with the pixel division layer (insulating resin layer) from the second electrode side of the pixel division layer. Primary ion species accelerated by applying a bias were collided from the second electrode side while etching was performed in the depth direction from the pixel division layer side toward the substrate side. The secondary ions emitted at that time were measured, and the depth profile in the depth direction from the pixel division layer side toward the substrate side was measured. In the depth profile, the point at which the detection intensity of the ion species of the element constituting the pixel division layer was 100 or more was defined as the surface of the pixel division layer. Further, the position at a depth of 5 nm from the surface of the pixel division layer was determined by measuring the depth profile in the depth direction from the pixel division layer side toward the substrate side from the surface of the pixel division layer to the surface opposite to the substrate side with the surface of the pixel division layer on the second electrode side as a starting point, measuring the thickness of the pixel division layer, and calculating the sputter rate of the pixel division layer from these values.

Measurement conditions of the time-of-flight secondary ion mass spectrometry are as follows. The detection intensity of each ion was calculated as an average value obtained by measuring time-of-flight secondary ion mass spectrometry three times.

### <Measurement Conditions>

Apparatus: Time-of-Flight Secondary Ion Mass Spectrometer (TOF.SIMS5; manufactured by IONTOF GmbH)
Etching ion species: Cs⁺
Etching ion acceleration energy: 0.25 keV
Etching ion current amount: 7 nA
Etched area: 150 μm□
Measurement area: 30 μm□
Number of pixels: 128×128 pixel
Primary ion species: Bi⁺
Primary ion energy: 25 keV
Amount of primary ion current: 0.6 pA (cycle time: 50 us)
Secondary ion polarity: Negative
Mass resolution: High
Charge compensation: E-gun.

### (10) Light Emission Characteristics of Light-Emitting Element (Low Voltage Drive Characteristics/Luminance)

The voltage value of the organic EL display produced by the method described in Example 1 below was sequentially changed from the low voltage side, and light was emitted by DC driving until the current density reached 30 mA/cm². The voltage value and the current density when the voltage value was sequentially changed from the low voltage side were plotted, and the driving voltage at which the current density was 10 mA/cm² was obtained as an index of the low voltage drive characteristic and the luminance. It was determined as follows, and At, A, B+, B, C+, and C in which the driving voltage was 4.5 V or less were regarded as acceptable.
A+: The driving voltage is 3.2 V or less.
A: The driving voltage is more than 3.2 V and 3.5 V or less.
B+: The driving voltage is more than 3.5 V and 3.7 V or less.
B: The driving voltage is more than 3.7 V and 4.0 V or less.
C+: The driving voltage is more than 4.0 V and 4.2 V or less.
C: The driving voltage is more than 4.2 V and 4.5 V or less.
D: The driving voltage is more than 4.5 V and 5.5 V or less.
E: The driving voltage exceeds 5.5 V or cannot be measured.

### (11) Reliability of Light-Emitting Element

The organic EL display produced by the method described in Example 1 below was caused to emit light at 10 mA/cm² by DC driving, and whether there was a light emission defect such as a non-light emitting area or luminance unevenness was observed. In addition, as a durability test, the light-emitting element was heated to 80° C with the light extraction side facing upward, irradiated with light having a wavelength of 365 nm and an illuminance of 0.6 mW/cm², and held for 500 hours. After 500 hours, the organic EL display was caused to emit light at 10 mA/cm² by DC driving, and whether there was a change in the light emission characteristics was observed. As an index of the reliability of the light-emitting element, the light emitting area after the durability test when the light emitting area before the durability test was set to 100% was measured. It was determined as follows, and At, A, B+, B, C+, and C in which the light emitting area was 80% or more were regarded as acceptable.
A+: The light emitting area is 100%.
A: The light emitting area is 97% or more and less than 100%.
B+: The light emitting area is 94% or more and less than 97%.
B: The light emitting area is 90% or more and less than 94%.
C+: The light emitting area is 85% or more and less than 90%.
C: The light emitting area is 80% or more and less than 85%.
D: The light emitting area is 60% or more and less than 80%.
E: The light emitting area is less than 60%.

### (12) Migration Resistance (Insulation Reliability)

A cured film of a composition having a film thickness of about 1.5 μm was prepared on a migration evaluation substrate (WALTS-TEG ME0102JY; Walts Co., Ltd.) in the same manner as the method for preparing a cured film described in Example 1 below. Next, in the line and space pattern of the copper wiring of the comb teeth, the lead wire was soldered to the portion of the measurement terminal having the line of 15 μm and the space of 10 μm to produce an evaluation element. The prepared evaluation element was evaluated for insulation reliability under high temperature and high humidity using an insulation degradation evaluation system (ETAC SIR13; manufactured by Kusumoto Chemicals, Ltd.). The evaluation element was placed in a high temperature and high humidity chamber in which the test conditions were set to a temperature of 85° C and a humidity of 85% RH, a voltage of 5.0 V was applied, and the change over time of the resistance value was measured at intervals of 5 minutes. When the resistance value reached 1.0×10⁶ Ω or less, insulation failure was determined, and the test time at that time was measured as an index of migration resistance. It was determined as follows, and A+, A, B+, B, C+, and C with a test time of 200 hours or more were regarded as acceptable.
A+: The test time is 1, 000 hours or more.
A: The test time is 800 hours or more and less than 1,000 hours.
B+: The test time is 600 hours or more and less than 800 hours.
B: The test time is 400 hours or more and less than 600 hours.
C+: The test time is 300 hours or more and less than 400 hours.
C: The test time is 200 hours or more and less than 300 hours.
D: The test time is 50 hours or more and less than 200 hours.
E: The test time is less than 50 hours or unmeasurable.

### Compounds Used in Examples, Reference Examples, and Comparative Examples

The structures of the compounds used in Examples, Reference Examples, and Comparative Examples are shown below. These compounds were synthesized by a known method. (p-1) is a dissolution promoter.

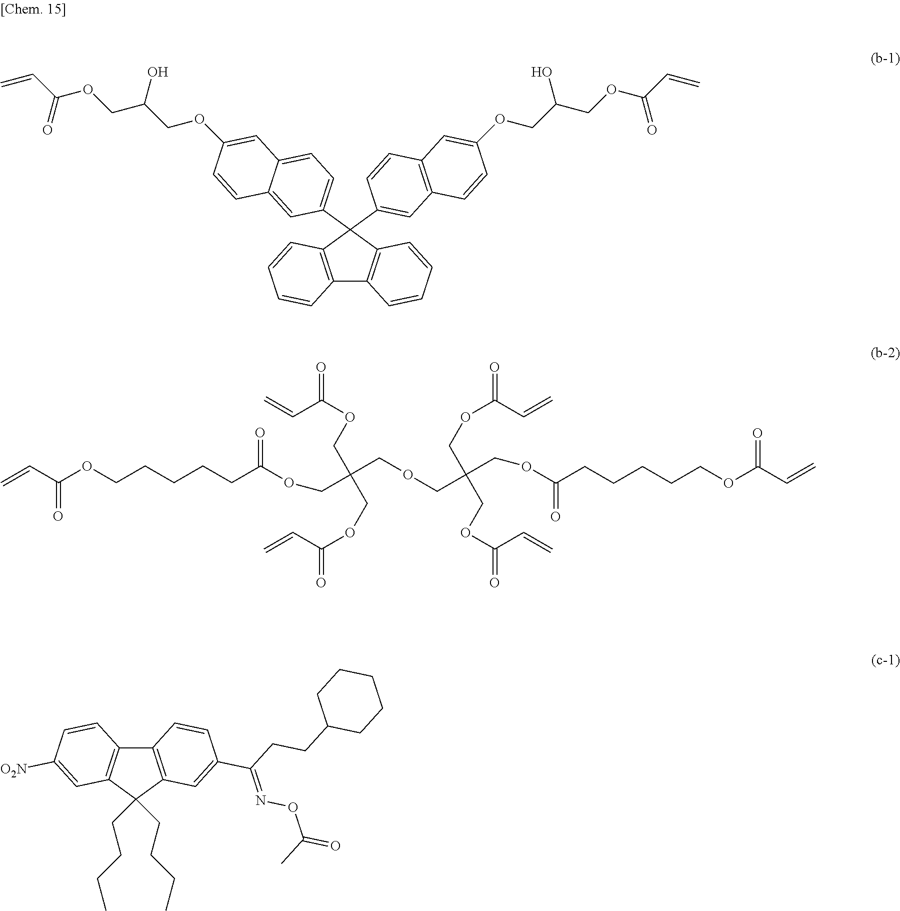

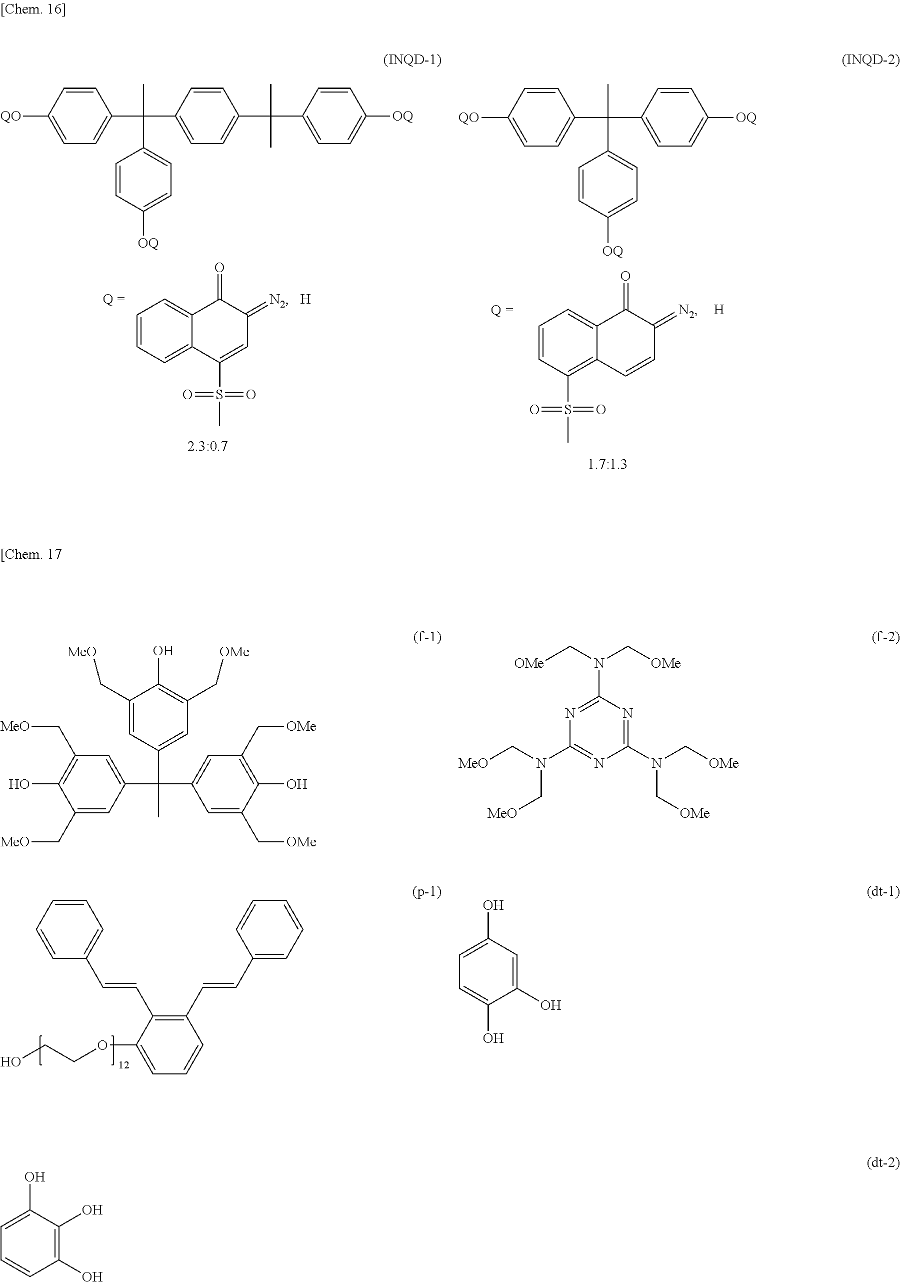

A compound including a fluorine element, a chlorine element, a bromine element, or a sulfur element (hereinafter, “compound including a specific element”) used in each of Examples, Reference Examples, and Comparative Examples; the specific nitrogen-containing compounds and the compounds corresponding thereto are collectively shown in Table 2-6.

TABLE 2-6

| Abbreviation | Compound containing specific element | Abbreviation | Specific nitrogen-containing compound |
|---|---|---|---|
| Fo-1 | 2,2-bis(4-hydroxyphenyl)hexafluoropropane | No-1 | N-methyl-2-pyrrolidone |
| F-I-1 | Ammonium fluoride(decyltriethyl) | No-2 | N,N-dimethylisobutyramide |
| Cl-1 | 2,2-bis(4-hydroxyphenyl)hexachloropropane | No-3 | N,N-dimethyl-3-methoxypropionamide |
| Cl-I-1 | Ammonium chloride(decyltriethyl) | No-4 | N,N-dimethyl-3-butoxypropionamide |
| Br-1 | 2,2-bis(4-hydroxyphenyl)hexabromopropane | No-5 | 1,3-dimethyl-2-imidazolidinone |
| Br-I-1 | Ammonium bromide(decyltriethyl) | No-6 | 1,1,3,3-tetramethylurea |
| So-1 | Ethylene bis(2-mercaptoacetate) | No-7 | N-methyl-2-oxazolidone |
| S-I-1 | Bis(decyltriethylammonium)sulfide | No-8 | N-methyl-3-isoxazolidone |

### <Preparation of Photosensitive Composition>

Composition 1 to Composition 103 were prepared with the compositions shown in Table 3-1 to Table 3-10, In Table 3-1 to Table 3-10, the numerical values in parentheses represent parts by mass of the solid content of each component. When the composition contained a pigment, first, a preparation liquid containing no pigment dispersion liquid was prepared, and then the pigment dispersion liquid and the preparation liquid were mixed to prepare a composition. Using PGMEA/EL/GBL=50/40/10 (mass ratio) as a solvent, the composition was prepared so that the solid content concentration was 20 mass %. The solution of the obtained composition was filtered through a 0.45 μmφ filter and used. Composition 45 to Composition 56 were prepared in the same manner using PGMEA/EDM/MBA=70/20/10 (mass ratio) as a solvent.

### Example 1

First, a method for preparing a cured film of a composition will be described. The composition 1 prepared on an ITO/Ag substrate was applied with the use of a spin coater (MS-A100; manufactured by Mikasa Co., Ltd.), and then prebaked at 120° C for 120 seconds with the use of a buzzer hot plate (HPD-3000BZN; manufactured by As One Corporation) to prepare a prebaked film having a film thickness of about 1.8 μm. The prebaked film was subjected to patterning exposure using a double-sided alignment single-sided exposure system (Mask Aligner PEM-6M; manufactured by Union Optical Co., Ltd.) with i-line (wavelength 365 nm), h-line (wavelength 405 nm), and g-line (wavelength 436 nm) from an ultra-high pressure mercury lamp through a grayscale mask for sensitivity measurement (MDRM MODEL 4000-5-FS; manufactured by Opto-Line International). After the exposure, the film was subjected to development with a 2.38 mass % TMAH aqueous solution with the use of a small-size development device for photolithography (AD-1200; manufactured by Takizawa Sangyo K.K.), and rinsed with water for 30 seconds to prepare a developed film. The development time was 60 seconds, 90 seconds, or 120 seconds. When a pattern could not be formed after development with a 2.38 mass % TMAH aqueous solution, an exposed film was prepared in the same manner as described above, developed with cyclopentanone after exposure, and rinsed with water for 30 seconds to prepare a developed film. The development time was similarly 60 seconds, 90 seconds, or 120 seconds. The developed pattern was observed for all the films, and the optimum exposure dose (i-ray illuminometer value) at which a space pattern corresponding to an opening could be formed with a dimension width of 20 μm in a 20 μm line and space pattern was determined. From these results, the optimum development time and the optimum exposure dose at the development time were determined. After the exposure with the optimum exposure dose, the pattern after development with the optimum development time was processed in a high-temperature inert gas oven (INH-9CD-S; Koyo Thermo Systems Co., Ltd.) at 200° C for 60 minutes to prepare a thermally cured film having a film thickness of about 1.2 μm. As thermal curing conditions, the temperature was raised to 200° C at a heating rate of 3.5° C/min in a nitrogen atmosphere having an oxygen concentration of 20 ppm by mass or less, heat treatment was performed at 200° C for 60 minutes, and then the temperature was cooled to 50° C.

The cured film was analyzed by methods such as proton nuclear magnetic resonance spectroscopy, infrared spectroscopy, pyrolysis gas chromatography mass spectrometry, reaction pyrolysis gas chromatography mass spectrometry, liquid chromatography mass spectrometry, and time-of-flight secondary ion mass spectrometry, and the structural unit of the resin and the structure of the compound contained in the cured film were analyzed. It was confirmed that the cured film of the composition 1 contained the resin and the compound in the composition 1 and the resin and the compound having a structure derived therefrom, as follows.
(XA1x) resin: Polyimide; Polyimide precursor; Polybenzoxazole; Polybenzoxazole precursor
(XA1y) resin: phenolic resin
(XC1x) compound: Carboxylic acids including an indene structure; carboxylic acid esters including an indene structure; sulfonic acids including an indene structure; and sulfonic acid aryl esters including an indene structure.

### <Production of Organic EL Display (Including Pixel Division Layer Having Thick Film Portion and Thin Film Portion)>

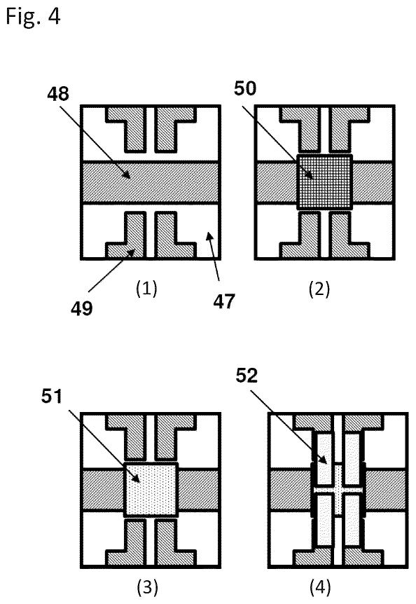

Next, a method for producing an organic EL display will be described. FIG. 4 shows a schematic view of a substrate used. First, APC (silver/palladium/copper=98.07/0.87/1.06 (mass ratio)) as a non-transparent conductive metal layer was formed in a thickness of 100 nm on a 38×46 mm alkali-free glass substrate 47 by sputtering, and subjected to pattern processing by etching to form an APC layer. Further, an amorphous ITO film having a thickness of 10 nm was formed as a transparent conductive oxide layer on the APC layer by sputtering, and subjected to pattern processing by etching to form a first electrode unit 48 as a reflective electrode. At this time, an auxiliary electrode unit 49 for taking out the second electrode was also formed at the same time ((1) in FIG. 4). The obtained electrode-equipped substrate was ultrasonically cleaned for 10 minutes using “Semico Clean” (registered trademark) 56 (manufactured by Furuuchi Chemical Corporation), and then washed with ultrapure water. Next, the composition 1 was applied and prebaked on the substrate in the same manner as described above, subjected to patterning exposure, development, and rinsing through a photomask having a predetermined pattern, and then heated and thermally cured. The processing conditions were an optimum exposure dose and an optimum development time measured in advance. The thermal curing conditions were the same as described above. By the above method, pixel division layer portions 50 having quadrangular openings having a width of 70 μm and a length of 70 μm arranged at a pitch of 175 μm in the width direction and a pitch of 175 μm in the length direction, each opening exposing the first electrode were formed only in the substrate effective area ((2) in FIG. 4). Note that the opening of the pixel division layer portion 50 finally becomes a light-emitting pixel of the organic EL display. Further, the substrate effective area was 16 mm square, and the thickness of the pixel division layer portion 50 was about 1.5 μm. Further, on the substrate on which the pixel division layer portion 50 was formed, the composition 1 was applied and prebaked in the same manner as described above, subjected to patterning exposure, development, and rinsing through a photomask having a predetermined pattern, and then heated and thermally cured. The processing conditions were an optimum exposure dose and an optimum development time measured in advance. The thermal curing conditions were the same as described above. By such a method, quadrangular thick film portions having a width of 35 μm and a length of 35 μm were formed at a plurality of locations not adjacent to the opening on the pixel division layer portion 50. The thick film portion was formed to have a thickness of about 1.5 μm.

Next, an organic EL display was produced using the substrate on which the first electrode unit 48, the auxiliary electrode unit 49, and the pixel division layer portion 50 were formed. A nitrogen plasma treatment was performed as a pretreatment, and then an organic EL layer portion 51 including a light-emitting layer was formed by a vacuum evaporation method ((3) in FIG. 4). The vacuum degree at the time of vapor deposition was 1×10⁻³ Pa or less, and the substrate was rotated with respect to the evaporation source during evaporation. First, a compound (HT-1) was deposited as a hole injection layer in a thickness of 10 nm, and a compound (HT-2) was deposited as a hole transport layer in a thickness of 50 nm. Next, a compound (GH-1) as a host material and a compound (GD-1) as a dopant material were deposited on the light-emitting layer in a thickness of 40 nm so as to have a doping concentration of 10 volt. Thereafter, a compound (ET-1) and a compound (LiQ) as electron transport materials were laminated at a volume ratio of 1:1 in a thickness of 40 nm. As the compound (Compounds (HT-1), (HT-2), (GH-1), (GD-1), (ET-1), and (LiQ)) used in the organic EL layer, the same compounds as those described in paragraphs to [0600] of WO 2017/057281 were used. Next, a compound (LiQ) was deposited to a thickness of 2 nm, and then MgAg (magnesium/silver=10/1 (volume ratio)) was deposited to a thickness of 10 nm to form a second electrode unit 52 as a transparent electrode ((4) in FIG. 4). Thereafter, sealing was performed by bonding a cap-shaped glass plate using an epoxy resin adhesive under a low humidity nitrogen atmosphere, and four 5-mm-square top emission type organic EL displays were produced on one substrate. The film thickness referred to herein is a quartz crystal film thickness monitor display value,

### Example 2 to Example 64 and Comparative Example 1 to Comparative Example 6

The same operation and evaluation as in Example 1 were performed using each composition shown in Table 3-1 to Table 3-10. These evaluation results are collectively shown in Table 3-1 to Table 3-10. When a composition having negative type photosensitivity was used in each Example, a prebaked film was prepared in the same manner as in Example 1, and spray-developed with a 2.38 mass % aqueous TMAH solution or cyclopentanone, and the time for completely dissolving the prebaked film (unexposed portion) (Breaking Point; hereinafter, “BP”) was measured, and the development time was 1.3 times the measured BP. As a photomask, a photomask in which a light-transmitting portion and a light-shielding portion were reversed was used, and a pattern after exposure at an optimum exposure dose and development was thermally cured at 200° C for 60 minutes. The contents of sulfur element and sulfur-based anions were measured only in Example 45 to Example 56.

TABLE 3-1

| | | Composition [parts by mass] | | | | | | | |
|---|---|---|---|---|---|---|---|---|---|
| | | (A) Resin | | | | | | | |
| | | (C) Photosensitive | | Content in total solid content | | | Composition of cured film | | |
| | | agent | | of composition | | | | Content in cured film | |
| | | (F) Crosslinking | Compound | | Halogen | | Specific | | Halogen |
| | | agent | containing | | ion | | compound | | ion |
| | Compo- | Dissolution | specific | Halogen element | Sulfur | Content in | in cured | Halogen element | Sulfur |
| | sition | promoter | element | Sulfur element | ion | composition | film | Sulfur element | ion |
| Example 1 | 1 | PIP-1 | Fc-1 | Fluorine element | — | Water | Fc-1 | Fluorine element | — |
| | | (45) | | (3 ppm by mass) | | (1.0 mass | | (3 ppm by mass) | |
| Example 2 | 2 | PBP-1 | | Fluorine element | — | %) | | Fluorine element | — |
| | | (30) | | (0.5 ppm by mass) | | | | (0.5 ppm by mass) | |
| Example 3 | 3 | PR-1 | | Fluorine element | — | | | Fluorine element | — |
| | | (25) | | (1 ppm by mass) | | | | (1 ppm by mass) | |
| Example 4 | 4 | NQD-1 | | Fluorine element | — | | | Fluorine element | — |
| | | (20) | | (40 ppm by mass) | | | | (40 ppm by mass) | |
| Example 5 | 5 | NQD-2 | F-I-1 | Fluorine element | Fluoride | | F-I-1 | Fluorine element | Fluoride |
| | | (10) | | (3 ppm by mass) | ion | | | (3 ppm by mass) | ion |
| | | f-1 | | | (3 ppm | | | | (3 ppm |
| | | (5) | | | by mass) | | | | by mass) |
| Example 6 | 6 | f-2 | Fc-1 | Fluorine element | — | | Fc-1 | Fluorine element | — |
| | | (5) | Cl-1 | (1 ppm by mass) | | | Cl-1 | (1 ppm by mass) | |
| | | p-1 | | Chlorine element | | | | Chlorine element | |
| | | (5) | | (1 ppm by mass) | | | | (1 ppm by mass) | |
| Example 7 | 7 | | Fo-1 | Fluorine element | Chloride | | Fc-1 | Fluorine element | Chloride |
| | | | Cl-I-1 | (1 ppm by mass) | ion | | Cl-I-1 | (1 ppm by mass) | ion |
| | | | | Chlorine element | (1 ppm | | | Chlorine element | (1 ppm |
| | | | | (1 ppm by mass) | by mass) | | | (1 ppm by mass) | by mass) |
| Example 8 | 8 | | Fc-1 | Fluorine element | — | | Fc-1 | Fluorine element | — |
| | | | Br-1 | (1 ppm by mass) | | | Br-1 | (1 ppm by mass) | |
| | | | | Bromine element | | | | Bromine element | |
| | | | | (1 ppm by mass) | | | | (1 ppm by mass) | |
| Example 9 | 9 | | Fc-1 | Fluorine element | Bromide | | Fc-1 | Fluorine element | Bromide |
| | | | Br-I-1 | (1 ppm by mass) | ion | | Br-I-1 | (1 ppm by mass) | ion |
| | | | | Bromine element | (1 ppm | | | Bromine element | (1 ppm |
| | | | | (1 ppm by mass) | by mass) | | | (1 ppm by mass) | by mass) |
| | | | | | Photosensitive characteristics/ | | | | |
| | | | | | cured film characteristics/ | | | | |
| | | | | | light emission characteristics | | | | |
| | | | | | | | | Reliability | |

| | Ion detection intensity (first electrode) | | | | | | Develop- | Low voltage | of light- | |
|---|---|---|---|---|---|---|---|---|---|---|
| | Fluoride | Chloride | Bromide | Indium | Carbon | Cyanide | ment | drive | emitting | Migration |
| | ion | ion | ion | oxide ion | ion | ion | residue | characteristic | element | resistance |
| Example 1 | 57.1 | — | — | 1,500 | 910 | 1,361 | B+ | A | B+ | B+ |
| Example 2 | 40.1 | — | — | 1,492 | 706 | 1,134 | A | A+ | A | A |
| Example 3 | 50.1 | — | — | 1,511 | 903 | 1,351 | A | A+ | B+ | B+ |
| Example 4 | 99.1 | — | — | 1,548 | 962 | 1,386 | B+ | A | B | B |
| Example 5 | 56.6 | — | — | 1,500 | 910 | 1,361 | B+ | A+ | B+ | B+ |
| Example 6 | 50.1 | 21.1 | — | 1,504 | 914 | 1,365 | A | A+ | B+ | B+ |
| Example 7 | 50.1 | 20.6 | — | 1,502 | 907 | 1,362 | A | A+ | A | B+ |
| Example 8 | 50.1 | — | 20.6 | 1,504 | 914 | 1,365 | A | A+ | B+ | B+ |
| Example 9 | 50.1 | — | 20.1 | 1,502 | 907 | 1,362 | A | A+ | A | B+ |

TABLE 3-2

| | | Composition [parts by mass] | | | | | |
|---|---|---|---|---|---|---|---|
| | | (A) Resin | | Content in total | | Composition of cured film | |
| | | (C) Photosensitive | Compound | solid content of | | Specific | Content in |
| | | agent | containing | composition | | compound | cured film |
| | | (F) Crosslinking agent | specific | Halogen element | Content in | in cured | Halogen element |
| | Composition | Dissolution promoter | element | Sulfur element | composition | film | Sulfur element |
| Example 1 | 1 | PIP-1 | Fc-1 | Fluorine element | Water | Fc-1 | Fluorine element |
| | | (45) | | (3 ppm by mass) | (1.0 | | (3 ppm by mass) |
| Example 10 | 10 | PBP-1 | Cl-1 | Chlorine element | mass %) | Cl-1 | Chlorine element |
| | | (30) | Br-1 | (1 ppm by mass) | | Br-1 | (1 ppm by mass) |
| | | PR-1 | | Bromine element | | | Bromine element |
| | | (25) | | (1 ppm by mass) | | | (1 ppm by mass) |
| Example 11 | 11 | NQD-1 | | Chlorine element | | | Chlorine element |
| | | (20) | | (0.5 ppm by mass) | | | (0.5 ppm by mass) |
| | | NQD-2 | | Bromine element | | | Bromine element |
| | | (10) | | (0.5 ppm by mass) | | | (0.5 ppm by mass) |
| Example 12 | 12 | f-1 | | Chlorine element | | | Chlorine element |
| | | (5) | | (40 ppm by mass) | | | (40 ppm by mass) |
| | | f-2 | | Bromine element | | | Bromine element |
| | | (5) | | (40 ppm by mass) | | | (40 ppm by mass) |
| | | p-1 | | | | | |
| Example 13 | 13 | (5) | Fc-1 | Fluorine element | Water | Fc-1 | Fluorine element |
| | | | | (3 ppm by mass) | (0.10 | | (3 ppm by mass) |
| | | | | | mass %) | | |
| Example 14 | 14 | | | | Water | | |
| | | | | | (0.50 | | |
| | | | | | mass %) | | |
| Example 15 | 15 | | | | Water | | |
| | | | | | (1.5 | | |
| | | | | | mass %) | | |

| | | | | | | | Photosensitive characteristics/ | | | |
|---|---|---|---|---|---|---|---|---|---|---|
| | | | | | | | cured film characteristics/ | | | |
| | | | | | | | light emission characteristics | | | |
| | | | | | | | | | Reliability | |
| | Ion detection intensity (first electrode) | | | | | | | Low voltage | of light- | |
| | Fluoride | Chloride | Bromide | Indium | Carbon | Cyanide | Development | drive | emitting | Migration |
| | ion | ion | ion | oxide ion | ion | ion | residue | characteristic | element | resistance |
| Example 1 | 57.1 | — | — | 1,500 | 910 | 1,361 | B+ | A | B+ | B+ |
| Example 10 | — | 21.1 | 20.6 | 1,503 | 913 | 1,364 | B | B | B | B |
| Example 11 | — | 16.5 | 17.5 | 1,480 | 900 | 1,350 | B+ | B+ | B | B |
| Example 12 | — | 40.5 | 41.4 | 1,548 | 962 | 1,386 | B+ | B+ | C+ | C+ |
| Example 13 | 40.5 | — | — | 1,492 | 706 | 1,134 | A | A+ | A | A |
| Example 14 | 50.1 | — | — | 1,504 | 914 | 1,365 | A | A+ | B+ | B+ |
| Example 15 | 65.1 | — | — | 1,541 | 925 | 1,377 | B+ | A | B | B |

TABLE 3-3

| | | Composition [parts by mass] | | | |
|---|---|---|---|---|---|
| | | | | | (C) Photosensitive agent |
| | | (A) Binder resin | | | (F) Crosslinking agent |
| | | | | (A1y) Resin | Dissolution promoter |
| | | | | (A2x) Resin | Compound containing |
| | Composition | (A1x) Resin | | (A2y) Resin | specific element |
| Example 1 | 1 | PIP-1 (45) | PBP-1 | PR-1 (25) | NQD-1 |
| Example 16 | 16 | PI-1 (45) | (30) | | (20) |
| Example 17 | 17 | PI-2 (45) | | | NQD-2 |
| Example 18 | 18 | PIP-2 (45) | | | (10) |
| Example 19 | 19 | PIP-3 (45) | | | f-1 |
| Example 20 | 20 | PIP-4 (45) | | | (5) |
| Example 21 | 21 | PIP-5 (45) | | | f-2 |
| Example 22 | 22 | PIP-6 (45) | | | (5) |
| Example 23 | 23 | PIP-7 (45) | | | p-1 |
| Example 24 | 24 | PIP-8 (45) | | | (5) |
| Example 25 | 25 | PIP-9 (45) | | | Fc-1 |
| Example 26 | 26 | PIP-10 (45) | | | |
| Example 27 | 27 | PIP-11 (45) | | | |
| Example 28 | 28 | PIP-12 (45) | | | |
| Example 29 | 29 | PIP-13 (45) | | | |
| Example 30 | 30 | PIP-14 (45) | | | |
| Example 31 | 31 | PIP-15 (45) | | | |
| Example 32 | 32 | PB-1 (45) | | | |
| Example 33 | 33 | PIP-1 (45) | PBP-2 | | |
| | | | (30) | | |
| Example 34 | 34 | PAI-1 (45) | PBP-1 | | |
| | | | (30) | | |
| Example 35 | 35 | PIP-1 (75) | — | | |
| Example 36 | 36 | PIP-1 (45) | PBP-1 | PHS-1 (25) | |
| Example 37 | 37 | | (30) | CR-1 (25) | |
| Example 38 | 38 | | | AE-1 (25) | |
| Example 39 | 39 | | | AC-1 (25) | |
| Example 40 | 40 | PIP-1 (40) | PBP-1 | PR-1 (20) | |
| | | | (30) | CR-1 (10) | |

| | Composition [parts by mass] | | Composition of cured film | |
|---|---|---|---|---|
| | Content in | | Specific | Content in |
| | total solid | | compound | cured film |
| | content of | Content in | in cured | Halogen element |
| | composition | composition | film | Sulfur element |
| Example 1 | Fluorine | Water | Fc-1 | Fluorine element |
| Example 16 | element | (1.0 mass %) | | (3 ppm by mass) |
| Example 17 | (3 ppm | | | |
| Example 18 | by mass) | | | |
| Example 19 | | | | |
| Example 20 | | | | |
| Example 21 | | | | |
| Example 22 | | | | |
| Example 23 | | | | |
| Example 24 | | | | |
| Example 25 | | | | |
| Example 26 | | | | |
| Example 27 | | | | |
| Example 28 | | | | |
| Example 29 | | | | |
| Example 30 | | | | |
| Example 31 | | | | |
| Example 32 | | | | |
| Example 33 | | | | |
| Example 34 | | | | |
| Example 35 | | | | |
| Example 36 | | | | |
| Example 37 | | | | |
| Example 38 | | | | |
| Example 39 | | | | |
| Example 40 | | | | |

| | | | | | Photosensitive characteristics/ | | | |
|---|---|---|---|---|---|---|---|---|
| | | | | | cured film characteristics/ | | | |
| | | | | | light emission characteristics | | | |
| | | | | | | | Reliability | |
| | Ion detection intensity (first electrode) | | | | | Low voltage | of light- | |
| | Fluoride | Indium | Carbon | Cyanide | Development | drive | emitting | Migration |
| | ion | oxide ion | ion | ion | residue | characteristic | element | resistance |
| Example 1 | 57.1 | 1,500 | 910 | 1,361 | B+ | A | B+ | B+ |
| Example 16 | 60.1 | 1,531 | 915 | 1,367 | B+ | B+ | B+ | B+ |
| Example 17 | 60.8 | 1,530 | 915 | 1,351 | B+ | B+ | B+ | B+ |
| Example 18 | 58.1 | 1,500 | 910 | 1,361 | B+ | A | B+ | B+ |
| Example 19 | 60.1 | 1,531 | 915 | 1,367 | B+ | A | B+ | B |
| Example 20 | 60.8 | 1,529 | 914 | 1,364 | B+ | A | B+ | B |
| Example 21 | 60.8 | 1,531 | 915 | 1,367 | B+ | A | B+ | B |
| Example 22 | 60.1 | 1,533 | 914 | 1,366 | B+ | A | B+ | B |
| Example 23 | 58.0 | 1,500 | 910 | 1,361 | B+ | A | B+ | B+ |
| Example 24 | 58.1 | 1,500 | 910 | 1,361 | B+ | B+ | B+ | B |
| Example 25 | 60.5 | 1,531 | 915 | 1,367 | B+ | A | B+ | B |
| Example 26 | 61.0 | 1,531 | 915 | 1,368 | B+ | A | B+ | B |
| Example 27 | 61.0 | 1,531 | 915 | 1,367 | B+ | A | B+ | B |
| Example 28 | 63.1 | 1,541 | 925 | 1,377 | B+ | B+ | B+ | B+ |
| Example 29 | 62.8 | 1,544 | 925 | 1,379 | B+ | B+ | B+ | B+ |
| Example 30 | 61.0 | 1,531 | 915 | 1,367 | B+ | B+ | B+ | B+ |
| Example 31 | 50.5 | 1,504 | 914 | 1,365 | A | A+ | B+ | B+ |
| Example 32 | 61.0 | 1,531 | 915 | 1,367 | B+ | B+ | B+ | B+ |
| Example 33 | 58.5 | 1,500 | 910 | 1,361 | B+ | A | B+ | B+ |
| Example 34 | 60.5 | 1,531 | 915 | 1,367 | B+ | B+ | B+ | B+ |
| Example 35 | 76.1 | 1,548 | 962 | 1,386 | B | B+ | B | B |
| Example 36 | 60.6 | 1,531 | 915 | 1,367 | B+ | A | B+ | B |
| Example 37 | 75.5 | 1,548 | 962 | 1,388 | B | B+ | B | B |
| Example 38 | 76.0 | 1,550 | 964 | 1,386 | B | B+ | B | B |
| Example 39 | 76.8 | 1,548 | 962 | 1,386 | B | B+ | B | B |
| Example 40 | 50.1 | 1,504 | 914 | 1,365 | B | A+ | B+ | B+ |

TABLE 3-4-1

| | | Composition [parts by mass] | | | | | | Composition of | |
|---|---|---|---|---|---|---|---|---|---|
| | | (A) Resin | | | | | | cured film | |
| | | (C) | | | | | | | Content |
| | | Photosensitive | | | | | | | in |
| | | agent | | | | | | | cured |
| | | Dissolution | (F) | | | Content in | | Specific | film |
| | | promoter | Crosslinking | | | total solid | Content | com- | Halogen |
| | | Compound | agent | | | content | in | pound | element |
| | Com- | containing | (G) Inorganic | (D) | <Thermal | of com- | com- | in cured | Sulfur |
| | position | specific element | particles | Colorant | colorant> | position | position | film | element |
| Example 1 | 1 | PIP-1 | f-1 (5) | — | — | Fluorine | Water | Fc-1 | Fluorine |
| | | (45) | f-2 (5) | | | element | (1.0 | | element |
| Example 41 | 41 | PBP-1 | f-1 (5) | — | — | (3 ppm | mass %) | | (3 ppm |
| | | (30) | f-2 (5) | | | by mass) | | | by mass) |
| | | PR-1 | SP-1 (20) | | | | | | |
| | | (25) | | | | | | | |
| Example 42 | 42 | NQD-1 | f-1 (5) | A.R.52- | | | | | |
| | | (20) | f-2 (5) | B.B.7 | | | | | |
| | | NQD-2 | | (15.0) | | | | | |
| | | (10) | | S.R.18 | | | | | |
| | | p-1 | | (6.0) | | | | | |
| | | (5) | | D.Y.201 | | | | | |
| | | Fc-1 | | (9.0) | | | | | |
| Example 43 | 43 | PIP-1 | f-1 (5) | A.R.52- | dt-1 | | | | |
| | | (45) | f-2 (15) | B.B.7 | (15) | | | | |
| | | PBP-1 | | (21.0) | | | | | |
| | | (30) | | S.R.18 | | | | | |
| | | PR-1 | | (9.0) | | | | | |
| | | (25) | | | | | | | |
| | | NQD-1 | | | | | | | |
| Example 44 | 44 | (20) | | | dt-2 | | | | |
| | | NQD-2 | | | (15) | | | | |
| | | (10) | | | | | | | |
| | | Fc-1 | | | | | | | |

TABLE 3-5-1

| | | Composition [parts by mass] | | | | | | Composition | |
|---|---|---|---|---|---|---|---|---|---|
| | | (A) Resin | | | | | | of cured film | |
| | | (B) Compound | | | (E) | Content in | | | Content in |
| | | (C) Photosensitive agent | | (D) Colorant | Dispersant | total solid | | | cured film |
| | | (F) Crosslinking agent | | derived from | derived from | content | Content | Specific | Halogen |
| | | Dissolution promoter | Pigment | pigment | pigment | of | in | compound | element |
| | Com- | Compound containing | dispersion | dispersion | dispersion | com- | com- | in cured | Sulfur |
| | position | specific element | liquid | liquid | liquid | position | position | film | element |
| Example 45 | 45 | PI-1 | Bk-1 | Bk-S0100CF | ADP | Fluorine | Water | Fc-1 | Fluorine |
| | | (35) | | (37.0) | (13.0) | element | (1.0 | | element |
| Example 46 | 46 | PBP-1 | Bk-2 | Bk-FK4280 | | (3 ppm | mass %) | | (3 ppm |
| | | (20) | | (37.0) | | by mass) | | | by mass) |
| | | PR-1 | | | | | | | |
| Example 47 | 47 | (10) | Bk-3 | Bk-CBF1 | | | | | |
| | | b-1 | | (37.0) | | | | | |
| | | (10) | | | | | | | |
| Example 48 | 48 | b-2 | Bk-4 | Bk-CPR1 | | | | | |
| | | (25) | | (37.0) | | | | | |
| | | c-1 | | | | | | | |
| Example 49 | 49 | (10) | Bk-5 | Bk-ZrN | ADP | | | | |
| | | f-2 | | (22.0) | (7.7) | | | | |
| | | (3) | | | | | | | |
| Example 50 | 50 | p-1 | Bk-3 | Bk-CBF1 | ADP | | | | |
| | | (2) | | (7.0) | (2.4) | | | | |
| | | Fc-1 | | | | | | | |
| Example 51 | 51 | | — | — | — | | | | |

TABLE 3-6-1

| | | Composition [parts by mass] | | | | | | | | |
|---|---|---|---|---|---|---|---|---|---|---|
| | | (A) Resin | | | | | | | | |
| | | (B) Compound | | | | Content | | | | |
| | | (C) Photosensitive | Com- | | | in | | | | |
| | | agent | pound | Content in total solid content | | total | | Composition of cured film | | |
| | | (F) Crosslinking | con- | of composition | | solid | Content | Specific | Content in cured film | |
| | | agent | taining | Halogen | Halogen | content | in | compound | Halogen | Halogen |
| | Com- | Dissolution | specific | element | ion | of com- | com- | in cured | element | ion |
| | position | promoter | element | Sulfur element | Sulfur ion | position | position | film | Sulfur element | Sulfur ion |
| Exam- | 51 | PI-1 | Fc-1 | Fluorine element | — | Fluorine | Water | Fc-1 | Fluorine element | — |
| ple 51 | | (35) | | (3 ppm by mass) | | element | (1.0 | | (3 ppm by mass) | |
| Exam- | 52 | PBP-1 | Fc-1 | Fluorine element | — | (3 ppm | mass | Fc-1 | Fluorine element | — |
| ple 52 | | (20) PR-1 | Sc-1 | (1 ppm by mass) | | by mass) | %) | Sc-1 | (1 ppm by mass) | |
| | | (10) | | Sulfur element | | | | | Sulfur element | |
| | | b-1 | | (1 ppm by mass) | | | | | (1 ppm by mass) | |
| Exam- | 53 | (10) | Fc-1 | Fluorine element | Sulfide ion | | | Fc-1 | Fluorine element | Sulfide |
| ple 53 | | b-2 | S-I-1 | (1 ppm by mass) | (1 ppm | | | S-I-1 | (1 ppm by mass) | ion (1 ppm |
| | | (25) | | Sulfur element | by mass) | | | | Sulfur element | by mass) |
| | | c-1 | | (1 ppm by mass) | | | | | (1 ppm by mass) | |
| Exam- | 54 | (10) | Cl-1 | Chlorine element | — | | | | Chlorine element | — |
| ple 54 | | f-2 | Sc-1 | (1 ppm by mass) | | | | | (1 ppm by mass) | |
| | | (3) | | Sulfur element | | | | | Sulfur element | |
| | | P-1 (2) | | (1 ppm by mass) | | | | | (1 ppm by mass) | |
| Exam- | 55 | | | Chlorine element | — | | | Cl-1 | Chlorine element | — |
| ple 55 | | | | (0.5 ppm by mass) | | | | Sc-1 | (0.5 ppm by mass) | |
| | | | | Sulfur element | | | | | Sulfur element | |
| | | | | (0.5 ppm by mass) | | | | | (0.5 ppm by mass) | |
| Exam- | 56 | | | Chlorine element | — | | | | Chlorine element | — |
| ple 56 | | | | (40 ppm by mass) | | | | | (40 ppm by mass) | |
| | | | | Sulfur element | | | | | Sulfur element | |
| | | | | (40 ppm by mass) | | | | | (40 ppm by mass) | |

TABLE 3-7-1

| | | Composition [parts by mass] | | | | | | | | |
|---|---|---|---|---|---|---|---|---|---|---|
| | | | | Content | Content | | | | | |
| | | (A) Resin | | in | in | | Composition of cured film | | | |
| | | (C) Photosensitive | | total | total | | | | Content in | |
| | | agent | | solid | solid | | | | cured film | |
| | | (F) Crosslinking | | content | content | Content | Specific | | Halogen | |
| | | agent | Specific | of | of | in | compound | | element | Specific |
| | Com- | Dissolution | com- | com- | com- | com- | in cured | | Sulfur | com- |
| | position | promoter | pound | position | position | position | film | | element | pound |
| Example 1 | 1 | PIP-1 | — | — | Fluorine | Water | (Fc-1) | — | Fluorine | — |
| | | (45) | | | element | (1.0 mass %) | | | element | |
| Example 57 | 57 | PBP-1 | Nc-1 | 1.0 mass % | (3 ppm | | | Nc-1 | (3 ppm | 1.0 mass % |
| Example 58 | 58 | (30) | Nc-2 | 1.0 mass % | by mass) | | | Nc-2 | by mass) | 1.0 mass % |
| | | PR-1 | | | | | | | | |
| Example 59 | 59 | (25) | Nc-3 | 1.0 mass % | | | | Nc-3 | | 1.0 mass % |
| | | NQD-1 | | | | | | | | |
| | | (20) | | | | | | | | |
| Example 60 | 60 | NQD-2 | Nc-4 | 1.0 mass % | | | | Nc-4 | | 1.0 mass % |
| | | (10) | | | | | | | | |
| Example 61 | 61 | f-1 | Nc-5 | 1.0 mass % | | | | Nc-5 | | 1.0 mass % |
| | | (5) | | | | | | | | |
| Example 62 | 62 | f-2 | Nc-6 | 1.0 mass % | | | | Nc-6 | | 1.0 mass % |
| | | (5) | | | | | | | | |
| Example 63 | 63 | p-1 | Nc-7 | 1.0 mass % | | | | Nc-7 | | 1.0 mass % |
| | | (5) | | | | | | | | |
| | | Fc-1 | | | | | | | | |
| Example 64 | 64 | | Nc-8 | 1. 0 mass % | | | | Nc-8 | | 1.0 mass % |

TABLE 3-8-1

| | | Composition [parts by mass] | | | | | | | |
|---|---|---|---|---|---|---|---|---|---|
| | | | | | (C) Photosensitive | | | Composition of cured film | |
| | | | | | agent | | | | Content |
| | | | | | (F) Crosslinking | Content | | | in |
| | | | | | agent | in | | | cured |
| | | | | | Dissolution | total | | | film |
| | | (A) Binder resin | | | promoter | solid | Content | Specific | Halogen |
| | | | | (A1y) Resin | Compound | content | in | compound | element |
| | Com- | | | (A2x) Resin | containing | of com- | com- | in cured | Sulfur |
| | position | (A1x) Resin | | (A2y) Resin | specific element | position | position | film | element |
| Example 1 | 1 | PIP-1 (45) | PBP-1 | PR-1 | NQD-1 | Fluorine | Water | Fc-1 | Fluorine |
| Example 65 | 65 | PI-4 (45) | (30) | (25) | (20) | element | (1.0 | | element |
| Example 66 | 66 | PI-5 (45) | | | NQD-2 | (3 ppm | mass | | (3 ppm |
| Example 67 | 67 | PIP-17 (45) | | | (10) | by mass) | %) | | by mass) |
| Example 68 | 68 | PIP-18 (45) | | | f-1 | | | | |
| Example 69 | 69 | PIP-19 (45) | | | (5) | | | | |
| Example 70 | 70 | PIP-20 (45) | | | f-2 | | | | |
| Example 71 | 71 | PIP-21 (45) | | | (5) | | | | |
| Example 72 | 72 | PIP-22 (45) | | | p-1 | | | | |
| Example 73 | 73 | PIP-23 (45) | | | (5) | | | | |
| Example 74 | 74 | PIP-24 (45) | | | Fc-1 | | | | |
| Example 75 | 75 | PIP-25 (45) | | | | | | | |
| Example 76 | 76 | PIP-26 (45) | | | | | | | |
| Example 77 | 77 | PIP-27 (45) | | | | | | | |
| Example 78 | 78 | PIP-28 (45) | | | | | | | |
| Example 79 | 79 | PIP-29 (45) | | | | | | | |
| Example 80 | 80 | PIP-30 (45) | | | | | | | |
| Example 81 | 81 | PIP-31 (45) | | | | | | | |
| Example 82 | 82 | PIP-32 (45) | | | | | | | |

TABLE 3-9-1

| | | Composition [parts by mass] | | | | | | | |
|---|---|---|---|---|---|---|---|---|---|
| | | | | | (C) Photosensitive | | | | |
| | | | | | agent | | | | |
| | | | | | (F) Crosslinking | | | | |
| | | | | | agent | Content | | Composition of cured film | |
| | | | | | Dissolution | in | | | Content in |
| | | | | | promoter | total | | | cured film |
| | | (A) Binder resin | | | Compound | solid | Content | Specific | Halogen |
| | | | | (A1y) Resin | containing | content | in | compound | element |
| | Com- | | | (A2x) Resin | specific | of com- | com- | in cured | Sulfur |
| | position | (A1x) Resin | | (A2y) Resin | element | position | position | film | element |
| Example 1 | 1 | PIP-1 (45) | PBP-1 | PR-1 | NQD-1 | Fluorine | Water | Fc-1 | Fluorine |
| Example 83 | 83 | PIP-33 (45) | (30) | (25) | (20) | element | (1.0 mass | | element |
| Example 84 | 84 | PIP-34 (45) | | | NQD-2 | (3 ppm | %) | | (3 ppm |
| Example 85 | 85 | PIP-35 (45) | | | (10) | by mass) | | | by mass) |
| Example 86 | 86 | PIP-36 (45) | | | f-1 | | | | |
| Example 87 | 87 | PIP-37 (45) | | | (5) | | | | |
| Example 88 | 88 | PIP-38 (45) | | | f-2 | | | | |
| Example 89 | 89 | PIP-39 (45) | | | (5) | | | | |
| Example 90 | 90 | PIP-40 (45) | | | p-1 | | | | |
| Example 91 | 91 | PIP-41 (45) | | | (5) | | | | |
| Example 92 | 92 | PB-2 (45) | | | Fc-1 | | | | |
| Example 93 | 93 | PIP-1 (45) | PBP-4 | | | | | | |
| | | | (30) | | | | | | |
| Example 94 | 94 | | PBP-5 | | | | | | |
| | | | (30) | | | | | | |
| Example 95 | 95 | | PBP-6 | | | | | | |
| | | | (30) | | | | | | |
| Example 96 | 96 | | PBP-7 | | | | | | |
| | | | (30) | | | | | | |
| Example 97 | 97 | PAI-2 (45) | PBP-1 | | | | | | |
| | | | (30) | | | | | | |

TABLE 3-10-1

| | | Composition [parts by mass ] | | | | | | | | |
|---|---|---|---|---|---|---|---|---|---|---|
| | | | (Aly) Resin | | | | | | | |
| | | | (C) | | | | | | | |
| | | | Photosensitive | Com- | Content in total solid | | | | | |
| | | | agent | pound | content of composition | | | Composition of cured film | | |
| | | | (F) Crosslinking | con- | | Halogen | Content | Specific | Content in cured film | |
| | | | agent | taining | | ion | in | compound | | Halogen |
| | Com- | (A1x) | Dissolution | specific | Halogen element | Sulfur | com- | in cured | Halogen element | ion |
| | position | Resin | promoter | element | Sulfur element | ion | position | film | Sulfur element | Sulfur ion |
| Com- | 98 | PIP-1 | PR-1 | Fc-1 | Fluorine element | — | Water | Fc-1 | Fluorine element | — |
| parative | | (45) | (25) | | (1,500 ppm by mass) | | (1.0 | | (1,500 ppm by mass) | |
| Example 1 | | PBP-1 | NQD-1 | | | | mass | | | |
| Com- | 99 | (30) | (20) | F-I-1 | Fluorine element | Fluoride ion | %) | F-I-1 | Fluorine element | Fluoride ion |
| parative | | | NQD-2 | | (1,500 ppm by mass) | (1,500 ppm | | | (1,500 ppm by mass) | (1,500 ppm |
| Example 2 | | | (10) | | | by mass ) | | | | by mass ) |
| Com- | 100 | | f-1 | Fc-1 | Fluorine element | Chloride ion | | Fc-1 | Fluorine element | Chloride ion |
| parative | | | (5) | Cl-I-1 | (1,500 ppm by mass) | (1,500 ppm | | Cl-I-1 | (1,500 ppm by mass) | (1,500 ppm |
| Example 3 | | | f-2 | | Chlorine element | by mass) | | | Chlorine element | by mass) |
| | | | (5) | | (1,500 ppm by mass) | | | | (1,500 ppm by mass) | |
| Com- | 101 | | p-1 | Fc-1 | Fluorine element | Bromide ion | | Fc-1 | Fluorine element | Bromide ion |
| parative | | | (5) | Br-I-1 | (1,500 ppm by mass) | (1,500 ppm | | Br-I-1 | (1,500 ppm by mass) | (1,500 ppm |
| Example 4 | | | | | Bromine element | by mass) | | | Bromine element | by mass) |
| | | | | | (1,500 ppm by mass) | | | | (1,500 ppm by mass) | |
| Com- | 102 | PIP-16 | | PIP-16 | Fluorine element | — | | PIP-16 | Fluorine element | — |
| parative | | (45) | | PBP-3 | (109, 000 ppm | | | PBP-3 | (109, 000 | |
| Example 5 | | PBP-3 | | | by mass) | | | | ppm by mass) | |
| | | (30) | | | | | | | | |
| Com- | 103 | PI-3 | | PI-3 | Fluorine element | — | | PI-3 | Fluorine element | — |
| parative | | (45) | | PBP-3 | (82,000 ppm | | | PBP-3 | (82, 000 ppm | |
| Example 6 | | PBP-3 | | | by mass) | | | | by mass) | |
| | | (30) | | | | | | | | |

In Comparative Example 1 to Comparative Example 4, the content of the fluorine element in the total solid content of the composition does not satisfy the matters specifying the invention of the composition of the present invention. In Comparative Example 5 and Comparative Example 6, the content of the fluorine element in the structure of the (A1x) resin is large, and the content of the fluorine element in the total solid content of the composition exceeds a suitable range. Therefore, Comparative Example 1 to Comparative Example 6 are inferior in various properties.

### Example 98; Production of Organic EL Display

An organic EL display was produced by the method described in Example 1 except that the thin film portion of the pixel division layer was produced using the composition 47 in place of the composition 1, and the thick film portion of the pixel division layer was formed using the composition 51. The results of evaluating various characteristics in the same manner as in Example 1 are collectively shown in Table 3-11. The structural unit of the resin and the structure of the compound contained in the thin film portion and the thick film portion were analyzed in the same manner. The thin film portion and the thick film portion included, respectively, the resin and the compound in the composition 47 or the composition 51, and the resin and the compound having a structure derived therefrom, as follows. The OD value per film thickness of 1 μm, which is an index of the light-shielding property of the thin film portion, was 0.9.

### Thin Film Portion:

(XA1x) resin: Polyimide; Polybenzoxazole; Polybenzoxazole precursor
(XA1y) resin: phenolic resin
(XC2x) compound: Compound having fluorene structure and having structure in which imino group is bonded to fluorene structure
(XD) colorant: Benzofuranone-based black pigment

### Thick Film Portion:

(XA1x) resin: Polyimide; Polybenzoxazole;

### Polybenzoxazole Precursor

(XA1y) resin: phenolic resin
(XC2x) compound: A compound having a fluorene structure and having a structure in which an imino group is bonded to the fluorene structure.

### Example 99; Preparation of Organic EL Display (Batch Processing of Thick Film Portion and Thin Film Portion)

An organic EL display was produced by the method described in Example 1 except that the cured film of the composition 43 was formed as the pixel division layer portion 50 by a method of collectively processing the step shape using a halftone photomask having a predetermined pattern. The pixel division layer portion 50 was formed so as to have a thick film portion having a film thickness of about 3.0 μm and a thin film portion having a film thickness of about 1.5 μm. The results of evaluating various characteristics in the same manner as in Example 1 are collectively shown in Table 3-11. The structural unit of the resin and the structure of the compound contained in the thin film portion and the thick film portion were analyzed in the same manner. The thin film portion and the thick film portion each contained the resin and compound in composition 43, and resins and compounds having structures derived therefrom, as follows. That is, the thin film portion and the thick film portion obtained by curing composition 43 include the same compound. The OD values per film thickness of 1 μm, which is an index of the light-shielding property of the thin film portion and the thick film portion, were both 0.9.
(XA1x) resin: Polyimide; Polyimide precursor; Polybenzoxazole; Polybenzoxazole precursor
(XA1y) resin: phenolic resin
(XC1x) compound: Carboxylic acids including an indene structure; Carboxylic acid esters including an indene structure; Sulfonic acids including an indene structure; Aryl sulfonic acid esters including an indene structure
(XD) colorant: C.I. Acid Red 52; C.I. Basic Blue 7; C.I. Solvent Red 18
Other compounds: 1,2,4-trihydroxybenzene; structure represented by Formula (12)

A compound having a specific crosslinked structure (a structure represented by formula (12) and a quinone structure represented by formula (12)).

In addition, the results of measuring the respective ion detection intensities on the surface of the pixel division layer portion and the respective ion detection intensities on the surface of the first electrode for Example 1, Example 6, Examples 10 to 12, Example 65, and Example 66 are also collectively shown in Table 3-9.

TABLE 3-11

| | | | | | Composition of cured film | | | Ion detection intensity | | | |
|---|---|---|---|---|---|---|---|---|---|---|---|
| | Composition | | Composition | | Specific | Content in | | (Pixel division layer/ | | | |
| | for forming | | for forming | | compound | cured film | | thin film portion) | | | |
| | thin film | | thick film | | in cured | Halogen element | | Fluoride | Chloride | Bromide | |
| | portion | | portion | | film | Sulfur element | | ion | ion | ion | |
| Example 1 | 1 | | 1 | | Fc-1 | Fluorine element | | 58.1 | — | — | |
| | | | | | | (3 ppm by mass) | | | | | |
| Example 6 | 6 | | 1 | | Fc-1 | Fluorine element | | 51.0 | 22.0 | — | |
| | | | | | Cl-1 | (1 ppm by mass) | | | | | |
| | | | | | | Chlorine element | | | | | |
| | | | | | | (1 ppm by mass) | | | | | |
| Example 10 | 10 | | 1 | | Cl-1 | Chlorine element | | — | 22.0 | 21.5 | |
| | | | | | Br-1 | (1 ppm by mass) | | | | | |
| | | | | | | Bromine element | | | | | |
| | | | | | | (1 ppm by mass) | | | | | |
| Example 11 | 11 | | 1 | | | Chlorine element | | — | 17.5 | 18.5 | |
| | | | | | | (0.5 ppm by mass) | | | | | |
| | | | | | | Bromine element | | | | | |
| | | | | | | (0.5 ppm by mass) | | | | | |
| Example 12 | 12 | | 1 | | | Chlorine element | | — | 41.5 | 42.4 | |
| | | | | | | (40 ppm by mass) | | | | | |
| | | | | | | Bromine element | | | | | |
| | | | | | | (40 ppm by mass) | | | | | |
| Example 98 | 47 | | 51 | | Fc-1 | Fluorine element | | 40.7 | — | — | |
| Example 99 | 43 (batch processing) | | | | | (3 ppm by mass) | | 39.5 | — | — | |
| | | | | | | | Photosensitive characteristics/cured film characteristics/ | | | | |
| | | | | | | | light emission characteristics | | | | |
| | Ion detection intensity | | | | | | | Light- | | Reliability | |
| | (First electrode) | | | | | | | shielding | Low voltage | of light- | |
| | Fluoride | Chloride | Bromide | Indium | Carbon | Cyanide | Development | property | drive | emitting | Migration |
| | ion | ion | ion | oxide ion | ion | ion | residue | OD value | characteristic | element | resistance |
| Example 1 | 57.1 | — | — | 1,500 | 910 | 1,361 | B+ | — | A | B+ | B+ |
| Example 6 | 50.1 | 21.1 | — | 1,504 | 914 | 1,365 | A | — | A+ | B+ | B+ |
| Example 10 | — | 21.1 | 20.6 | 1,503 | 913 | 1,364 | B | — | B | B | B |
| Example 11 | — | 16.5 | 17.5 | 1,480 | 900 | 1,350 | B+ | — | B+ | B | B |
| Example 12 | — | 40.5 | 41.4 | 1,548 | 962 | 1,386 | B+ | — | B+ | C+ | C+ |
| Example 98 | 39.7 | — | — | 1,495 | 701 | 1,133 | A | 0.9 | A+ | A+ | A |
| Example 99 | 38.5 | — | — | 1,499 | 695 | 1,134 | A | 0.9 | A+ | A+ | A+ |

### <Storage Stability of Photosensitive Composition>

Each composition prepared in Example 1 to Example 97 was stored at 25° C for one week. After the storage, as a result of forming a film of the composition on the substrate in the same manner as in Example 1, there was no generation of foreign matters, and the storage stability was good. On the other hand, the composition 98 to the composition 103 in which the content of the fluorine element in the total solid content of the photosensitive compositions exceeds 1, 000 ppm by mass, prepared in Comparative Example 1 to Comparative Example 6, were stored at 25° C for one week in the same manner. After the storage, as a result of forming a film of the composition on the substrate in the same manner, there were many foreign matters generated, and the storage stability was poor.

### DESCRIPTION OF REFERENCE SIGNS

10A: Semiconductor device having bumps
11: Silicon substrate
12: Al pad
13: Passivation layer
14: Insulating layer
15: Metal layer
16: Metal wiring
17: Insulating layer
18: Barrier metal layer
19: Scribe line
20: Solder bump
30A: Display device having interlayer insulating layer, barrier layer, and planarization layer
31: Light-emitting element
32: Interlayer insulating layer
33, 33c: Metal wiring
34: Counter substrate
35: Electrode terminal
36: Light-emitting element driving substrate
37: Drive element
38: Barrier metal
39: Solder bump
40: Barrier layer
41: Planarization layer
47: Alkali-free glass substrate
48: First electrode portion
49: Auxiliary electrode portion
50: Pixel division layer portion
51: Organic EL layer portion including light-emitting layer
52: Second electrode portion
100A: Display device having step shape in which pixel division layer has thick film portions and thin film portions
101: Substrate
102: Metal wiring
103: TFT element layer
104: Interlayer insulating layer
105: TFT planarization layer/TFT protective layer
106: Pixel division layer having step shape
106a: Thin film portion in pixel division layer portion
107: First electrode
108: Light-emitting layer
109: Second electrode
110: Sealing layer
111: Touch panel wiring/touch panel electrode
112: Color filter layer
113: Black matrix layer
114: Overcoat layer
115: Substrate
116: Thick film portion in pixel division layer
100x: Cross-sectional axis in plan view
112a: Color filter layer portion
116a: Thick film portion in pixel division layer portion
117a: Opening of pixel division layer portion having step shape
118a: Opening of black matrix layer portion

1. An element comprising a substrate, a conductive inorganic layer, and an insulating resin layer in this order, wherein
the insulating resin layer has a plurality of openings, and
when a detection intensity of fluorine ions (F⁻) measured by time-of-flight secondary ion mass spectrometry at a position of 5 nm in depth from a surface of the conductive inorganic layer on the insulating resin layer side in the opening is denoted by (F_{ML}) counts, Formula (FA-1) is satisfied:
(F_{ML})≤500 (FA-1).

2. A display device comprising the element according to claim 1, further comprising a second electrode, and a light-emitting layer, wherein the conductive inorganic layer is a first electrode, and the insulating resin layer is a pixel division layer, or the display device further comprising a first electrode, a second electrode, a pixel division layer, and a light-emitting layer, wherein the insulating resin layer is a TFT planarization layer, and the conductive inorganic layer is a metal wiring layer.

3. The display device according to claim 2, wherein
the first electrode is a multi-layered non-transparent electrode, and
at least one of the layers of the first electrode other than an outermost layer on a light-emitting layer side has a non-transparent conductive metal layer containing silver or copper as a main component element.

4. The display device according to claim 3, wherein
the first electrode has a transparent conductive oxide layer and a non-transparent conductive metal layer, and
the outermost layer of the first electrode on the light-emitting layer side has a transparent conductive oxide layer containing indium as a main element.

5. The display device according to claim 4, further comprising a second electrode, and a light-emitting layer, wherein
the conductive inorganic layer is a first electrode, and the insulating resin layer is a pixel division layer, and
when a detection intensity of indium oxide ions (InO₂⁻) measured by time-of-flight secondary ion mass spectrometry at a position 5 nm deep from a surface of the transparent conductive oxide layer on a side in contact with the light-emitting layer in the opening is denoted by (InO_{ML}) counts, Formula (FA-2) and Formula (InA-1) are satisfied:
(F_{ML})/(InO_{ML})≤0.5000 (FA-2)
1,000≤(InO_{ML})≤40,000 (InA-1).

6. The display device according to claim 2, wherein
the pixel division layer has a step shape with a thick film portion and a thin film portion, and
the thick film portion and the thin film portion include a same (XA) resin, or
the thick film portion and the thin film portion include a same (XD) colorant, and an optical density at a visible light wavelength per 1 μm of film thickness of both the thick film portion and the thin film portion is 0.5 or more and 3.0 or less.

7. The display device according to claim 2, wherein
the pixel division layer has a step shape having a thick film portion and a thin film portion,
the thin film portion includes a (XD) colorant, an optical density at a visible light wavelength per 1 μm of film thickness of the thin film portion is 0.5 or more and 3.0 or less, and
the thick film portion satisfies at least one of conditions (SP1) to (SP3) below:
(SP1) the thick film portion does not include a (XD) colorant;
(SP2) the thick film portion includes an (XD) colorant, and the thick film portion has an optical density of 0.0 or more and 0.3 or less at a wavelength of visible light per 1 μm of a film thickness;
(SP3) the thick film portion includes (XC1x) compound: one or more compounds selected from a group consisting of carboxylic acid having an indene structure, carboxylic acid ester having an indene structure, sulfonic acid having an indene structure, and sulfonic acid aryl ester having an indene structure.

8. The element according to claim 1, wherein when a detection intensity of a chloride ion (Cl⁻), a detection intensity of a bromide ion (Br⁻), and a detection intensity of a sulfur ion (S⁻) measured by time-of-flight secondary ion mass spectrometry at a position of 5 nm in depth from a surface of the conductive inorganic layer on the insulating resin layer side in the opening are denoted by (Cl_{ML}) counts, (Br_{ML}) counts, and (S_{ML}) counts, respectively,
at least one of Formula (ClA-1), Formula (BrA-1), and Formula (SA-1) is satisfied:
(Cl_{ML})≤200 (ClA-1)
(Br_{ML})≤200 (BrA-1)
(S_{ML})≤200 (SA-1).

9. The element according to claim 1, wherein the (F_{ML}) is 40 or less.

10. The element according to claim 1, wherein the insulating resin layer includes a (XA1x) resin: a resin having one or more structures selected from a group consisting of an imide structure, an amide structure, an oxazole structure, and a siloxane structure in a structural unit of resin, and/or a (XA1y) resin: a resin having a phenolic hydroxyl group in a structural unit of a resin.

11. The element according to claim 10, wherein the insulating resin layer includes the (XA1x) resin, and the (XA1x) resin includes one or more resins selected from a group consisting of a polyimide, a polyimide precursor, a polybenzoxazole, a polybenzoxazole precursor, a polyamideimide, a polyamideimide precursor, and a copolymer thereof.

12. The element according to claim 11, wherein the (XA1x) resin has an amine residue having a phenolic hydroxyl group, and the amine residue having a phenolic hydroxyl group has an amine residue satisfying a following condition (XS1x):
(XS1x) an amine residue has a C₁ symmetry axis as a molecular symmetry and does not have a C₂ symmetry axis.

13. The element according to claim 11, wherein the (XA1x) resin has an amine residue having a phenolic hydroxyl group and an amine residue not having a phenolic hydroxyl group, and
the amine residue having a phenolic hydroxyl group has an amine residue that satisfies the following condition (XS1x), and/or the amine residue not having a phenolic hydroxyl group has an amine residue that satisfies at least one of the following conditions (XS1x) and (XS2x):
(XS1x) the amine residue has a C₁ symmetry axis as a molecular symmetry and does not have a C₂ symmetry axis;
(XS2x) the amine residue has at least one of an asymmetric center, an asymmetric axis, an asymmetric plane, and a helical axis.

14. The element according to claim 11, wherein the insulating resin layer includes a (XH) nitrogen-containing compound, the (XH) nitrogen-containing compound includes one or more selected from a group consisting of a cyclic amide compound, an amide compound, a cyclic urea compound, a urea compound, an oxazolidone compound, and an isoxazolidone compound, and a following condition (X4) is satisfied:
(X4) A total content of the cyclic amide compound, the amide compound, the cyclic urea compound, the urea compound, the oxazolidone compound, and the isoxazolidone compound in the resin layer is 0.010 mass % or more and 5.0 mass % or less.

15. (canceled)

16. The element according to claim 1, wherein
the insulating resin layer includes an organic black pigment and/or an inorganic black pigment, and the organic black pigment includes one or more selected from a group consisting of a benzofuranone-based black pigment, a perylene-based black pigment, and an azo-based black pigment, and
the inorganic black pigment includes one or more selected from a group consisting of a nitride including a metal element, a carbide including a metal element, and an oxynitride including a metal element, and the metal element is one or more selected from a group consisting of zirconium, vanadium, niobium, hafnium, and tantalum.

17. The element according to claim 1, wherein
the insulating resin layer includes
a compound having a quinone structure and/or a quinoid structure of a compound having an aromatic structure to which at least three phenolic hydroxyl groups are bonded, or
a compound having a crosslinked structure between a compound having an aromatic structure to which at least three phenolic hydroxyl groups are bonded and a compound having a structure represented by Formula (11): 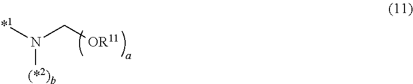
where in Formula (11), R¹¹ represents a hydrogen atom or an alkyl group having 1 to 10 carbon atoms; * 1 and *² each independently represent a bonding point; however, a carbonyl group is not adjacent to a nitrogen atom; a represents 1 or 2; b represents 0 or 1; note that a+b=2.

18. An electronic component comprising the element according to claim 1.

19. A semiconductor device comprising the element according to claim 1,
the semiconductor device further comprising a semiconductor chip, and a sealing material covering the semiconductor chip, wherein
the conductive inorganic layer is a redistribution layer, the insulating resin layer is an interlayer insulating layer of the redistribution layer, and
in plan view, an area of the redistribution layer is larger than an area of the semiconductor chip.

20. A display device comprising the element according to claim 1,
the display device further comprising a light-emitting element, wherein
the conductive inorganic layer is a metal wiring layer, the insulating resin layer is a barrier layer and/or a planarization layer,
the light-emitting element and the metal wiring are electrically connected, the light-emitting element is a semiconductor chip, the barrier layer is formed between adjacent light-emitting elements, and the planarization layer is formed so as to cover at least a part of the light-emitting element, or
the display device further comprising a light-emitting element, and a metal wiring layer, wherein
the conductive inorganic layer is a redistribution layer, and the insulating resin layer is an interlayer insulating layer of the redistribution layer,
the light-emitting element and the metal wiring are electrically connected, the light-emitting element is a semiconductor chip, and
in plan view, an area of the redistribution layer is larger than an area of the light-emitting element.

21. An element comprising a substrate, a conductive inorganic layer, and an insulating resin layer in this order, wherein
the insulating resin layer has a plurality of openings, and
when a detection intensity of a fluorine ion (F⁻), a detection intensity of a chlorine ion (Cl⁻), and a detection intensity of a bromine ion (Br⁻) measured by time-of-flight secondary ion mass spectrometry at a position of 5 nm in depth from a surface of the conductive inorganic layer on the insulating resin layer side in the opening are defined as (F_{ML}) counts, (Cl_{ML}) counts, and (Br_{ML}) counts, respectively, and
when a sum of (F_{ML}), (Cl_{ML}), and (Br_{ML}) is set as (X_{ML}) counts, Formula (XA-1) is satisfied, and
further, when a detection intensity of a fluorine ion (F⁻), a detection intensity of a chlorine ion (Cl⁻), and a detection intensity of a bromine ion (Br⁻) measured by time-of-flight secondary ion mass spectrometry at a position of 5 nm in depth from a surface of the insulating resin layer in the insulating resin layer portion are defined as (F_{RN}) counts, (Cl_{RN}) counts, and (Br_{RN}) counts, respectively, and
when a sum total of (F_{RN}), (Cl_{RN}), and (Br_{RN}) is set as (X_{RN}) counts, Formula (XB-1) is satisfied:
(X_{ML})≤500 (XA-1)
(X_{RN})≤500 (XB-1).

22. (canceled)
